(19) United States
(12) Patent Application Publication
(10) Pub. No.: US 2013/0025120 A1
(43) Pub. Date: Jan. 31, 2013

(54) WIRING BOARD AND MANUFACTURING METHOD FOR SAME

(71) Applicant: Takaharu HONDO, Sakura-shi (JP)

(72) Inventor: Takaharu HONDO, Sakura-shi (JP)

(73) Assignee: FUJIKURA LTD., Tokyo (JP)

(21) Appl. No.: 13/567,685

(22) Filed: Aug. 6, 2012

Related U.S. Application Data
(63) Continuation of application No. PCT/JP2011/052420, filed on Feb. 4, 2011.

(30) Foreign Application Priority Data
Feb. 5, 2010 (JP) 2010-024675
Feb. 5, 2010 (JP) 2010-024677
Feb. 5, 2010 (JP) 2010-024678

(51) Int. Cl. H05K 3/10

(52) U.S. Cl. 29/849

(57) ABSTRACT

A wiring board having high connection reliability is provided. The wiring board comprises: an insulating base material (30); wiring patterns (51-57) formed on one main surface of the insulating base material (30); and vias (11V, 12V) which penetrate from the one main surface side of the insulating base material (30) to the other main surface side and which is conductive with the wiring patterns (51-57), wherein the vias (11V, 12V) have connection base portions (111V, 121V) which merge into the wiring patterns (51-57) to have certain curvatures, and cone-like portions (113V, 123V) of which the outer diameters become thinner as approaching top head portions (112V, 122V) of the vias (11V, 12V) from the connection base portions (111V, 121V).

### BACKGROUND OF THE INVENTION

1. Technical Field of the Invention

The present invention relates to a wiring board and a manufacturing method for the same.

For those designated countries which permit the incorporation by reference, the contents described and/or illustrated in the documents relevant to Patent Application No. 2010-024675 filed with Japan Patent Office on Feb. 5, 2010, Patent application No. 2010-024677 filed with Japan Patent Office on Feb. 5, 2010, and Patent application No. 2010-024678 filed with Japan Patent Office on Feb. 5, 2010 will be incorporated herein by reference, as a part of the description and/or drawings of the present application.

2. Description of the Related Art

In order to achieve highly-dense wiring associated with downsizing electronic devices and enhancing the functionality, patterns (including wiring patterns and via patterns) are required to be finely configured. As a method for forming fine patterns, imprinting method is known in which a mold is used to transfer concave shapes to an insulating base material and the concave shapes are filled with a conductive material to form the wiring patterns. In addition, a method is known for making concave-convex shape of a mold to be used in such imprinting method by photolithography technique.

### PRIOR ART DOCUMENTS

### Patent Documents

Patent Document 1: Published Patent Application No. 2001-320150
Patent Document 2: Published Patent Application No. 2005-108924
Patent Document 3: Published Patent Application No. 2005-026412
Patent Document 4: Published Patent Application No. 2009-111241

### SUMMARY OF THE INVENTION

### Problems to be Solved by the Invention

According to the conventional techniques, however, problems occur that it is difficult to maintain the connection reliability between the vias formed in a wiring board and the wiring patterns to be conductive with the via patterns.

Problems to be solved by the present invention include providing a wiring board with high connection reliability between via patterns and wiring patterns and also providing a manufacturing method for such a wiring board.

### Means for Solving the Problems

(1) The present invention solves the above problems by a manufacturing method for a wiring board, comprising: a step for preparing a first mold comprising a first stamping surface, the first stamping surface including a first protruding portion formed depending on a first via pattern constituting a part of patterns of a first wiring board, the first protruding portion having a first base portion and a first slope portion, the first base portion merging into a main surface of the first stamping surface to have a curvature, the first slope portion decreasing in outer diameter as approaching a first top portion of the first protruding portion from the first base portion; a step for pressing the first stamping surface to one main surface of a first insulating base material having been softened and thereafter releasing the first stamping surface from the one main surface to form a first hole depending on shape of the first protruding portion in the first insulating base material; a step for forming a first concave portion on the one main surface of the first insulating base material, the first concave portion depending on a first wiring pattern constituting a part of the patterns of the first wiring board; and a step for filling the first hole and the first concave portion formed in the first insulating base material with a conductive material to form the first via pattern and the first wiring pattern capable of being conductive with each other.

(2) The above problems are solved by a manufacturing method for a laminate-type wiring board, comprising: a first laminating process for preparing a first wiring board having been obtained by the manufacturing method for a wiring board of the above invention and laminating one or more second insulating base materials on uppermost surface and/or lowermost surface of the first wiring board; a second laminating process for preparing a second mold comprising a second stamping surface, the second stamping surface including a second protruding portion formed depending on a second via pattern constituting a part of patterns of a second wiring board to be laminated, the second protruding portion having a second base portion and a second slope portion, the second base portion merging into a main surface of the second stamping surface to have a curvature, the second slope portion decreasing in outer diameter as approaching a second top portion of the second protruding portion from the second base portion, the second laminating process further for pressing the second stamping surface to a surface of each laminated second insulating base material and thereafter releasing the second stamping surface from the surface of the laminated second insulating base material to form a second hole depending on shape of the second protruding portion in the laminated second insulating base material; a third laminating process for forming a second concave portion on a main surface of the laminated second insulating base material, the second concave portion depending on a second wiring pattern constituting a part of the patterns of the second wiring board; and a fourth laminating process for filling the second hole and the second concave portion formed in the laminated second insulating base material with a conductive material to form the second via pattern and the second wiring pattern capable of being conductive with each other, wherein the first to fourth laminating processes are performed one time or repeated two or more times using the molds having stamping surfaces depending on respective patterns of the wiring boards to be laminated, and wherein whether the first to fourth laminating processes are performed one time or repeated two or more times is depending on a laminating number of a wiring board to be manufactured.

(3) The present invention solves the above problems by a manufacturing method for a wiring board, comprising: a step for preparing a first mold comprising a first stamping surface, the first stamping surface including a first protruding portion formed depending on a first via pattern constituting a part of patterns of a first wiring board, the first stamping surface further including a first convex portion formed depending on a first wiring pattern constituting a part of the patterns of the first wiring board, the first protruding portion having a first base portion and a first slope portion, the first base portion merging into an upper surface of the first convex portion to have a curvature, the first slope portion decreasing in outer diameter as approaching a first top portion of the first protruding portion from the first base portion; a step for pressing the first stamping surface to one main surface of a first insulating base material having been softened and thereafter releasing the first stamping surface from the one main surface to form in the first insulating base material a first hole depending on shape of the first protruding portion and a first concave portion depending on shape of the first convex portion; and a step for filling the first hole and the first concave portion formed in the first insulating base material with a conductive material to form the first via pattern and the first wiring pattern capable of being conductive with each other.

(4) The above problems are solved by a manufacturing method for a laminate-type wiring board, comprising: a first laminating process for preparing a first wiring board having been obtained by the manufacturing method for a wiring board of the above invention and laminating one or more second insulating base materials on uppermost surface and/or lowermost surface of the first wiring board; a second laminating process for preparing a second mold comprising a second stamping surface, the second stamping surface including a second protruding portion formed depending on a second via pattern constituting a part of patterns of a second wiring board to be laminated, the second stamping surface further including a second convex portion formed depending on a second wiring pattern constituting a part of the patterns of the second wiring board, the second protruding portion having a second base portion and a second slope portion, the second base portion merging into an upper surface of the second convex portion to have a curvature, the second slope portion decreasing in outer diameter as approaching a second top portion of the second protruding portion from the second base portion, the second laminating process further for pressing the second stamping surface to a surface of each laminated second insulating base material and thereafter releasing the second stamping surface from the surface of the laminated second insulating base material to form in the laminated second insulating base material a second hole depending on shape of the second protruding portion and a second concave portion depending on shape of the second convex portion; and a third laminating process for filling the second hole and the second concave portion formed in the laminated second insulating base material with a conductive material to form the second via pattern and the second wiring pattern capable of being conductive with each other, wherein the first to third laminating processes are performed one time or repeated two or more times using the molds having stamping surfaces depending on respective patterns of the wiring boards to be laminated, and wherein whether the first to third laminating processes are performed one time or repeated two or more times is depending on a laminating number of a wiring board to be manufactured.

(5) The present invention solves the above problems by a manufacturing method for a wiring board, comprising: a step for preparing a first mold for via, the first mold for via comprising a first stamping surface for via, the first stamping surface for via including a first protruding portion formed depending on a first via pattern constituting a part of patterns of a first wiring board, the first protruding portion having a first base portion and a first slope portion, the first base portion having a curved surface, the first slope portion decreasing in outer diameter as approaching a first top portion of the first protruding portion from the first base portion; a step for preparing a first mold for wiring, the first mold for wiring comprising a first stamping surface for wiring, the first stamping surface for wiring including a first convex portion formed depending on a first wiring pattern constituting a part of the patterns of the first wiring board; a step for pressing the first stamping surface for wiring to one main surface of a first insulating base material having been softened and thereafter releasing the first stamping surface for wiring from the one main surface to form a first concave portion in the first insulating base material, the first concave portion being of shape depending on the first convex portion; a step for pressing the first stamping surface for via to the one main surface of the first insulating base material such that the first protruding portion gets into touch with the first concave portion formed on the one main surface of the first insulating base material and thereafter releasing the first stamping surface for via from the one main surface to form a first hole depending on shape of the first protruding portion in the first insulating base material; and a step for filling the first hole and the first concave portion formed in the first insulating base material with a conductive material to form the first via pattern and the first wiring pattern capable of being conductive with each other.

(6) The above problems are solved by a manufacturing method for a laminate-type wiring board, comprising: a first laminating process for preparing a first wiring board having been obtained by the manufacturing method for a wiring board of the above invention and laminating one or more second insulating base materials on uppermost surface and/or lowermost surface of the first wiring board; a second laminating process for preparing a second mold for wiring, the second mold for wiring comprising a second stamping surface for wiring, the second stamping surface for wiring including a second convex portion formed depending on a second wiring pattern constituting a part of patterns of a second wiring board to be laminated, the second laminating process further for pressing the second stamping surface for wiring to a surface of each laminated second insulating base material and thereafter releasing the second stamping surface for wiring from the surface of the laminated second insulating base material to form a second concave portion in the laminated second insulating base material, the second concave portion being of shape depending on the second convex portion; a third laminating process for preparing a second mold for via, the second mold for via comprising a second stamping surface for via, the second stamping surface for via including a second protruding portion formed depending on a second via pattern constituting a part of the patterns of the second wiring board, the second protruding portion having a second base portion and a second slope portion, the second base portion having a curved surface, the second slope portion decreasing in outer diameter as approaching a second top portion of the second protruding portion from the second base portion, the third laminating process further for pressing the second stamping surface for via to the surface of the laminated second insulating base material such that the second protruding portion gets into touch with the second concave portion formed on the surface of the laminated second insulating base material and thereafter releasing the second stamping surface for via from the surface of the laminated second insulating base material to form a second hole depending on shape of the second protruding portion in the laminated second insulating base material; and a fourth laminating process for filling the second hole and the second concave portion formed in the laminated second insulating base material with a conductive material to form the second via pattern and the second wiring pattern capable of being conductive with each other, wherein the first to fourth laminating processes are performed one time or repeated two or more times using the molds for via and the molds for wiring depending on respective patterns of the wiring boards to be laminated, and wherein whether the first to fourth laminating processes are performed one time or repeated two or more times is depending on a laminating number of a wiring board to be manufactured.

(7) The above problems are solved by a manufacturing method for a wiring board in the first embodiment, further comprising: forming a lower layer concave portion on the other main surface of the first insulating base material, the lower layer concave portion depending on a third wiring pattern conductive with the first via pattern, wherein the filling the first hole with a conductive material includes filling the lower layer concave portion formed on the other main surface of the first insulating base material with the conductive material.

(8) The above problems are solved by a manufacturing method for a wiring board in the second embodiment, further comprising: forming a lower layer concave portion on the other main surface of the first insulating base material, the lower layer concave portion depending on a third wiring pattern conductive with the first via pattern, wherein the filling the first hole with a conductive material includes filling the lower layer concave portion formed on the other main surface of the first insulating base material with the conductive material.

(9) The above problems are solved by a manufacturing method for a wiring board in the third embodiment, further comprising: forming a lower layer concave portion on the other main surface of the first insulating base material, the lower layer concave portion depending on a third wiring pattern conductive with the first via pattern, wherein the filling the first hole with a conductive material includes filling the lower layer concave portion formed on the other main surface of the first insulating base material with the conductive material.

(10) A manufacturing method for a wiring board in claim 1, further comprising: the first top portion of the first protruding portion has a curved surface.

(11) A manufacturing method for a wiring board in claim 3, further comprising: the first top portion of the first protruding portion has a curved surface.

(12) A manufacturing method for a wiring board in claim 5, further comprising: the first top portion of the first protruding portion has a curved surface.

(13) A manufacturing method for a wiring board in claim 2, comprising: the first top portion of the first protruding portion and the second top portion of the second protruding portion have curved surfaces.

(14) A manufacturing method for a wiring board in claim 4, comprising: the first top portion of the first protruding portion and the second top portion of the second protruding portion have curved surfaces.

(15) A manufacturing method for a wiring board in claim 6, comprising: the first top portion of the first protruding portion and the second top portion of the second protruding portion have curved surfaces.

(16) A manufacturing method for a wiring board in claim 1, further comprising: after forming the first hole in the first insulating base material, removing the first insulating base material from a bottom portion of the first hole to cause the first hole to pass through.

(17) A manufacturing method for a wiring board in claim 3, further comprising: after forming the first hole in the first insulating base material, removing the first insulating base material from a bottom portion of the first hole to cause the first hole to pass through.

(18) A manufacturing method for a wiring board in claim 5, further comprising: after forming the first hole in the first insulating base material, removing the first insulating base material from a bottom portion of the first hole to cause the first hole to pass through.

### Advantageous Effect of the Invention

According to the present invention, the via pattern penetrating from one main surface side of the insulating base material of a wiring board to the other main surface side is formed such that the outer diameter decreases as approaching the top head portion of the via pattern from a portion merging into the wiring pattern, which is formed on the one main surface of the insulating base material, to have a certain curvature, so that the force generated between the via pattern and the wiring pattern may be distributed thereby to prevent the stress from concentrating at the connection portion between the via pattern and the wiring pattern. Consequently, the connection reliability between the via pattern and the wiring pattern can be improved. In addition, since the via pattern merges into the wiring pattern to have a certain curvature, reflection of signals is suppressed thereby to reduce the loss of signals even when transmitting high frequency signals.

### BRIEF DESCRIPTION OF DRAWINGS

FIG. 1 is a process cross-sectional view for explaining one example of a manufacturing method for a wiring board according to a first embodiment of the present invention;

FIG. 2 is a process cross-sectional view for explaining one example of the manufacturing method for a wiring board according to the first embodiment of the present invention;

FIG. 3 is a process cross-sectional view for explaining one example of the manufacturing method for a wiring board according to the first embodiment of the present invention;

FIG. 4 is a process cross-sectional view for explaining one example of the manufacturing method for a wiring board according to the first embodiment of the present invention;

FIG. 5 is a process cross-sectional view for explaining one example of the manufacturing method for a wiring board according to the first embodiment of the present invention and also is a cross-sectional view of a mold to be used for this manufacturing method;

FIG. 6 is an enlarged view of a protruding portion shown as area A in FIG. 5;

FIG. 7 is a process cross-sectional view for explaining one example of the manufacturing method for a wiring board according to the first embodiment of the present invention;

FIG. 8 is a process cross-sectional view for explaining one example of the manufacturing method for a wiring board according to the first embodiment of the present invention;

FIG. 9 is a process cross-sectional view for explaining one example of the manufacturing method for a wiring board according to the first embodiment of the present invention;

FIG. 10 is a process cross-sectional view for explaining one example of the manufacturing method for a wiring board according to the first embodiment of the present invention;

FIG. 11 is a cross-sectional view illustrating a wiring board according to the first embodiment of the present invention;

FIG. 12 is a schematic view of a crystal in a cross section along line XII-XII shown in FIG. 11;

FIG. 13 is a process cross-sectional view for explaining one example of a manufacturing method for a wiring board according to a second embodiment of the present invention;

FIG. 14 is a process cross-sectional view for explaining one example of the manufacturing method for a wiring board according to the second embodiment of the present invention;

FIG. 15 is a process cross-sectional view for explaining one example of the manufacturing method for a wiring board according to the second embodiment of the present invention;

FIG. 16 is a process cross-sectional view for explaining one example of the manufacturing method for a wiring board according to the second embodiment of the present invention;

FIG. 17 is a process cross-sectional view for explaining one example of the manufacturing method for a wiring board according to the second embodiment of the present invention;

FIG. 18 is a cross-sectional view illustrating one example of a laminate-type wiring board according to the second embodiment of the present invention;

FIG. 19 is a process cross-sectional view for explaining one example of another manufacturing method for a wiring board according to the second embodiment of the present invention;

FIG. 20 is a process cross-sectional view for explaining one example of another manufacturing method for a wiring board according to the second embodiment of the present invention;

FIG. 21 is a process cross-sectional view for explaining one example of another manufacturing method for a wiring board according to the second embodiment of the present invention;

FIG. 22 is a process cross-sectional view for explaining one example of another manufacturing method for a wiring board according to the second embodiment of the present invention;

FIG. 23 is a process cross-sectional view for explaining one example of another manufacturing method for a wiring board according to the second embodiment of the present invention;

FIG. 24 is a cross-sectional view illustrating one example of another laminate-type wiring board according to the second embodiment of the present invention;

FIG. 25 is a process cross-sectional view for explaining one example of a manufacturing method for a wiring board according to a third embodiment of the present invention;

FIG. 26 is a process cross-sectional view for explaining one example of the manufacturing method for a wiring board according to the third embodiment of the present invention;

FIG. 27 is a process cross-sectional view for explaining one example of the manufacturing method for a wiring board according to the third embodiment of the present invention;

FIG. 28 is a process cross-sectional view for explaining one example of the manufacturing method for a wiring board according to the third embodiment of the present invention;

FIG. 29 is a process cross-sectional view for explaining one example of the manufacturing method for a wiring board according to the third embodiment of the present invention;

FIG. 30 is a process cross-sectional view for explaining one example of the manufacturing method for a wiring board according to the third embodiment of the present invention;

FIG. 31 is a process cross-sectional view for explaining one example of the manufacturing method for a wiring board according to the third embodiment of the present invention and also is a cross-sectional view of a mold to be used in the present embodiment;

FIG. 32 is a process cross-sectional view for explaining one example of the manufacturing method for a wiring board according to the third embodiment of the present invention;

FIG. 33 is a process cross-sectional view for explaining one example of the manufacturing method for a wiring board according to the third embodiment of the present invention;

FIG. 34 is a process cross-sectional view for explaining one example of the manufacturing method for a wiring board according to the third embodiment of the present invention;

FIG. 35 is a process cross-sectional view for explaining one example of the manufacturing method for a wiring board according to the third embodiment of the present invention;

FIG. 36 is a process cross-sectional view for explaining one example of the manufacturing method for a wiring board according to the third embodiment of the present invention;

FIG. 37 is a cross-sectional view illustrating one example of a wiring board according to the third embodiment of the present invention;

FIG. 38 is a process cross-sectional view for explaining another example (first modified example) of the manufacturing method for a wiring board according to the third embodiment of the present invention;

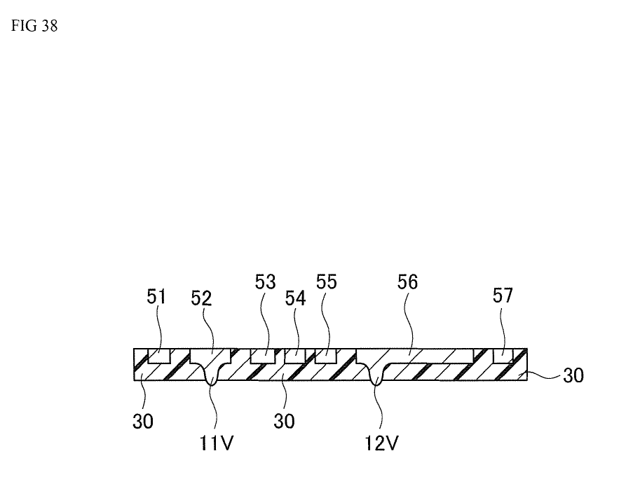

FIG. 39 is a cross-sectional view illustrating one example (the first modified example) of a wiring board according to the third embodiment of the present invention;

FIG. 40 is a process cross-sectional view for explaining another example (second modified example) of the manufacturing method for a wiring board according to the third embodiment of the present invention;

FIG. 41 is a process cross-sectional view for explaining another example (the second modified example) of the manufacturing method for a wiring board according to the third embodiment of the present invention;

FIG. 42 is a process cross-sectional view for explaining another example (the second modified example) of the manufacturing method for a wiring board according to the third embodiment of the present invention;

FIG. 43 is a process cross-sectional view for explaining yet another example (third modified example) of the manufacturing method for a wiring board according to the third embodiment of the present invention;

FIG. 44 is a process cross-sectional view for explaining one example of a manufacturing method for a wiring board according to a fourth embodiment of the present invention;

FIG. 45 is a process cross-sectional view for explaining one example of the manufacturing method for a wiring board according to the fourth embodiment of the present invention;

FIG. 46 is a process cross-sectional view for explaining one example of the manufacturing method for a wiring board according to the fourth embodiment of the present invention;

FIG. 47 is a process cross-sectional view for explaining one example of the manufacturing method for a wiring board according to the fourth embodiment of the present invention;

FIG. 48 is a cross-sectional view illustrating a laminate-type wiring board according to the fourth embodiment of the present invention;

FIG. 49 is a process cross-sectional view for explaining one example of a manufacturing method for a wiring board according to a fifth embodiment of the present invention;

FIG. 50 is a process cross-sectional view for explaining one example of the manufacturing method for a wiring board according to the fifth embodiment of the present invention;

FIG. 51 is a process cross-sectional view for explaining one example of the manufacturing method for a wiring board according to the fifth embodiment of the present invention;

FIG. 52 is a process cross-sectional view for explaining one example of the manufacturing method for a wiring board according to the fifth embodiment of the present invention;

FIG. 53 is a process cross-sectional view for explaining one example of the manufacturing method for a wiring board according to the fifth embodiment of the present invention and also is a cross-sectional view of a mold to be used in the present embodiment;

FIG. 54 is a process cross-sectional view for explaining one example of the manufacturing method for a wiring board according to the fifth embodiment of the present invention;

FIG. 55 is a process cross-sectional view for explaining one example of the manufacturing method for a wiring board according to the fifth embodiment of the present invention;

FIG. 56 is a process cross-sectional view for explaining one example of the manufacturing method for a wiring board according to the fifth embodiment of the present invention;

FIG. 57 is a process cross-sectional view for explaining one example of the manufacturing method for a wiring board according to the fifth embodiment of the present invention;

FIG. 58 is a process cross-sectional view for explaining one example of the manufacturing method for a wiring board according to the fifth embodiment of the present invention;

FIG. 59 is a process cross-sectional view for explaining one example of the manufacturing method for a wiring board according to the fifth embodiment of the present invention;

FIG. 60 is a process cross-sectional view for explaining one example of the manufacturing method for a wiring board according to the fifth embodiment of the present invention;

FIG. 61 is a cross-sectional view illustrating one example of a wiring board according to the fifth embodiment of the present invention;

FIG. 62 is a process cross-sectional view for explaining one example of a manufacturing method for a wiring board according to a sixth embodiment of the present invention;

FIG. 63 is a process cross-sectional view for explaining one example of the manufacturing method for a wiring board according to the sixth embodiment of the present invention;

FIG. 64 is a process cross-sectional view for explaining one example of the manufacturing method for a wiring board according to the sixth embodiment of the present invention;

FIG. 65 is a process cross-sectional view for explaining one example of the manufacturing method for a wiring board according to the sixth embodiment of the present invention;

FIG. 66 is a process cross-sectional view for explaining one example of the manufacturing method for a wiring board according to the sixth embodiment of the present invention;

FIG. 67 is a process cross-sectional view for explaining one example of the manufacturing method for a wiring board according to the sixth embodiment of the present invention;

FIG. 68 is a process cross-sectional view for explaining one example of the manufacturing method for a wiring board according to the sixth embodiment of the present invention;

FIG. 69 is a cross-sectional view illustrating one example of a laminate-type wiring board according to the sixth embodiment of the present invention;

FIG. 70 is a process cross-sectional view for explaining one example of a manufacturing method for a wiring board according to a seventh embodiment of the present invention;

FIG. 71 is a process cross-sectional view for explaining one example of the manufacturing method for a wiring board according to the seventh embodiment of the present invention;

FIG. 72 is a process cross-sectional view for explaining one example of the manufacturing method for a wiring board according to the seventh embodiment of the present invention;

FIG. 73 is a process cross-sectional view for explaining one example of the manufacturing method for a wiring board according to the seventh embodiment of the present invention;

FIG. 74 is a process cross-sectional view for explaining one example of the manufacturing method for a wiring board according to the seventh embodiment of the present invention and also is a cross-sectional view of a mold to be used in the present embodiment;

FIG. 75 is a process cross-sectional view for explaining one example of the manufacturing method for a wiring board according to the seventh embodiment of the present invention;

FIG. 76 is a process cross-sectional view for explaining one example of the manufacturing method for a wiring board according to the seventh embodiment of the present invention;

FIG. 77 is a process cross-sectional view for explaining one example of the manufacturing method for a wiring board according to the seventh embodiment of the present invention;

FIG. 78 is a process cross-sectional view for explaining one example of the manufacturing method for a wiring board according to the seventh embodiment of the present invention;

FIG. 79 is a process cross-sectional view for explaining one example of the manufacturing method for a wiring board according to the seventh embodiment of the present invention;

FIG. 80 is a process cross-sectional view for explaining one example of the manufacturing method for a wiring board according to the seventh embodiment of the present invention;

FIG. 81 is a process cross-sectional view for explaining one example of the manufacturing method for a wiring board according to the seventh embodiment of the present invention;

FIG. 82 is a cross-sectional view illustrating one example of a wiring board according to the seventh embodiment of the present invention;

FIG. 83 is a process cross-sectional view for explaining one example of a manufacturing method for a wiring board according to an eighth embodiment of the present invention;

FIG. 84 is a process cross-sectional view for explaining one example of the manufacturing method for a wiring board according to the eighth embodiment of the present invention;

FIG. 85 is a process cross-sectional view for explaining one example of the manufacturing method for a wiring board according to the eighth embodiment of the present invention;

FIG. 86 is a process cross-sectional view for explaining one example of the manufacturing method for a wiring board according to the eighth embodiment of the present invention;

FIG. 87 is a process cross-sectional view for explaining one example of the manufacturing method for a wiring board according to the eighth embodiment of the present invention;

FIG. 88 is a process cross-sectional view for explaining one example of the manufacturing method for a wiring board according to the eighth embodiment of the present invention;

FIG. 89 is a process cross-sectional view for explaining one example of the manufacturing method for a wiring board according to the eighth embodiment of the present invention; and

FIG. 90 is a cross-sectional view illustrating one example of a laminate-type wiring board according to the eighth embodiment of the present invention;

### DESCRIPTION OF THE PREFERRED EMBODIMENT

### First Embodiment

Hereinafter, a wiring board according to the present embodiment of this invention and a manufacturing method for this wiring board will be described. The manufacturing method for a wiring board in the present embodiment has the following two processes in broad terms: a process for preparing a mold to be used; and a process for producing a wiring board using the prepared mold.

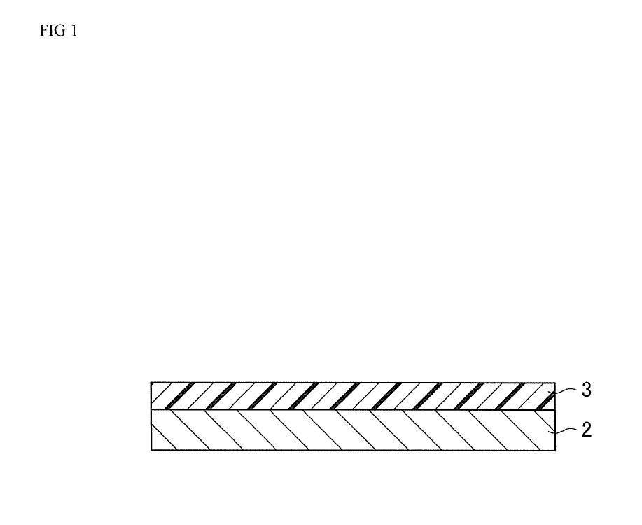

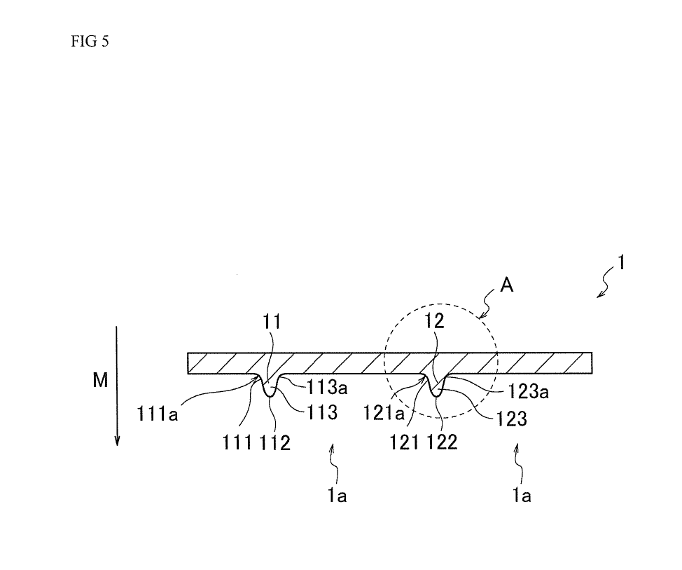

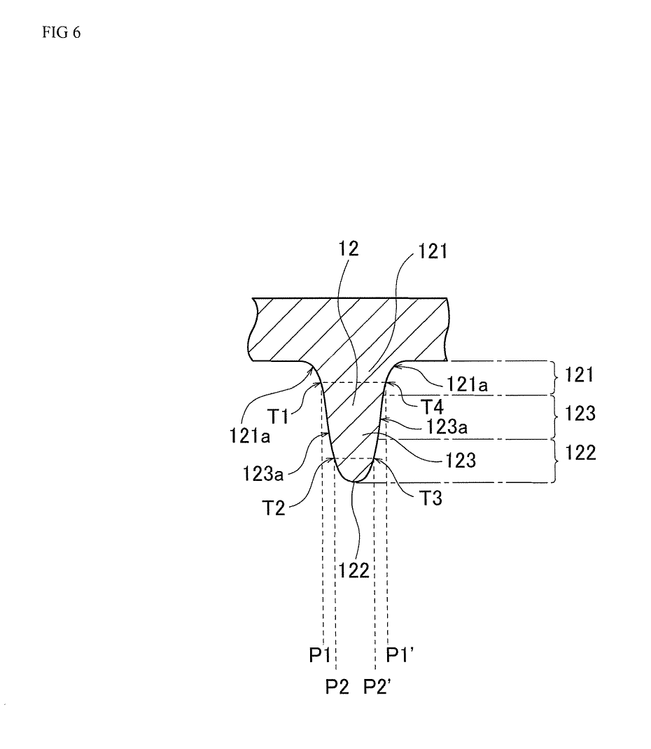

A manufacturing method for a mold will be described first with reference to FIG. 1 to FIG. 4, and the manufactured mold will then be described with reference to FIG. 5 and FIG. 6. Thereafter, the manufacturing method for a wiring board using the mold will be described.

The manufacturing method for a mold according to the present embodiment has a step for preparing a cured resin plate body, a step for irradiating laser or electron beam depending on via patterns to a main surface of the resin plate body thereby to form holes, and a step, using a mold material, for filling the holes formed in the resin plate body and covering the main surface of the resin plate body.

(1) First, a resin plate body 3 for taking the shape of a mold 1 and a supporting plate 2 for supporting this resin plate body 3 are prepared. As the supporting plate 2, a material removable by etching is used. Although not particularly limited, the present embodiment employs the supporting plate 2 as a copper foil with thickness of about 80 to 120 μm. The use of copper foil as the supporting plate 2 can suppress the supporting plate 2 from expanding or contracting when applying heat to the resin plate body 3. On the other hand, as the resin plate body 3, a material soluble in alkali or acid is used. Although not particularly limited, the present embodiment employs a light curable type or heat curable type resist film as the resin plate body 3 with thickness of about 15 to 40 μm, for example 25 μm.

(2) Thereafter, as shown in FIG. 1, the resin plate body 3 is laminated on the main surface of the supporting plate 2 to be cured by light irradiation or heating. A separating treatment may be performed between the supporting plate 2 and the resin plate body 3.

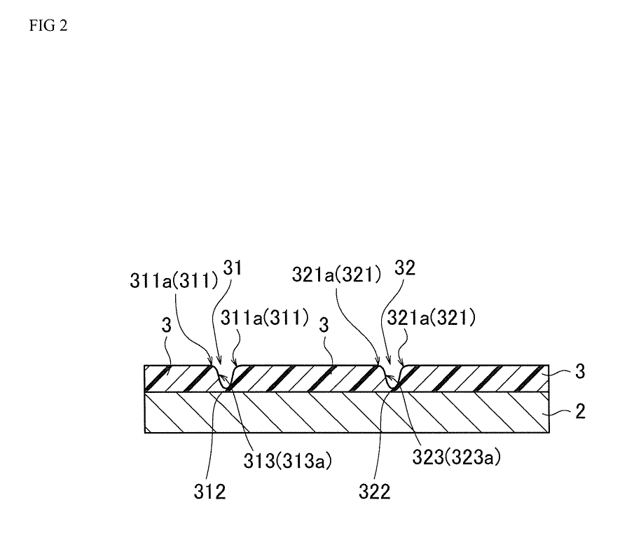

(3) Subsequently, as shown in FIG. 2, laser or electron beam (EB) is irradiated to the main surface of the resin plate body 3 to form holes 31 and 32. Excimer laser, femtosecond laser or other laser may be used as the laser. The irradiation direction of the laser or electron beam may be perpendicular direction with respect to the main surface of the resin plate body 3, or the irradiation may alternatively be performed with a certain angle other than right angle.

Although not particularly limited, the diameter of opening areas 311 and 321 of the holes 31 and 32 in the present embodiment is 2 μm or more and 35 μm or less, preferably 2 μm or more and 15 μm or less, and further preferably 2 μm or more and less than 10 μm. In addition, the diameter of bottom areas 312 and 322 of the holes 31 and 32 in the present embodiment is 1 μm or more and 30 μm or less, preferably 1 μm or more and 10 μm or less, and further preferably 1 μm or more and 5 μm or less. The depth is 1 μm or more and 50 μm or less, and preferably 10 μm or more and 40 μm or less. For one example, the holes 31 and 32 in the present embodiment are such that the diameter of the opening areas 311 and 321 is about 10 μm and the depth is about 15 μm.

Although not particularly limited, in the present embodiment, the laser or electron beam may be irradiated to the resin plate body 3 such that the energy given by the laser or electron beam to the resin plate body 3 gradually decreases from the opening areas 311 and 321 of the holes 31 and 32 to the bottom areas 312 and 322 of the holes 31 and 32. For example, the step for forming the holes 31 and 32 may involve an approach for progressively decreasing with time the energy density of laser light or an approach for progressively decreasing with time the number of shots. This allows for giving a larger energy to the opening areas 311 and 321 to provide a larger diameter in the vicinity of the opening areas 311 and 321 while decreasing the diameter of the holes 31 and 32 as progressing the laser drilling toward the bottom areas 312 and 322 from the opening areas 311 and 321 of the holes 31 and 32.

Moreover, by controlling the energy given by laser or electron beam, inner walls 311a and 321a of the opening areas 311 and 321 of the holes 31 and 32 can be made as being surfaces with certain curvatures, and body areas 313 and 323 merging into the opening areas 311 and 321 can be made as being slope walls 313a and 323a inclined with respect to the depth direction. Approaches for controlling the energy given by laser or electron beam may be experimentally achieved depending on various factors, such as, but not particularly limited to, type of the resin plate body 3, thickness of the resin plate body 3, type of the laser or electron beam, magnitude of energy to be given (energy density, the number of shots), and the distance between a light source and the resin plate body 3.

In addition, the step for forming the holes 31 and 32 may involve an approach of decreasing with time the beam diameter of laser light, such as excimer laser. For example, the beam diameter when forming the opening areas 311 and 321 of the holes 31 and 32 may be set as being larger than the beam diameter when forming the bottom areas 312 and 322 of the holes 31 and 32. This approach allows for providing a larger diameter of the opening areas 311 and 321 while decreasing the diameter of the holes 31 and 32 as progressing the laser drilling toward the bottom areas 312 and 322 from the opening areas 311 and 321 of the holes 31 and 32.

The holes 31 and 32 formed according to such approaches may be such that, as shown in FIG. 2, the inner walls 311a and 321a of the opening areas 311 and 321 are formed to merge into the main surface of the resin plate body 3 to have certain curvatures. Further, the body areas 313 and 323 may be formed to comprise the slope walls 313a and 323a of which diameters decrease as approaching the bottom areas 312 and 322 from the opening areas 311 and 321 of the holes 31 and 32 formed in the resin plate body 3.

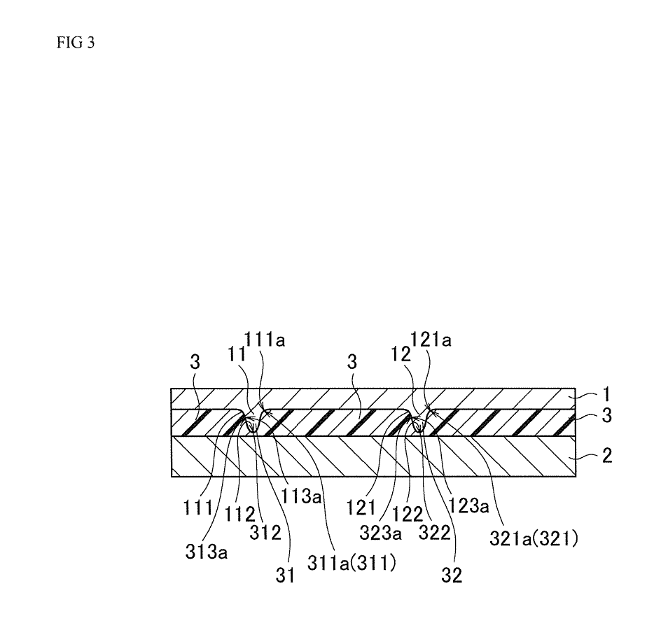

(4) Subsequently, as shown in FIG. 3, a mold material is used for filling the holes 31 and 32 formed in the resin plate body 3 and covering the main surface of the resin plate body 3.

Specifically, regions to be filled with the mold material, such as in the holes 31 and 32 of the resin plate body 3 and on the main surface of the resin plate body 3, are first formed thereon with a conductive layer to be a seed layer for the subsequent plating process or the like. This conductive layer is achieved by Direct Plating Process (DPP) using carbon (C), palladium (Pd) or other appropriate materials, or by sputtering using copper (Cu), nickel (Ni) or other appropriate materials. Thereafter, plating is performed using the mold material such as copper (Cu) or nickel (Ni) to fill the holes 31 and 32 with the mold material and cover the main surface of the resin plate body 3 with plated layer of the mold material. Of course, conductive nano-paste containing copper (Cu), silver (Ag) or other appropriate materials may be printed to fill the holes 31 and 32 with the mold material and cover the main surface of the resin plate body 3 therewith. Note, however, that an insulating material (nonconductive material) such as glass may also be used as the mold material aside from conductive materials.

Although not particularly limited, the present embodiment involves performing copper plating after having formed a copper (Cu) layer with the thickness of about 100 to 300 nm by sputtering. The copper plated layer is formed above the resin plate body 3 with the thickness of about 10 to 50 μm to fill the holes 31 and 32 with the mold material and cover the main surface of the resin plate body 3 therewith.

This causes protruding portions 11 and 12 to be formed within the holes 31 and 32 formed in the resin plate body 3, as shown in the figure, to comprise: base portions 111 and 121 having curved surfaces 111a and 121a; slope portions 113 and 123; and top portions 112 and 122. The curved surfaces 111a and 121a of the formed protruding portions 11 and 12 contact with the inner walls 311a and 321a of the holes 31 and 32, slope surfaces 113a and 123a of the protruding portions 11 and 12 contact with the slope walls 313a and 323a of the holes 31 and 32, and the top portions 112 and 122 of the protruding portions 11 and 12 contact with the bottom areas 312 and 322.

The holes 31 and 32 of the resin plate body 3 according to the present embodiment are such that the inner walls 311a and 321a of those opening areas 311 and 321 are formed with surfaces having certain curvatures to merge into the main surface of the resin plate body 3, and there is thus no corner area such as being formed by intersecting straight lines or flat planes. If such a corner area is formed on a subject to be plated thereon, the plating thickness at the corner area will tend to be different from that of other areas. In contrast, according to the present embodiment, no corner area is formed within the opening areas 311 and 321, and the plated layer with uniform thickness can thus be formed on the inner walls 311a and 321a.

Moreover, since the slope walls 313a and 323a, of which the diameters decrease as approaching the bottom areas 312 and 322 from the inner walls 311a and 321a, have flat surfaces without irregularities and the opening planar dimensions gradually increase from the bottom areas 312 and 322 to the opening areas 311 and 321, the plated layer with uniform thickness can also be formed on the slope walls 313a and 323a and the bottom areas 312 and 322.

If, however, the plating thickness is of nonuniform, then stresses acting on the plated layer concentrate to generate strong force at a part thereof, whereas according to the present embodiment, the plated layer with uniform thickness is formed on the inner walls 311a and 321a of the opening areas 311 and 321, on the slope walls 313a and 323a, and on the bottom areas 312 and 322, thereby to prevent stresses from concentrating to act at a part of the plated layer (mold 1). According to the manufacturing method in the present embodiment, a highly durable mold 1 can be obtained which is capable of suppressing partial breakages from occurring.

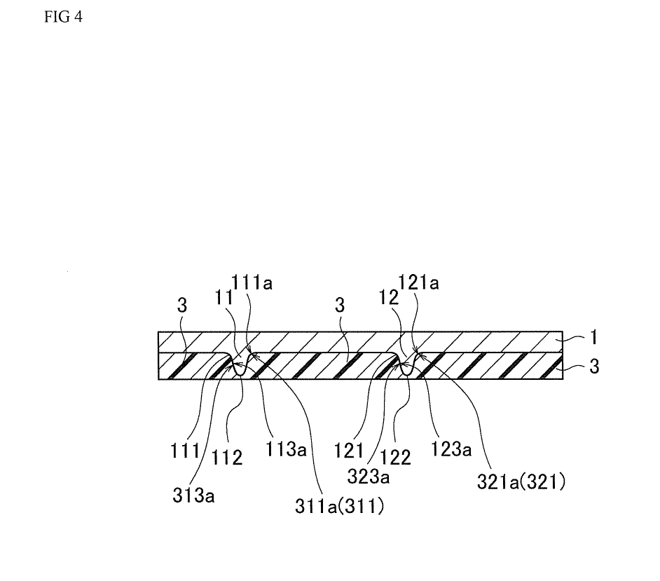

(5) Subsequently, as shown in FIG. 4, the supporting plate 2 is removed by using etching liquid such as ferric chloride solution to expose the surface of the resin plate body 3.

(6) Finally, the resin plate body 3 is also removed through swelling by using aqueous solution of sodium hydroxide or other appropriate liquid. This provides the mold 1 as shown in FIG. 5, which will be described later.

Conventionally, the shape of protruding portions has been constrained by the resolution of photolithography because photolithography technique has been used to form protruding portions for forming via patterns, and it has been difficult to make fine shapes with the diameter of 20 μm or less, particularly 10 μm or less and with the aspect ratio of 1 or more. In contrast, the manufacturing method for the mold 1 according to the present embodiment forms the holes 31 and 32 by using laser or electron beam, thereby to allow for forming in one step the fine holes 31 and 32 with reduced diameter (e.g. the diameter of the opening areas 311 and 321 of the holes 31 and 32 is 2 μm or more and 35 μm or less, and the diameter of the bottom areas 312 and 322 of the holes 31 and 32 is 1 μm or more and 30 μm or less) and increased aspect ratio (such as 1 or more).

Furthermore, according to the above method using laser or electron beam to form the holes 31 and 32, it is possible to form in one step curved surfaces which are difficult to be formed by the photolithography steps.

In addition, according to the above method using laser or electron beam to form the holes 31 and 32, one step may be enough to make the inner walls 311a and 321a having certain curvatures, the slope walls 313a and 323a merging into these inner walls 311a and 321a and being inclined to the depth direction, and the bottom areas 312 and 322 merging into these slope walls 313a and 323a and being formed by curved surfaces, thereby to allow for manufacturing the mold 1 as shown in FIG. 5 with high productivity and reduced cost.

As in conventional techniques, via patterns may be directly formed in an insulating base material using ultraviolet (UV) laser, but the diameter of via patterns formed in the insulating base material is restricted to be about 30 μm or more. Further, via patterns with the diameter of about 10 μm may even be directly formed in an insulating base material using excimer laser, but wiring boards increase in cost because processing via patterns one by one requires long time and gases to be used such as krypton fluoride (KrF) is expensive. Given the foregoing, if via patterns could be formed in a wiring board using the mold 1 according to the present embodiment, then via patterns may be formed at low cost, of which the thickest portion has a diameter of 35 μm or less, further 15 μm or less, and further less than 10 μm.

FIG. 5 is a cross-sectional view of the mold 1 in the present embodiment along the mold clamping direction (arrow M in the figure). As shown in FIG. 5, the mold 1 according to the present embodiment has a stamping surface 1a formed depending on patterns (including via patterns and wiring patterns) to be made on a wiring board. The stamping surface 1a of the mold 1 according to the present invention functions as a working-purpose plate (original plate) for transferring a concave-convex shape (including protruding portions 11 and 12 depending on via patterns, and convex portions depending on wiring patterns), which is used for constituting desired patterns, to an insulating base material or the like of a wiring board. Reference character 1a in FIG. 5 specifies the entire surface of the stamping surface 1a formed thereon with the concave-convex shape including the protruding portions 11 and 12 used for constituting desired patterns.

The stamping surface 1a in the present embodiment has at least protruding portions 11 and 12 each formed in convex shape on the main surface side of this stamping surface 1a. No interface exists between the stamping surface 1a and the protruding portions 11 and 12, and the protruding portions 11 and 12 thus constitute parts of the stamping surface 1a. Although not particularly limited, the stamping surface 1a may be provided by a plate-like member having a certain thickness as shown in FIG. 5 or by a structure supported by another plate-like member (not shown). Note that, as mold materials for constituting the mold 1, metals such as copper (Cu) as well as resins or other appropriate materials may be utilized.

The protruding portions 11 and 12 in the present embodiment are formed into shapes having certain thicknesses (diameters), lengths and aspect ratios corresponding to those of holes of via patterns to be formed. Although not particularly limited, the diameter of base portions 111 and 121 of the protruding portions 11 and 12 is 2 μm or more and 35 μm or less, preferably 2 μm or more and 15 μm or less, and further preferably 2 μm or more and less than 10 μm. In addition, the diameter of top portions 112 and 122 of the protruding portions 11 and 12 in the present embodiment is 1 μm or more and 30 μm or less, preferably 1 μm or more and 10 μm or less, and further preferably 1 μm or more and 5 μm or less. The length of the protruding portions 11 and 12 in the present embodiment is 1 μm or more and 50 μm or less, and preferably 10 μm or more and 40 μm or less. The aspect ratio is 0.5 to 40, preferably 1 to 30, and may be selected as being about 1 to 4 in this example. While two protruding portions 11 and 12 are shown in FIG. 5, the arrangement and the number of protruding portion(s) 11, 12 are not particularly limited.

The protruding portions 11 and 12 in the present embodiment have base portions 111 and 121 which merge into the main surface of the stamping surface 1a with curved surfaces 111a and 121a having certain curvatures, and the slope portions 113 and 123 which are tapered from these base portions 111 and 121 to the top portions 112 and 122 of the protruding portions 11 and 12. Note that the main surface of the stamping surface 1a is a surface parallel to a plane moving when transferring or releasing.

FIG. 6 is an enlarged view of area A shown by dashed line in FIG. 5. As shown in the figure, the protruding portion 12 in the present embodiment has the curved surface 121a at the base portion 121 as being a root portion thereof. The base portion 121 of the protruding portion 12 merges into the stamping surface 1a to have a certain curvature. Thus, a connecting portion between the stamping surface 1a and the protruding portion 12 is configured as the curved surface 121a, thereby allowing the protruding portion 12 to be easily pulled away from a resin base material when releasing. Moreover, the base portion 121, which supports the protruding portion 12 with high aspect ratio on the stamping surface 1a, is provided with the curved surface 121a, thereby also to allow for distributing the force acting on the base portion 121 to the curved surface 121a. Consequently, such a trouble that the protruding portion 12 may be broken at the root or the end of the protruding portion 12 may drop off is prevented from occurring. Note that only the protruding portion 12 is shown in FIG. 6 while the protruding portion 11 may also be configured in the same fashion.

Although not particularly limited, the protruding portions 11 and 12 in the present embodiment are such that the slope portions 113 and 123 are formed in cone-like shapes in which the diameters (thicknesses) or areas of cross sections parallel to the main surface of the stamping surface 1a progressively decrease as separating from the main surface of the stamping surface 1a (refer to FIG. 5). Specifically, as shown in the enlarged view of FIG. 6, the slope portion 123 of the protruding portion 12 in the present embodiment has a slope surface 123a which is formed such that the outer diameter (P1-P1′) decreases as approaching the top portion 122 from the base portion 121. In other word, the distance (outer diameter: P1-P1′) between points T1 and T4 on the surface of the protruding portion 12 shown in FIG. 6 progressively decreases as approaching the point T2 (T3) from the point T1 (T4) (P2-P2′<P1-P1′). Under this condition, the mold 1 may be configured such that the segment between the point T1 (T4) and the point T2 (T3) on the surface of the protruding portion 12 is represented by a straight line of y=ax (“a” is a positive or negative constant).

According to another aspect, as shown in FIG. 6, the cross-sectional shape along the moving direction (arrow M direction in FIG. 5) of the stamping surface 1a of the slope portion 123, such as the shape surrounded by points T1, T2, T3 and T4, may be made to be a substantially tapered shape.

Thus, the mold 1 in the present embodiment has the protruding portion 12 provided with the slope portion 123 progressively decreasing in thickness from the base portion 121, which merges into the main surface of the stamping surface 1a to have a certain curvature, to the top portion 122, thereby to result in that a portion with smaller cross section area is allowed to be pressed first into a resin base material during press fitting of the protruding portion 12 into the resin base material. This allows the resistance during the press fitting to be reduced.

Moreover, also during the releasing, the protruding portion 12 is avoided from getting lodged in the resin base material when being pulled off from the resin base material, because the protruding portion 12 has its thickness progressively decreasing toward the top portion 122.

Furthermore, the top portion 122 of the protruding portion 12 may be formed to have a curved surface. In this manner the curved surface is employed for an end portion when mold clamping to the resin base material thereby to allow for distributing the force acting on the protruding portion 12 during the press fitting.

Consequently, it is possible to provide the mold 1 in which the protruding portions 11 and 12 are easy to be pressed into a resin base material when clamping the mold 1 to the resin base material and also easy to be pulled out from the resin base material when releasing the mold 1 from the resin base material.

Note that the length T1-T4 shown in FIG. 6 represents one exemplary diameter of the base portions 111 and 121 of the protruding portions 11 and 12, while the length T2-T3 shown in the figure represents one exemplary diameter of the top portions 112 and 122 of the protruding portions 11 and 12. It should be appreciated that the top portions 112 and 122 include portions with a predetermined distance toward the base portions 111 and 121 from the apexes of the top portions 112 and 122 of the protruding portions 11 and 12, and the diameter of the top portions 112 and 122 is represented by the maximum width of the cross section along the stamping surface 1a where the cross section is defined for the portions included in the top portions 112 and 122.

Note also that the shapes of the above-described holes 31 and 32 of the resin plate body 3, holes 31V and 32V of an insulating base material 30 described hereinafter, and via patterns 11V and 12V, are substantially common to the shape of the protruding portion 12 shown in FIG. 6. In other words, the diameter of the base portion 121 of the protruding portion 12 corresponds to the diameter of the opening areas 311 and 321 of the holes 31 and 32 of the resin plate body 3, the diameter of opening areas 311V and 321V of the holes 31V and 32V of the insulating base material 30, and the diameter of connection base portions 111V and 121V of the via patterns 11V and 12V, while the diameter of the top portion 122 of the protruding portion 12 corresponds to the diameter of the bottom areas 312 and 322 of the holes 31 and 32 of the resin plate body 3, the diameter of bottom areas 312V and 322V of the holes 31V and 32V of the insulating base material 30, and the diameter of top head portions 112V and 122V of the via patterns 11V and 12V.

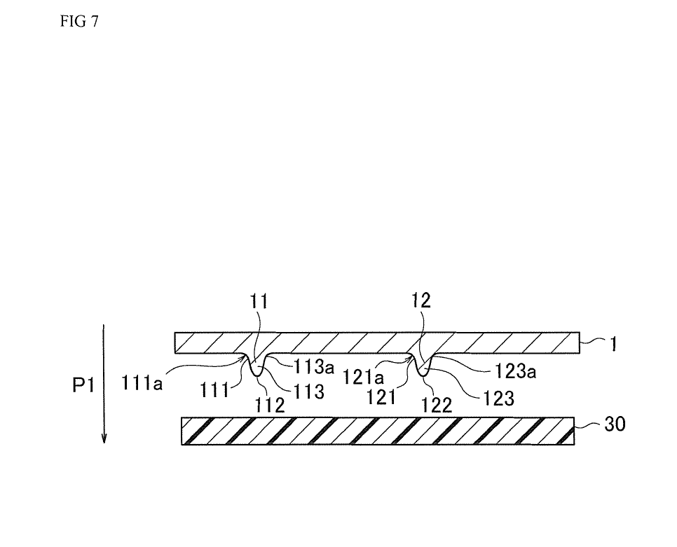

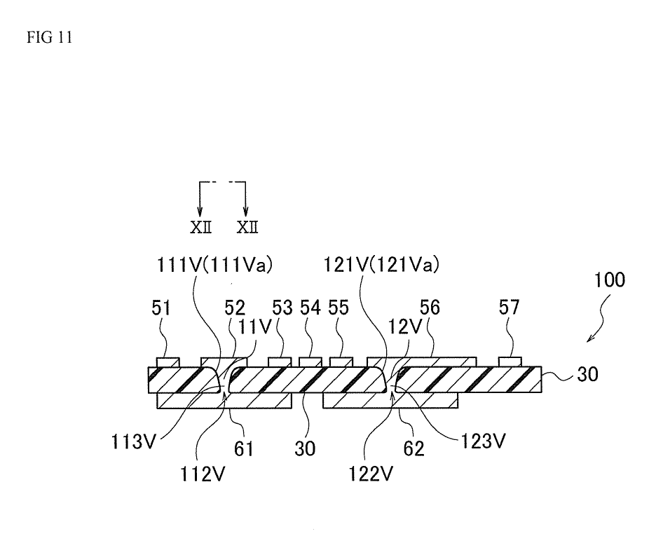

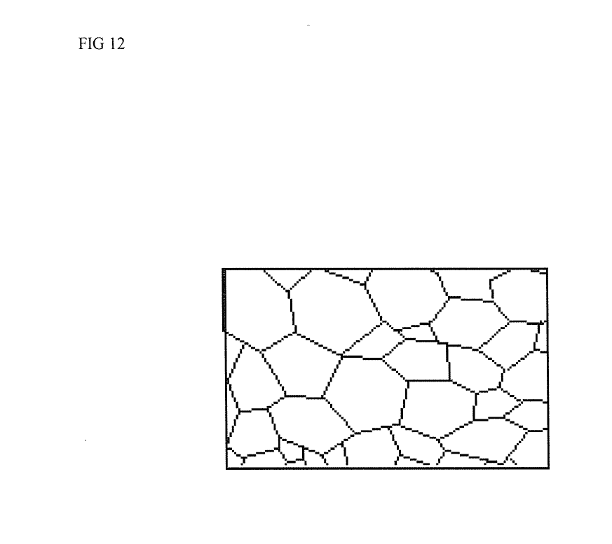

Hereinafter, a manufacturing method for a wiring board using the mold 1 will be described with reference to FIG. 7 to FIG. 10, and the manufactured wiring board will then be described with reference to FIG. 11 and FIG. 12.

In the present embodiment, a wiring board is obtained by so-called imprinting method using the above-described mold 1 shown in FIG. 5 and FIG. 6.

As shown in FIG. 7, the mold 1, and an insulating base material (resin film) 30 for transfer which is to constitute a wiring board, are prepared first and they are arranged such that the main surface of the mold 1 opposes the main surface of the insulating base material 30. As a material for the insulating base material 30, heat-curable resin such as epoxy resin or thermoplastic resin such as liquid crystal polymer may be used, for example. The mold 1 is then caused to move along the direction where the mold 1 approaches the insulating base material 30 (direction denoted by arrow P1). The present embodiment employs Ajinomoto Build-Up Film (ABF) of heat-curable resin as the material for the insulating base material 30, which is hot pressed under 150 degrees C. and 10 MPa. At this time, because the top portions 112 and 122 of the protruding portions 11 and 12 are configured with curved surfaces, the resistance force acting thereto may be reduced. Accordingly, the top portions 112 and 122 of the protruding portions 11 and 12 are allowed to be pressed into the insulating base material 30 with less force than the case where the top portions 112 and 122 are flat.

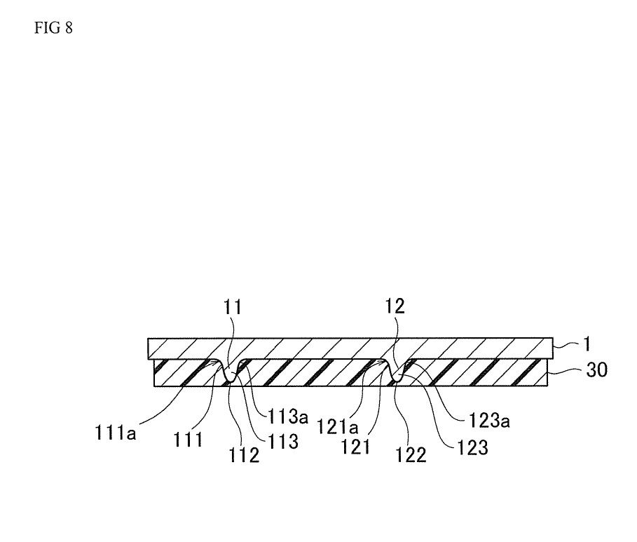

The mold 1 and the insulating base material 30 are heated to a temperature equal to or above the glass transition temperature (Tg), and the mold 1 is pressed to the insulating base material 30, as shown in FIG. 8. Thereafter, the mold 1 and the insulating base material 30 are cooled below the glass transition temperature (Tg).

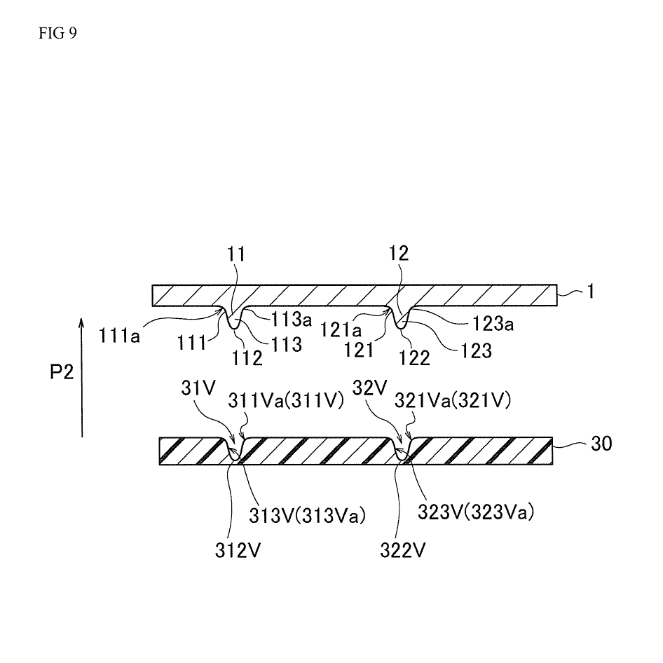

Subsequently, as shown in FIG. 9, the mold 1 is released in the direction where the mold 1 is separated from the insulating base material 30 (arrow P2). At this time, because the base portions 111 and 121 of the protruding portions 11 and 12 have certain curvatures, the releasing is more easily performed than the case where the base portions 111 and 121 are connected to the stamping surface 1a with angles. If the insulating base material 30 is heat-curable resin, then the insulating base material 30 is fully cured by heating at 180 degrees C., for example, during 1 hour in an oven or the like. If, on the other hand, the insulating base material 30 is thermoplastic resin, then it is cured by cooling.

This allows for transferring the patterns (including via patterns and wiring patterns, here and hereinafter) of the stamping surface 1a of the mold 1 to the main surface of the insulating base material 30. As shown in the figure, after the release of the mold 1, the insulating base material 30 is formed therein holes 31V and 32V depending on the shapes of the protruding portions 11 and 12 of the mold 1. These holes 31V and 32V have: inner walls 311Va and 321Va having certain curvatures around opening areas 311V and 321V; and slope walls 313Va and 323Va gradually decreasing in inner diameters thereof toward the bottom surfaces. The holes 31V and 32V formed in the insulating base material 30 are substantially of the same shapes as the holes 31 and 32 shown in FIG. 2.

Specifically, the holes 31V and 32V having been formed in the insulating base material 30 are such that, as shown in the figure, the inner walls 311Va and 321Va having certain curvatures are formed within the opening areas 311V and 321V, and merge into the main surface of the insulating base material 30 to have a curvature. These holes 31V and 32V have body areas 313V and 323V comprising the slope walls 313Va and 323Va which decrease in their diameters as approaching the bottom areas 312V and 322V from the opening areas 311V and 321V. Although not particularly limited, the diameter of the opening areas 311V and 321V of the holes 31V and 32V in the present embodiment is 2 μm or more and 35 μm or less, preferably 2 μm or more and 15 μm or less, and further preferably 2 μm or more and less than 10 μm. In addition, the diameter of the bottom areas 312V and 322V of the holes 31V and 32V in the present embodiment is 1 μm or more and 30 μm or less, preferably 1 μm or more and 10 μm or less, and further preferably 1 μm or more and 5 μm or less. The depth is 1 μm or more and 50 μm or less, and preferably 10 μm or more and 40 μm or less. For one example, the holes 31V and 32V in the present embodiment are such that the diameter of the opening areas 311V and 321V is about 10 μm and the depth is about 15

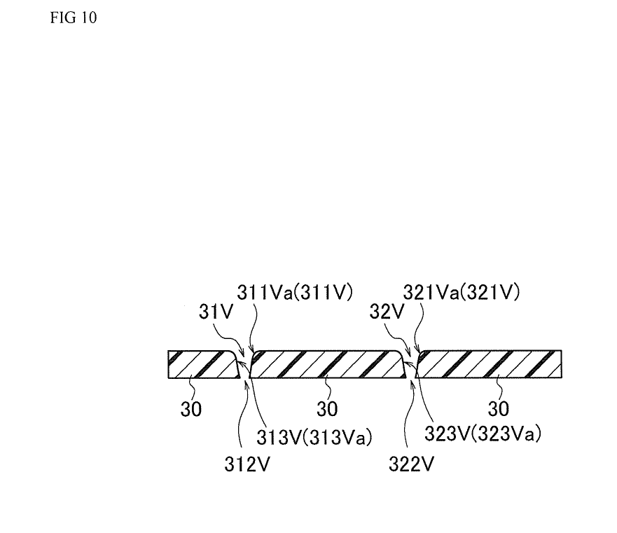

After the process or step for forming the holes 31V and 32V in the insulating base material 30, parts of the insulating base material 30 remaining at the bottom areas 312V and 322V of the holes 31V and 32V are removed. The holes 31V and 32V are thus caused to pass through, as shown in FIG. 10. The method for removing parts of the insulating base material 30 remaining at the bottom areas 312V and 322V includes such as, but not limited to, performing mechanical or chemical polishing from the upper surface or the lower surface of the insulating base material 30. For example, the holes 31V and 32V are caused to pass through by irradiating plasma, spraying chemical solution, or sandblasting etc. from the upper surface or the lower surface of the insulating base material 30.

Finally, a resist is applied to one main surface of the insulating base material 30 and the resist is patterned depending on wiring patterns using photolithography technique to form concave portions depending on the wiring patterns on the one main surface of the insulating base material 30. Thereafter, plating is performed to fill the holes 31V and 32V and the concave portions formed by the resist pattern with conductive material such as copper (Cu) or silver (Ag). This process may also be performed for the other main surface of the insulating base material 30. That is, after patterning the resist on the one main surface of the insulating base material 30, photolithography technique may also be used for the other main surface to pattern another resist, followed by plating. This process allows conductive material such as copper (Cu) or silver (Ag) to be filled in the holes 31V and 32V as well as upper layer concave portions formed on the one main surface side and lower layer concave portions formed on the other main surface side by the resist pattern. In other words, conductive material is filled during one time plating process in the holes 31V and 32V depending on via patterns and in the concave portions depending on wiring patterns of two sides to provide a wiring board in which interlayer conduction is achieved.

During this plating process, because the holes 31V and 32V in the present embodiment have: the inner walls 311Va and 321Va having curvatures around the opening areas 311V and 321V; and the slope walls 313Va and 323Va progressively decreasing in their inner diameters toward the lower surface, uniform seed layer may be evenly formed on the inner surfaces of the holes 31V and 32V by direct plating process (DPP) or sputtering process before plating. Further, the plated layer may be formed with uniform rate because the holes 31V and 32V in the present embodiment have: the inner walls 311Va and 321Va having curvatures around the opening areas 311V and 321V; and the slope walls 313Va and 323Va progressively decreasing in their inner diameters toward the lower surface, so that the plated layer with uniform metallurgical orientation will be formed above the inner surfaces of the holes 31V and 32V. In this way, the seed layer is formed with uniform condition, and the plated layer is thus allowed to be evenly formed thereon with uniform thickness above the inner surfaces of the holes 31V and 32V.

Moreover, the holes 31V and 32V in the present embodiment are so fine that the diameter of the opening areas 311V and 321V is 2 μm or more and 35 μm or less, preferably 2 μm or more and 15 μm or less, and further preferably 2 μm or more and less than 10 μm while the diameter of the bottom areas 312V and 322V of the holes 31V and 32V is 1 μm or more and 30 μm or less, preferably 1 μm or more and 10 μm or less, and further preferably 1 μm or more and 5 μm or less, and therefore, plating process enables to form solid filled-vias therein. Forming such fine holes 31V and 32V allows the filled-vias to be formed in a short amount of time. In addition, the reduced amount of time for plating allows for controlling the forming conditions for the plated layer to be constant thereby forming uniform plated layer.

In an alternative embodiment, conductive paste may be printed using a press plate on either the upper surface or the lower surface or both the upper surface and the lower surface of the insulating base material 30 to collectively form first wiring patterns 51 to 57, second wiring patterns 61 and 62 and the via patterns 11V and 12V conducting therebetween. If surplus portions of conductive material remain, they will be removed by polishing, etching or other appropriate means. A wiring board 100 is thus obtained.

If the wiring board 100 is made by the manufacturing method according to the present embodiment, there occurs no smear such as residue and dust during drilling, because steps for drilling the insulating base material 30 with laser is not included. Accordingly, desmear process is unnecessary thereby to reduce the steps therefor.

FIG. 11 illustrates wiring board 100 according to the present embodiment.

As shown in FIG. 11, the wiring board 100 in the present embodiment comprises: insulating base material 30; the first wiring patterns 51 to 57 formed on one main surface of the insulating base material 30; the second wiring patterns 61 and 62 formed on the other main surface; and via patterns 11V and 12V penetrating from the one main surface side to the other main surface side of the insulating base material 30 and conducting with the first wiring patterns 51 to 57 and the second wiring patterns 61 and 62. Note that the via patterns 11V and 12V in the present embodiment of this invention involve a concept including pillar-like conductive members formed in via holes which pass through the insulating base material 30.

The first wiring patterns 51 to 57 of the wiring board 100 according to the present embodiment are formed in convex-like shape from the one main surface of the insulating base material 30 toward outer side thereof (upper side in the figure).

The via patterns 11V and 12V in the present embodiment have, as shown in the figure, connection base portions 111V and 121V merging into the first wiring patterns 52 and 56 to have certain curvatures and cone-like portions 113V and 123V decreasing in their outer diameters as approaching the top head portions 112V and 122V of the via patterns 11V and 12V from the connection base portions 111V and 121V.

As shown in the figure, because the via patterns 11V and 12V in the present embodiment have curved surfaces 111Va and 121Va having certain curvatures with the first wiring patterns 52 and 56, and the via patterns 11V and 12V and the first wiring patterns 52 and 56 smoothly merge into one another via the curved surfaces 111Va and 121Va, reflection of electrical signal may be reduced even when the frequency comes to be high, thereby to suppress the loss.

Moreover, the via patterns 11V and 12V in the present embodiment are so-called filled-vias, which are solidly formed by conductive material without hollow spaces. The via patterns 11V and 12V and the first wiring patterns 51 to 57 in the present embodiment are formed by the same process (e.g. plating process) at the same time and under the same condition, thereby causing the orientation of metallic crystal in the conductive material to be uniform. This avoids interfaces from being generated within the via patterns 11V and 12V and within the connection portions between the via patterns 11V and 12V and the first wiring patterns 52 and 56. If portions with different orientations of metallic crystal are generated, then cracks are liable to occur in the via patterns due to those portions as sources. Such cracks may grow up under thermal load and/or mechanical load thereby making it difficult to maintain electrical connection in the wiring board. In contrast, no interface is generated in the via patterns 11V and 12V in the present embodiment, and cracks will thus be prevented from occurring thereby to achieve high connection reliability.

Although not particularly limited, the diameter of the connection base portions 111V and 121V of the via patterns 11V and 12V in the present embodiment, that is, the diameter of cross sections of the connection base portions 111V and 121V along the main surface of the insulating base material 30 is 2 μm or more and 35 μm or less, preferably 2 μm or more and 15 μm or less, and further preferably 2 μm or more and less than 10 μm. In addition, the diameter of the top head portions 112V and 122V of the via patterns 11V and 12V in the present embodiment is 1 μm or more and 30 μm or less, preferably 1 μm or more and 10 μm or less, and further preferably 1 μm or more and 5 μm or less. The length of the via patterns 11V and 12V in the present embodiment is 1 μm or more and 50 μm or less, and preferably 10 μm or more and 40 μm or less. The aspect ratio is 0.5 to 40, preferably 1 to 30, and may be selected as being about 1 to 4 in this example. The via patterns 11V and 12V in the present embodiment are such that the diameter of the connection base portions 111V and 121V is about 10 μm and the depth is about 15 μm.

The first wiring patterns 51 to 57 and the via patterns 11V and 12V of the wiring board 100 according to the present embodiment are integrally formed in a status where no interface exists because of being formed at the same time. Observing cross sections of the first wiring pattern 52 and the via pattern 11V and the first wiring pattern 56 and the via pattern 12V in the present embodiment along the penetrating direction by scanning ion microscopy (SIM), as shown in the schematic diagram of FIG. 12, crystal grains without interfaces may be observed. Similarly, within the connection base portion 111V of the via pattern 11V, merging into the first wiring pattern 52, and within the connection base portion 121 of the via pattern 12V, merging into the first wiring pattern 56, crystal grains without interfaces may be observed.

Via patterns 11V and 12V of the wiring board 100 formed by using the mold 1 according to the present embodiment are formed thereon with no corner area such as being formed by intersecting straight lines or flat planes. That is, the main surface of the insulating base material 30 and the first wiring patterns 52 and 56 and the connection base portions 111V and 121V of the via patterns 11V and 12V merge into one another with the curved surfaces 111Va and 121Va having certain curvatures, thereby to result in that the occurrence of signal reflection can be prevented when transmitting signals through the accomplished wiring board 100. Even if high frequency signals, regarded in general as readily causing signal reflection, are transmitted, the wiring board according to the present embodiment may prevent such signal reflection thereby to suppress the transmission loss of signals. This allows to result in providing the wiring board 100 with excellent transmission characteristics.

Furthermore, as in conventional manufacturing processes for a wiring board, the diameter of via patterns formed in the insulating layer using ultraviolet (UV) laser is restricted to be about 30 μm or more. In addition, via patterns with the diameter of about 10 μm may even be formed one by one in an insulating layer using excimer laser, but wiring boards increase in cost because the large amount of time for the process is required and gases to be used such as krypton fluoride (KrF) is expensive. In contrast, the manufacturing method for a wiring board according to the first embodiment of the present invention enables to efficiently manufacture the wiring board 100 having fine via patterns 11V and 12V using the mold 1.

### Second Embodiment

Hereinafter, a second embodiment will be described. The second embodiment involves a method of manufacturing a laminate-type wiring board using the wiring board 100 according to the first embodiment, and the laminate-type wiring board obtained by this manufacturing method. Detailed descriptions for common elements will be represented by those for the first embodiment.

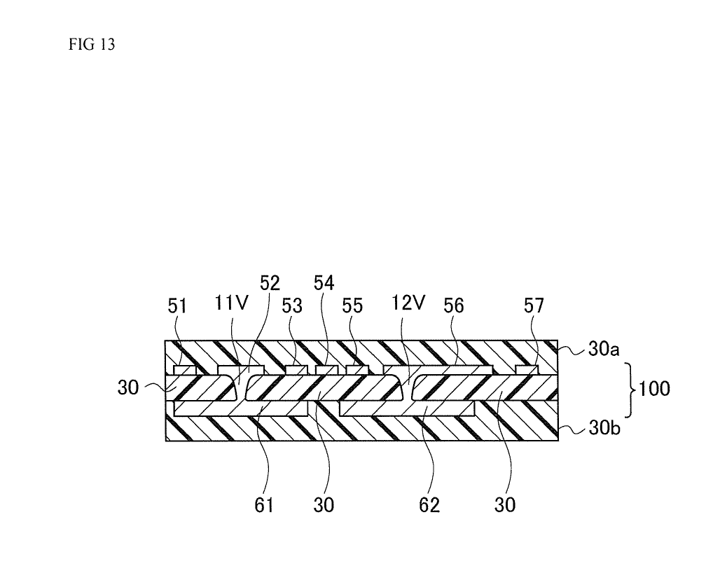

First with reference to FIG. 13 to FIG. 18, the manufacturing method for a laminate-type wiring board according to the second embodiment of the present invention will be described.

(1) The previously-described wiring board 100 shown in FIG. 11 is prepared first. As shown in FIG. 13, the wiring board 100 and insulating base materials 30a and 30b other than the insulating base material 30 used in this wiring board 100 are laminated respectively on the uppermost surface and the lowermost surface (exposed surfaces) of this wiring board 100 (first laminating process). As a material for the insulating base materials 30a and 30b, heat-curable resin such as epoxy resin or thermoplastic resin such as liquid crystal polymer may be used, for example. In view of preventing thermal contraction, the same material as the insulating base material 30 of the wiring board 100 may be used, but different materials may also be used.

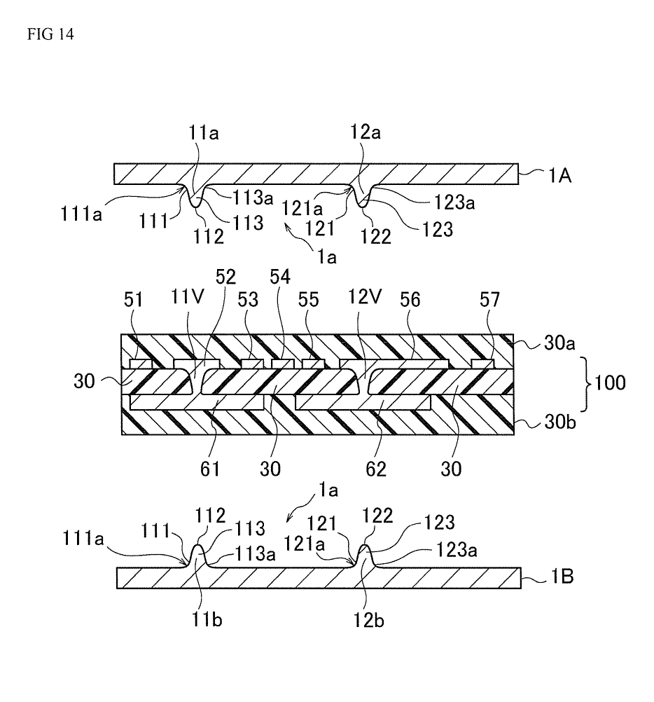

(2) Thereafter, two molds 1A and 1B are prepared. The structure of the molds 1A and 1B is common to that of the mold 1 shown in FIG. 5 and described in the first embodiment, so the description thereof is omitted here. As shown in FIG. 14, one mold 1A is located parallel to the insulating base material 30a laminated on the uppermost layer surface side of the wiring board 100 while the other mold 1B is located parallel to the insulating base material 30b laminated on the lowermost layer side of the wiring board 100. Top portions 112 and 122 of the protruding portions 11 and 12 formed on the stamping surfaces 1a of these two molds 1A and 1B oppose the insulating base materials 30a and 30b, respectively.

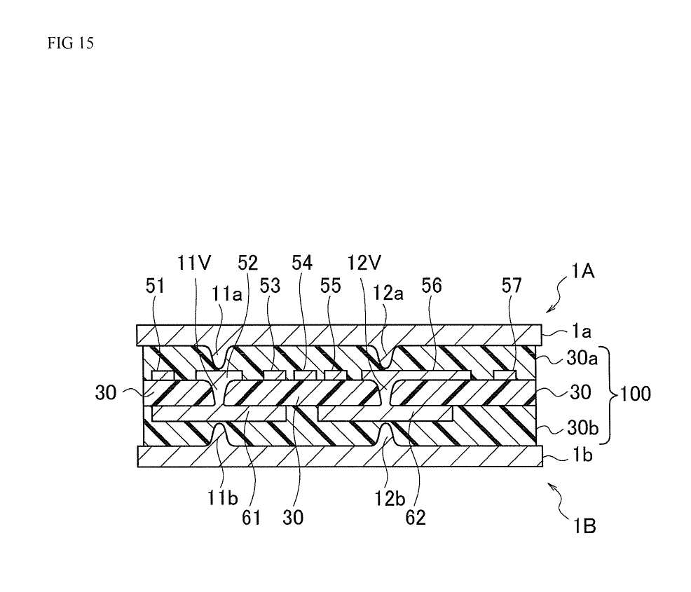

(3) The insulating base materials 30a and 30b are heated to a temperature equal to or above the glass transition temperature, and the molds 1A and 1B are caused to move toward the insulating base materials 30a and 30b such that the protruding portions 11a and 12a (11b and 12b) are pressed into the insulating base material 30a (30b), as shown in FIG. 15. The movement of the molds 1A and 1B may be performed concurrently or sequentially.

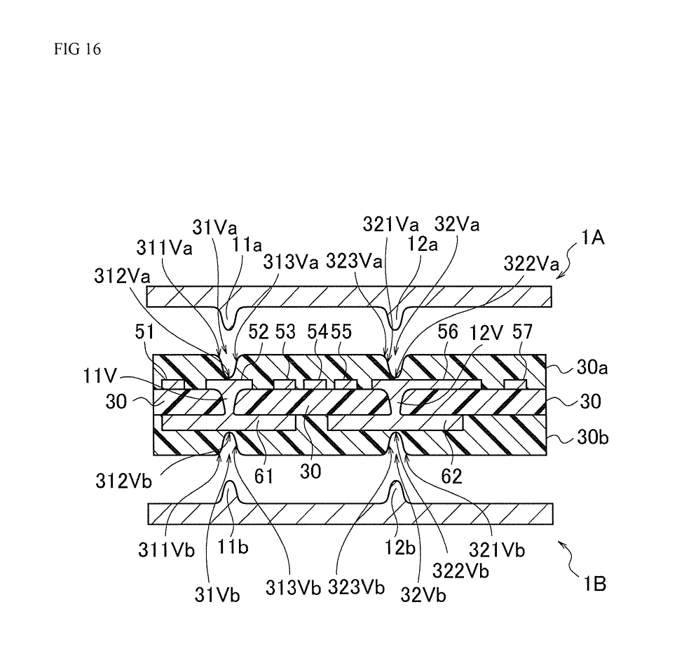

(4) Subsequently, as shown in FIG. 16, the molds 1A and 1B are released from the insulating base materials 30a and 30b, respectively. At this time, because the base portions 111 and 121 of the protruding portions 11a and 12a (11b and 12b) have certain curvatures, the releasing is more easily performed than the case where the protruding portions 11a and 12a (11b and 12b) merge into the stamping surface 1a with angles. If the insulating base materials 30a and 30b are of heat-curable resin, then they are cured by heating in an oven or the like. If, on the other hand, the insulating base materials 30a and 30b are of thermoplastic resin, then they are cured by cooling.

As shown in the figure, after the release of the molds 1A and 1B, the insulating base material 30a (30b) is formed therein holes 31Va and 32Va (31Vb and 32Vb) depending on the shapes of the protruding portions 11a and 12a (11b and 12b) of the mold 1A (1B) (second laminating process).

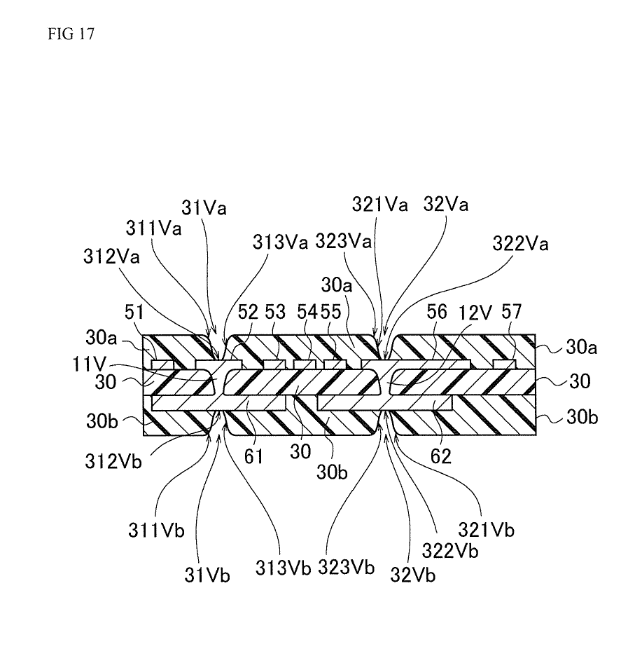

(5) If, as shown in the figure, bottom areas 312Va and 322Va (312Vb and 322Vb) of the holes 31Va and 32Va (31Vb and 32Vb) of the insulating base material 30a (30b) are not passed through and resins remain there, then irradiating plasma, spraying chemical solution, or sandblasting process is performed from the inner walls 311Va and 321Va (311Vb and 321Vb). Thereafter, as shown in FIG. 17, the bottom areas 312Va and 322Va (312Vb and 322Vb) of the holes 31Va and 32Va (31Vb and 32Vb) are caused to pass through.

(6) Resists are applied to main surfaces (exposed surfaces) of the insulating base materials 30a and 30b and the resists are patterned depending on wiring patterns using photolithography technique to form concave portions depending on the wiring patterns on the main surfaces of the insulating base materials 30a and 30b (third laminating process).

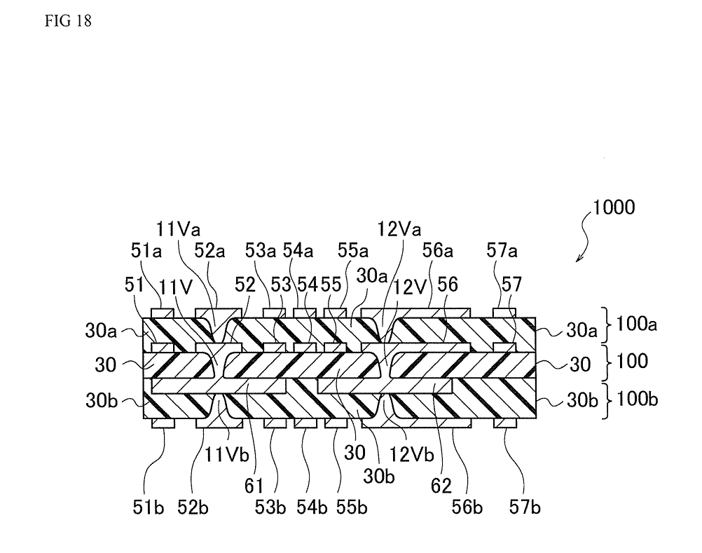

Thereafter, plating is performed to fill the holes 31Va and 32Va (31Vb and 32Vb) and the concave portions formed by the resist pattern with conductive material such as copper (Cu) or silver (Ag). This process or step allows conductive material to be filled in the holes 31Va and 32Va (31Vb and 32Vb) and the concave portions depending on the wiring patterns, thereby forming via patterns 11Va and 12Va (11Vb and 12Vb) and wiring patterns 51a to 57a (51b to 57b), as shown in FIG. 18 (fourth laminating process).

According to the first laminating process to the fourth laminating process, a laminate-type wiring board 1000 can be obtained in which interlayer conduction is achieved for the wiring board 100. The above-described first laminating process to the fourth laminating process may be repeated a number of times depending on the target laminating number of the wiring board 1000. Of course, in respective layers, the first wiring patterns 51 to 57, 51a to 57a and 51b to 57b and second wiring patterns 61 and 62 may be of substantially the same shape, or may also be of different shapes.

The manufacturing method for a wiring board according to the second embodiment of the present invention enables to produce with high production efficiency the laminate-type wiring board 1000 having fine via patterns 11Va and 12Va (11Vb and 12Vb) using the molds 1A and 1B.

As shown in FIG. 18, the first wiring patterns 51 to 57 are formed on one main surface of the insulating base material 30 of the wiring board 100 located at the center, while the second wiring patterns 61 and 62 are formed on the other main surface thereof. The via patterns 11V and 12V, which are integrally formed therewith and electrically conductive thereto, merge into the first wiring patterns 52 and 56 with curved surfaces. Further, the via patterns 11V and 12V are tapered from the first wiring patterns 52 and 56 side toward the second wiring patterns 61 and 62 side.

In addition, as shown in the figure, another wiring board 100a is laminated on one main surface side of the wiring board 100 (upper side of the figure), while yet another wiring board 100b is laminated on the other main surface side of the wiring board 100. The first wiring patterns 51a to 57a are formed on one main surface side of the insulating base material 30a of the wiring board 100a (upper side of the figure). The via patterns 11Va and 12Va, which are integrally formed with the first wiring patterns 51a to 57a and electrically conductive with the first wiring patterns 51a to 57a and the first wiring patterns 51 to 57 of the wiring board 100, merge into the first wiring patterns 52a and 56a with curved surfaces. Further, the via patterns 11Va and 12Va are tapered from the first wiring patterns 52a and 56a side toward the first wiring patterns 52 and 56 side of the wiring board 100.

Moreover, the first wiring patterns 51b to 57b are formed on the other main surface side of the insulating base material 30b of the wiring board 100b (lower side of the figure). The via patterns 11Vb and 12Vb, which are integrally formed with the first wiring patterns 51b to 57b and electrically conductive with the first wiring patterns 51b to 57b and the second wiring patterns 61 and 62 of the wiring board 100, merge into the first wiring patterns 52b and 56b with curved surfaces. Further, the via patterns 11Vb and 12Vb are tapered from the first wiring patterns 52b and 56b side toward the second wiring patterns 61 and 62 side of the wiring board 100.

In addition, similar to the via patterns 11V and 12V as described in the first embodiment, the via patterns 11Va and 12Va and via patterns 11Vb and 12Vb are integrally formed with the first wiring patterns 52a and 56a and 52b and 56b in a status where no interface exists.

The via patterns 11Va and 12Va and via patterns 11Vb and 12Vb in the laminate-type wiring board 1000 in the present embodiment comprise similar configuration as the via patterns 11V and 12V in the first embodiment, so that the laminate-type wiring board 1000 according to the present embodiment provides functionalities and advantageous effects like the single layer wiring board 100 according to the first embodiment.

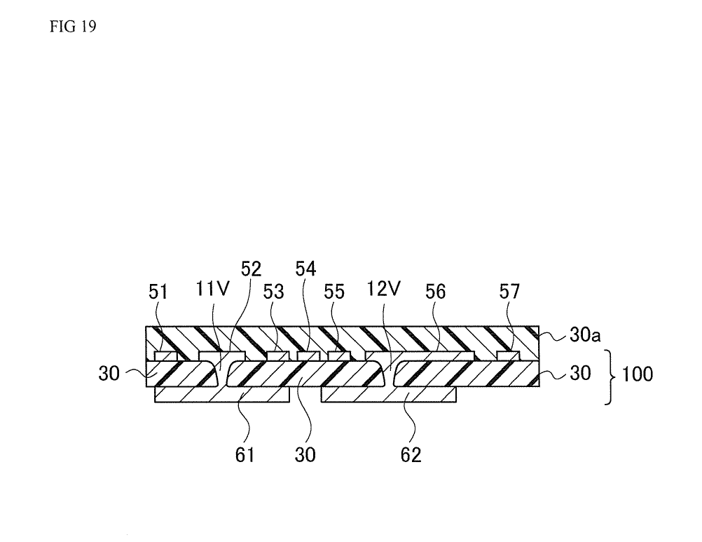

With reference to FIG. 19 to FIG. 24, a manufacturing method (modified example) will then be described which is common to the second embodiment in using the manufacturing method according to the first embodiment, but the laminating manner is different from the second embodiment.

(1) The wiring board 100 shown in FIG. 11 and obtained by the manufacturing method according to the first embodiment is prepared first. Another insulating base material 30a is then laminated, as shown in FIG. 19, on the uppermost surface (upper side in the figure) of the wiring board (first laminating process). The same material as the second embodiment may be used for the insulating base material 30a.

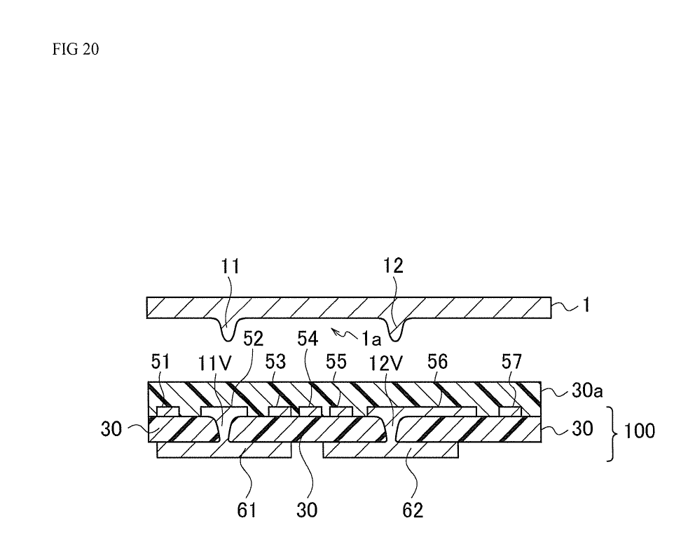

(2) The mold 1 is prepared. The same mold 1 as shown in FIG. 5 and used in the manufacturing method of the first embodiment is used. As shown in FIG. 20, the mold 1 is located parallel to the wiring board 100, and the stamping surface 1a of the mold 1 is arranged to oppose the main surface of the insulating base material 30a.

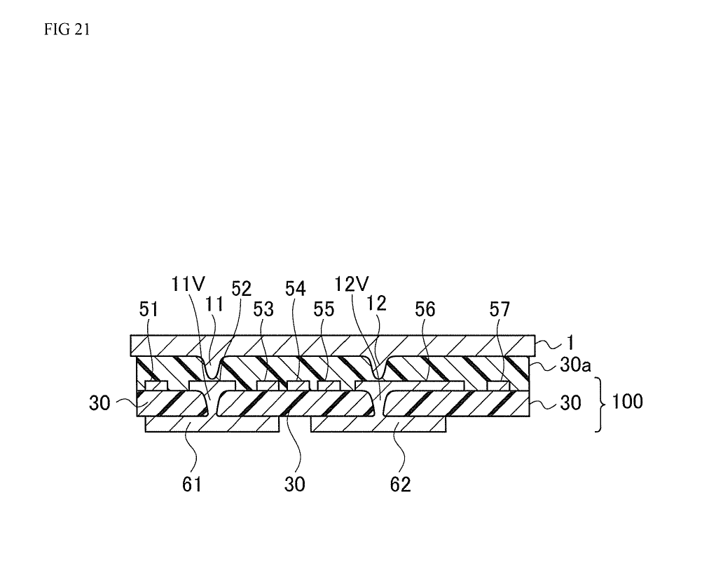

(3) The insulating base material 30a is heated to a temperature equal to or above the glass transition temperature, and the mold 1 is caused to move toward the insulating base material 30a such that the protruding portions 11 and 12 are pressed into the insulating base material 30a, as shown in FIG. 21.

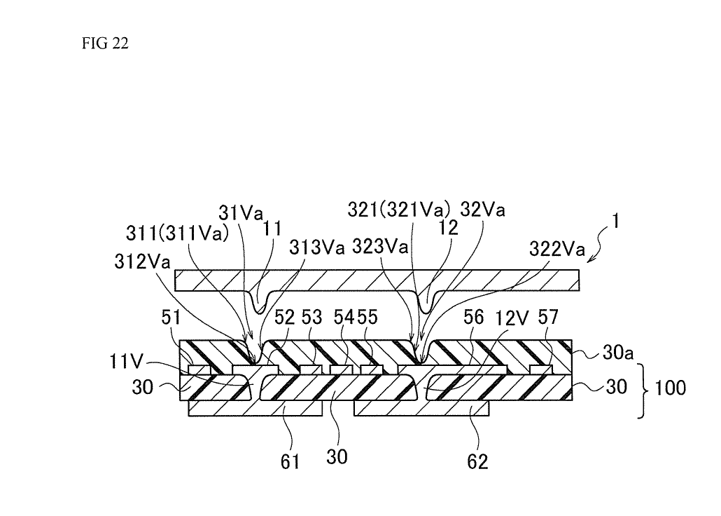

(4) Subsequently, as shown in FIG. 22, the mold 1 is released from the insulating base material 30a, and the insulating base material 30a is cured. As shown in the figure, after the release of the mold 1, the insulating base material 30a has been formed therein holes 31Va and 32Va depending on the shapes of the protruding portions 11 and 12 of the mold 1 (second laminating process).

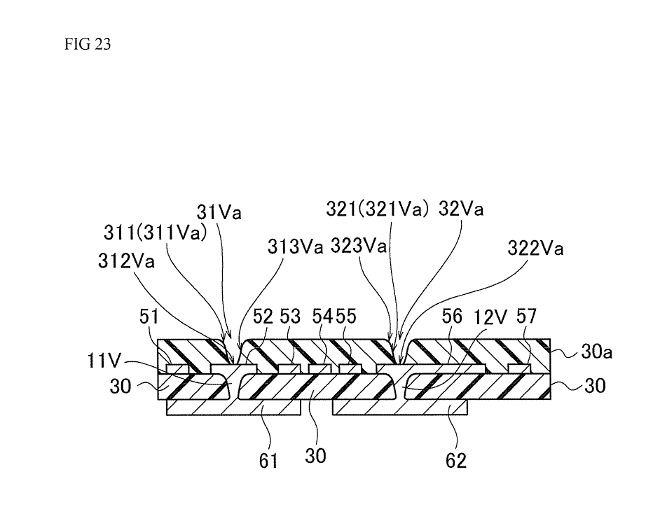

(5) If, as shown in the figure, bottom areas 312Va and 322Va of the holes 31Va and 32Va of the insulating base material 30a are not passed through and resins remain there, then irradiating plasma, spraying chemical solution, or sandblasting process is performed from the opening areas 311V and 321V, and the bottom areas 312Va and 322Va of the holes 31Va and 32Va are caused to pass through, as shown in FIG. 23.

(6) A resist is applied to the main surface (exposed surface) of the insulating base materials 30a and the resist is patterned depending on wiring patterns using photolithography technique to form concave portions depending on the wiring patterns on the main surface of the insulating base material 30a (third laminating process).

Thereafter, plating is performed to fill the holes 31Va and 32Va and the concave portions formed by the resist pattern with conductive material such as copper (Cu) or silver (Ag). This process allows conductive material to be filled in the holes 31Va and 32Va and the concave portions depending on the wiring patterns, thereby forming via patterns 11Va and 12Va (fourth laminating process).

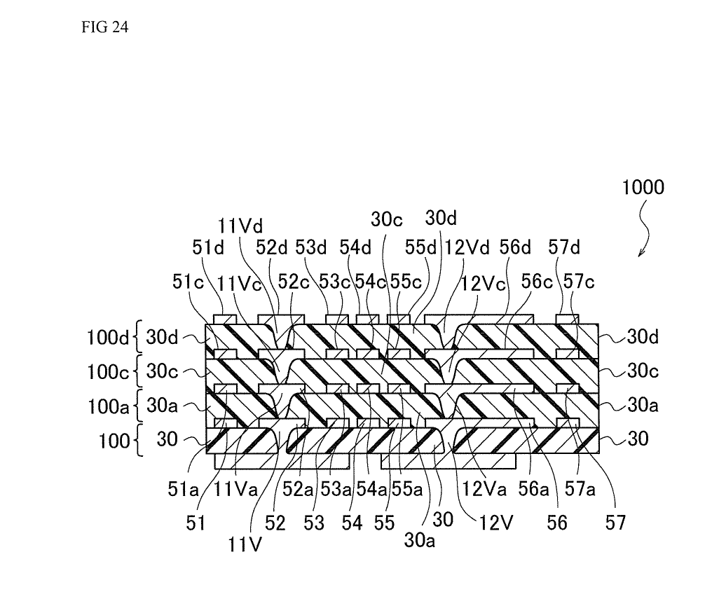

(7) According to the above-described first laminating process to the fourth laminating process, a laminate-type wiring board 1000 can be obtained, as shown in FIG. 24, in which interlayer conduction is achieved for the wiring board 100. The above-described first laminating process to the fourth laminating process may be repeated a number of times depending on the target laminating number of the wiring board 1000. The wiring board 1000 shown in the figure is one example of four-layer laminated wiring board 1000 in which three layers of wiring boards 100a, 100c and 100d are laminated on the wiring board 100 through repeating three times the first laminating process to the fourth laminating process. In respective layers, the first wiring patterns 51 to 57, 51a to 57a, 51c to 57c and 51d to 57d and second wiring patterns 61 and 62 may be of the same shape, or may also be of different shapes.

Likewise the wiring board 1000 in the second embodiment, the present example is such that the via patterns 11Va and 12Va, via patterns 11Vc and 12Vc, and via patterns 11Vd and 12Vd are integrally formed with the first wiring patterns 51a to 57a, 51c to 57c, and 51d to 57d without interfaces similar to the via patterns 11V and 12V described in the first embodiment. In addition, the via patterns 11Va and 12Va, via patterns 11Vc and 12Vc, and via patterns 11Vd and 12Vd merge into the first wiring patterns 51a to 57a, 51c to 57c, and 51d to 57d, respectively, with curved surfaces, and are of tapered shapes from those connection portions toward the ends of the via patterns.

Thus, the via patterns 11Va and 12Va, via patterns 11Vc and 12Vc, and via patterns 11Vd and 12Vd in the laminate-type wiring board 1000 of the present example comprise similar configuration as the via patterns 11V and 12V in the first embodiment, so that the laminate-type wiring board 1000 according to the present embodiment provides functionalities and advantageous effects like the single layer wiring board 100 according to the first embodiment.

### Third Embodiment

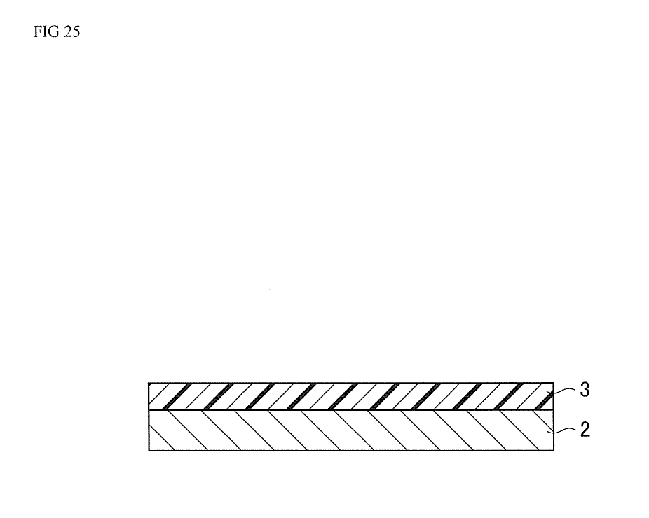

With reference to FIG. 25 to FIG. 37, a manufacturing method for a wiring board of the third embodiment and a wiring board 100 manufactured by this manufacturing method will be hereinafter described. Since the manufacturing method for a wiring board according to the present embodiment and the wiring board 100 manufactured by this manufacturing method essentially share common entities with the wiring board 100 in the first embodiment, descriptions for common entities will be represented by those for the first embodiment and different parts will primarily be described in order to avoid redundancy.

The manufacturing method for a wiring board in the present embodiment has the following two processes in broad terms: a process for preparing a mold to be used; and a process for producing a wiring board using the prepared mold. The manufacturing method for a mold and the manufactured mold will be described first, and the manufacturing method for a wiring board using this mold and the manufactured wiring board will then be described.

The manufacturing method for a mold according to the present embodiment has a step for preparing a cured resin plate body, a step for irradiating laser or electron beam to a main surface of the resin plate body depending on via patterns thereby to form holes, a step for laminating a resist layer on the main surface of the resin plate body formed therein the holes, a step for removing a predetermined region of the resist layer including opening areas of the holes by photolithography method, and a step for using a mold material to cover the resist layer removed therefrom the predetermined region and the main surface of the resin plate body.

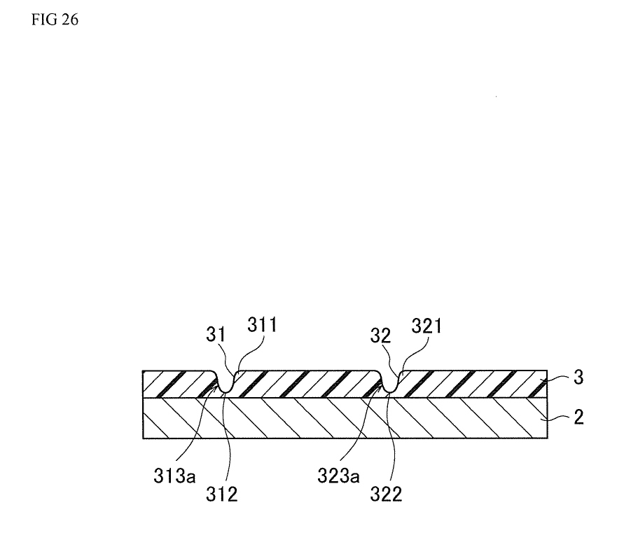

Each step will be specifically described. Like the first embodiment, a laminate of resin plate body 3 and supporting plate 2 as shown in FIG. 25 is prepared, and the resin plate body 3 is cured. Materials for the resin plate body 3 and the supporting plate 2 are similar to the first embodiment. Subsequently, as shown in FIG. 26, laser or electron beam (EB) is irradiated to the main surface of the resin plate body 3 to form holes 31 and 32 in a similar manner to the first embodiment. Inner walls of opening areas 311 and 321 of the holes 31 and 32 of the resin plate body 3 according to the present embodiment are formed to merge into the main surface of the resin plate body 3 with curved surfaces having certain curvatures. Further, the holes 31 and 32 have slope walls 313a and 323a inclined with respect to the depth direction and merge into the opening areas 311 and 321, and the slope walls 313a and 323a merge into bottom areas 312 and 322.

Although not particularly limited, the diameter of the opening areas 311 and 321 of the holes 31 and 32 in the present embodiment is 2 μm or more and 35 μm or less, preferably 2 μm or more and 15 μm or less, and further preferably 2 μm or more and less than 10 μm. In addition, the diameter of the bottom areas 312 and 322 of the holes 31 and 32 in the present embodiment is 1 μm or more and 30 μm or less, preferably 1 μm or more and 10 μm or less, and further preferably 1 μm or more and 5 μm or less. The depth is 1 μm or more and 50 μm or less, and preferably 10 μm or more and 40 μm or less. For one example, the holes 31 and 32 in the present embodiment are such that the diameter is about 10 μm and the depth is about 15 μm.

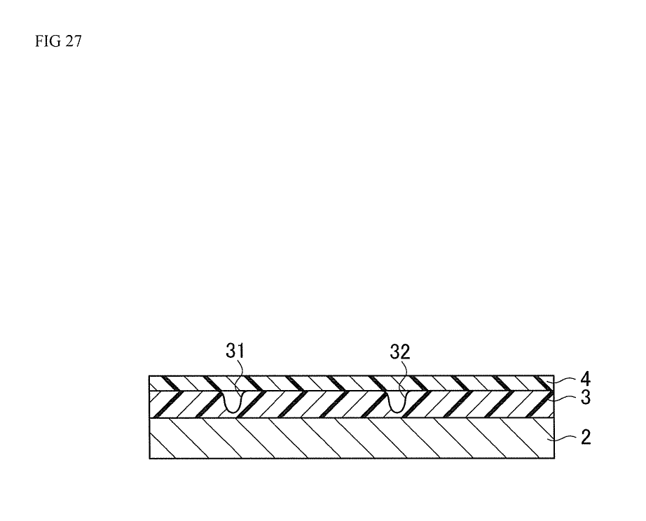

Subsequently, as shown in FIG. 27, a resist layer 4 is formed on the resin plate body 3 so as not to fill the holes 31 and 32. As the resist layer 4, a film-like material soluble in alkali or acid and with thickness of about 5 to 20 μm may be used.

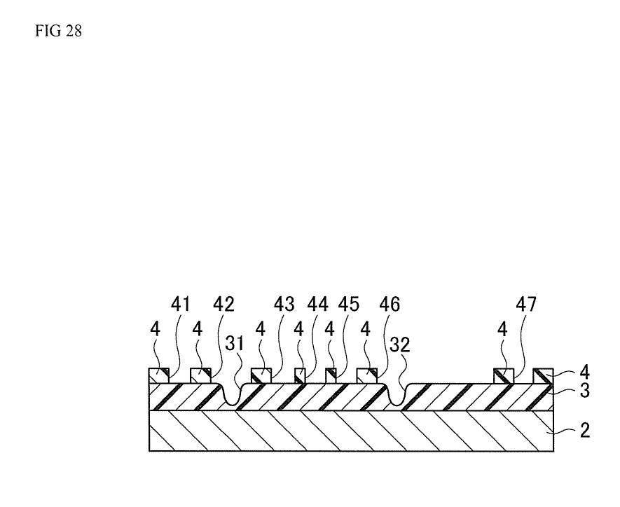

Thereafter, as shown in FIG. 28, photolithography method is employed to remove a predetermined region of the resist layer 4, which includes regions covering opening area regions of the holes 31 and 32, depending on wiring patterns. Specifically, patterning is performed in which a photomask and an exposure apparatus are used to expose the resist layer 4 and the predetermined region of the resist layer 4 is selectively removed through alkaline development or acidic development. As a result of this, the opening area regions of the holes 31 and 32 are opened (come to be a state where the holes 31 and 32 are not closed), and trenches 41 to 47 of the resist layer 4 are formed. The formed trenches 42 and 46 merge into the previously formed holes 31 and 32, and step-like (two-stage shaped) patterns are defined by the main surface of the resin plate body 3, which merges into opening areas 311 and 321 of the holes 31 and 32, and the main surface (on the side of light source of the exposure) of the resist layer 4, which forms the trenches 42 and 46. Although not particularly limited, line-and-space area configured by the trenches 41 to 47 may be such that the wiring width is about 5 to 20 μm and the wiring space is also about 5 to 20 μm, and the land diameter of via patterns may be 50 to 120 μm.

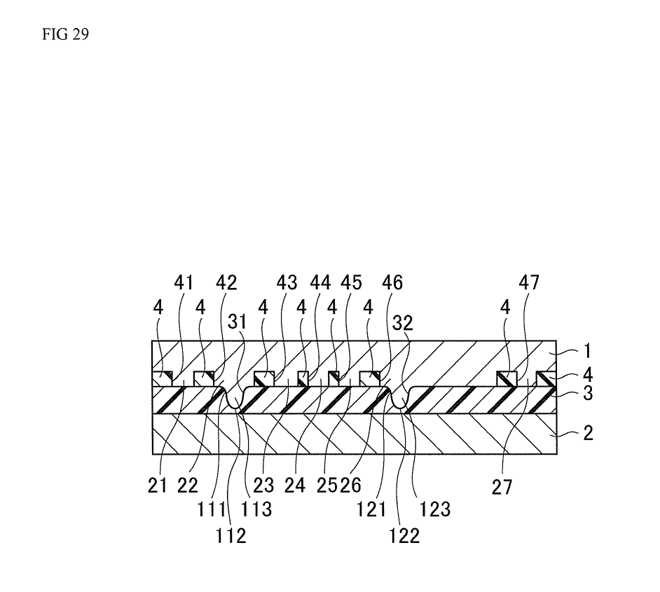

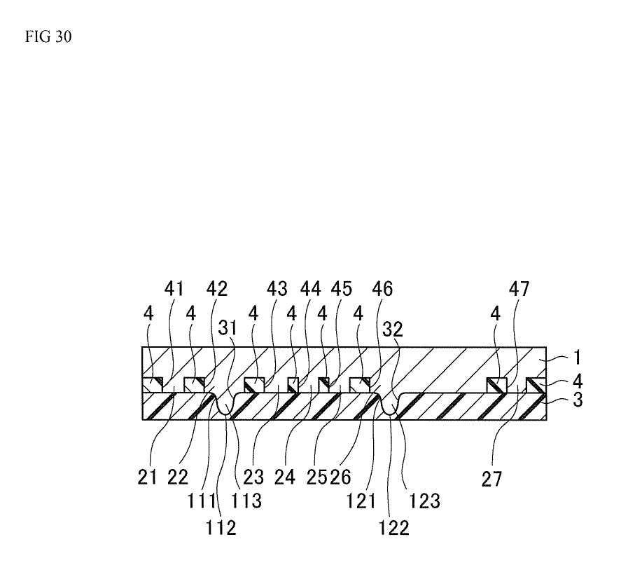

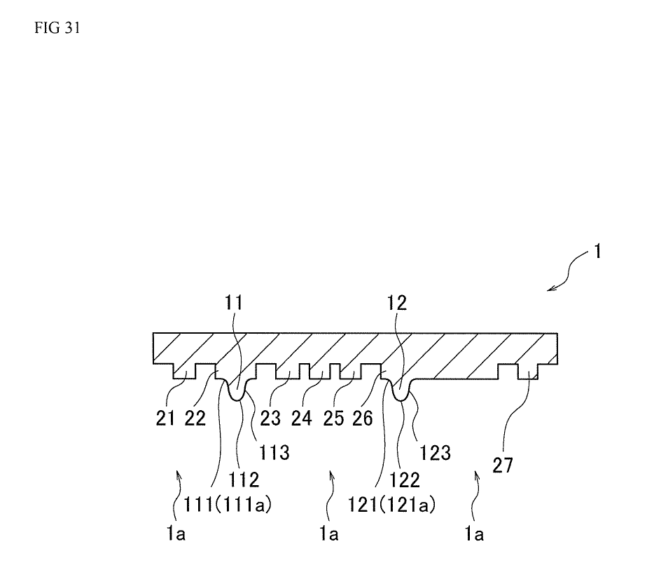

Subsequently, in a similar manner to the first embodiment, a conductive layer to be a seed layer for the subsequent plating process or the like is formed. Thereafter, as shown in FIG. 29, a mold material is used to cover the resist layer 4 removed therefrom the predetermined region including regions covering opening area regions, and the main surface of the resin plate body 3. Specifically, plating process is performed to fill the holes 31 and 32 formed in the resin plate body 3 and the trenches 41 to 47 with the mold material and cover the upper surface and side surfaces of the resist layer 4 and the main surface of the resin plate body 3 with the mold material. Approaches for plating and other treatments are common to those in the first embodiment. Thereafter, as shown in FIG. 30, the supporting plate 2 is removed by using etching liquid such as ferric chloride solution. Finally, the resin plate body 3 is also removed through swelling by using aqueous solution of sodium hydroxide or other appropriate liquid, and the mold 1 as shown in FIG. 31 is obtained.

The manufacturing method for the mold 1 according to the present embodiment of this invention forms the two-stage shaped patterns having the holes 31 and 32 by laser or electron beam and the trenches 41 to 47, thereby to allow for forming protruding portions 11 and 12 and convex portions 21 to 27 through one time plating process (one step or one process).

As an approach to form protruding portions for forming via patterns and convex portions for forming wiring patterns, a construction method is known in which steps of photolithography, plating and polishing are repeated to build up respective portions. The present embodiment forms the holes 31 and 32 for via patterns using laser or other means, followed by the formation of the trenches 41 to 47 for wiring patterns, thereafter filling the holes 31 and 32 and the trenches 41 to 47 with the mold material in one step or one process, and therefore, the present embodiment requires no polishing step for top portions of protruding portions for via patterns thereby to simplify the steps or processes, compared to the conventional approach where convex portions for wiring patterns are formed and protruding portions for via patterns are then formed on those convex portions. Note that the holes 31 and 32 may be formed in the underlying resin plate body after patterning the resist layer 4.

Moreover, the present embodiment provides functionalities and advantageous effects like the first embodiment because this embodiment forms the holes 31 and 32 using laser or electron beam thereby to allow for forming the protruding portions 11 and 12 which have the base portions 111 and 121 smoothly merging into the upper surface of the convex portions 12 and 16 to have certain curvatures, and which may not be obtained by photolithography process.

As shown in FIG. 31, stamping surface 1a of the mold 1 according to the present embodiment of this invention is formed thereon with the protruding portions 11 and 12, which are formed depending on via patterns, and the convex portions 21 to 27, which are formed depending on wiring patterns. The via patterns and the wiring patterns constitute patterns of a wiring board. The protruding portions 11 and 12 have base portions 111 and 121 merging into the upper surface of the convex portions 21 to 27, and slope portions 113 and 123 decreasing in their outer diameters as approaching top portions 112 and 122 of the protruding portions 11 and 12 from the base portions 111 and 121. In other words, the base portions 111 and 121 of the protruding portions 11 and 12, which depend on via patterns, merge into the upper surface of the convex portions 21 to 27 (surfaces parallel to the main surface of the stamping surface 1a, here and hereinafter) with curved surfaces 111a and 121a. More specifically, the protruding portions 11 and 12 have the top portions 112 and 122 higher than the convex portions 21 to 27, and the base portions 111 and 121 connected to the upper surface of the convex portions 22 and 26 with the curved surfaces 111a and 121a having certain curvatures. No interface exists between the stamping surface 1a and the convex portions 21 to 27 and between the convex portions 22 and 26 and the protruding portions 11 and 12, and the mold 1 is thus formed integrally. Like the first embodiment, copper (Cu) or other appropriate material may be used as the mold material for constituting the mold 1.

As shown in the figure, the protruding portions 11 and 12 in the present embodiment have the top portions 112 and 122, respectively, which are configured with curved surfaces. Note that shapes of the protruding portions 11 and 12 may be formed in a similar approach to the previously-described embodiments.

Although not particularly limited, the diameter of the base portions 111 and 121 of the protruding portions 11 and 12 is 2 μm or more and 35 μm or less, preferably 2 μm or more and 15 μm or less, and further preferably 2 μm or more and less than 10 μm. In addition, the diameter of the top portions 112 and 122 of the protruding portions 11 and 12 in the present embodiment is 1 μm or more and 30 μm or less, preferably 1 μm or more and 10 μm or less, and further preferably 1 μm or more and 5 μm or less. Further, the length of the protruding portions 11 and 12 in the present embodiment is 1 μm or more and 50 μm or less, and preferably 10 μm or more and 40 μm or less. The aspect ratio is 0.5 to 40, preferably 1 to 30, and may be selected as being about 1 to 4 in this example.

The mold 1 in the present embodiment is configured such that the base portions 111 and 121 of the protruding portions 11 and 12 are smoothly connected to the upper surface (surface parallel to the stamping surface 1a) of the convex portions 21 to 27 to have certain curvatures, thereby providing functionalities and advantageous effects like the first embodiment.

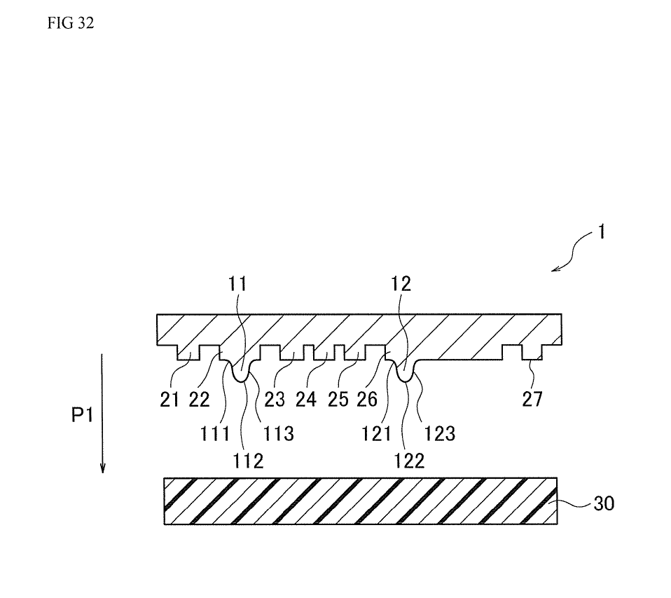

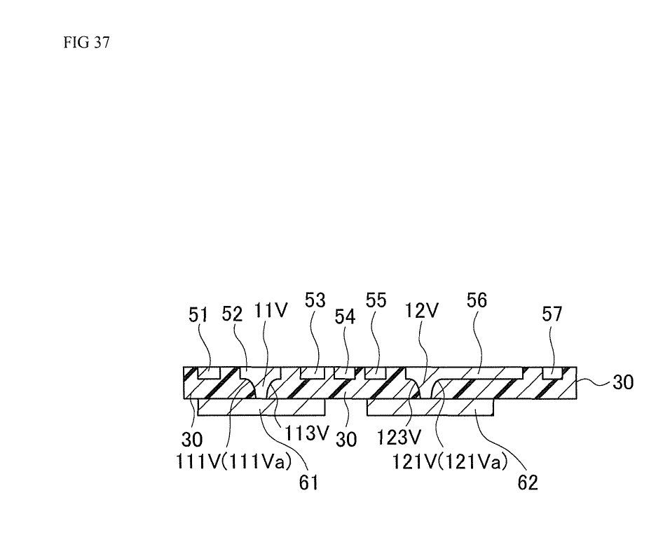

Hereinafter, a manufacturing method for a wiring board using the mold 1 will be described with reference to FIG. 32 to FIG. 36, and the manufactured wiring board will then be described with reference to FIG. 37.

In the present embodiment, a wiring board is obtained by so-called imprinting method using the above-described mold 1 shown in FIG. 31.

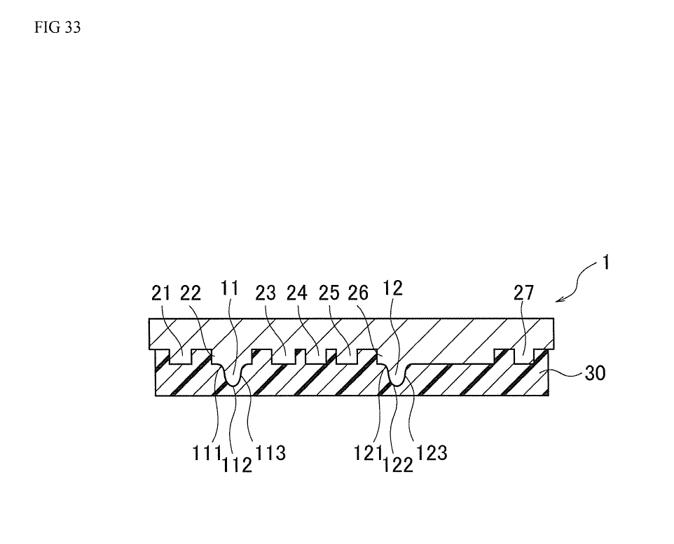

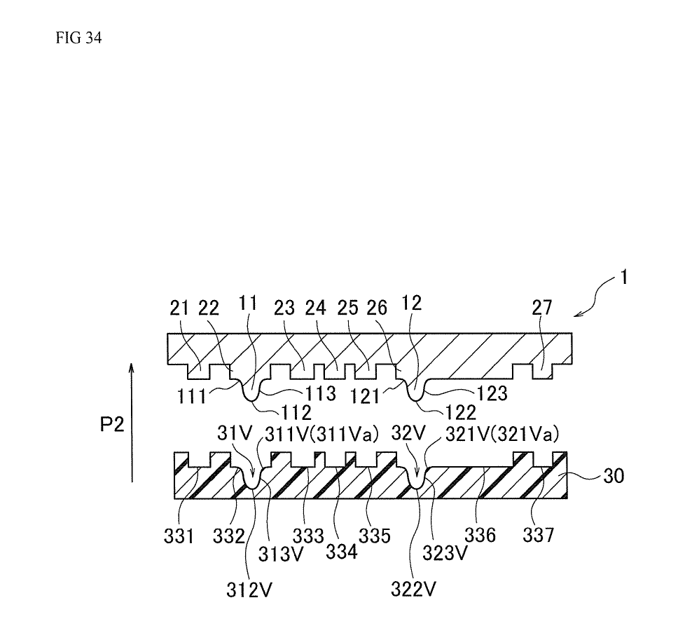

As shown in FIG. 32, the mold 1, and an insulating base material (resin film) 30 for transfer which is to constitute a wiring board, are prepared first and they are arranged such that the main surface of the mold 1 opposes the main surface of the insulating base material 30. The material for the insulating base material 30 is the same as that for the first embodiment. The mold 1 is caused to move along arrow P1 shown in FIG. 32, and mold clamping is performed as shown in FIG. 33. The mold 1 and the insulating base material 30 are cooled below the glass transition temperature (Tg), and the mold 1 is released in the direction where the mold 1 is separated from the insulating base material 30 (arrow P2), as shown in FIG. 34. If the insulating base material 30 is heat-curable resin, then the insulating base material 30 is fully cured by heating at 160 to 200 degrees C., for example, during 40 to 80 minutes in an oven or the like. If, on the other hand, the insulating base material 30 is thermoplastic resin, then it is cured by cooling.

This allows for transferring the patterns (including via patterns and wiring patterns, here and hereinafter) of the stamping surface 1a of the mold 1 to the main surface of the insulating base material 30. As shown in the figure, after releasing the mold 1, the insulating base material 30 is formed therein holes 31V and 32V depending on the shapes of the protruding portions 11 and 12 of the mold 1, and concave portions 331 to 337.

As shown in FIG. 34, these holes 31V and 32V have: inner walls 311Va and 321Va having certain curvatures around opening areas 311V and 321V; and slope walls 313Va and 323Va gradually decreasing in inner diameters thereof toward the bottom surfaces. Specifically, the holes 31V and 32V having been formed in the insulating base material 30 are such that the inner walls 311Va and 321Va having certain curvatures are formed within the opening areas 311V and 321V, and merge into the concave portions 331 to 337 of the insulating base material 30. These holes 31V and 32V have body areas 313V and 323V comprising the slope walls 313Va and 323Va which decrease in their diameters as approaching the bottom areas 312V and 322V from the opening areas 311V and 321V. Although not particularly limited, the diameter of the opening areas 311V and 321V of the holes 31V and 32V in the present embodiment is 2 μm or more and 35 μm or less, preferably 2 μm or more and 15 μm or less, and further preferably 2 μm or more and less than 10 μm. In addition, the diameter of the bottom areas 312V and 322V of the holes 31V and 32V in the present embodiment is 1 μm or more and 30 μm or less, preferably 1 μm or more and 10 μm or less, and further preferably 1 μm or more and 5 μm or less. The depth is 1 μm or more and 50 μm or less, and preferably 10 μm or more and 40 μm or less. For one example, the holes 31V and 32V in the present embodiment are such that the diameter is about 10 μm and the depth is about 15 μm.

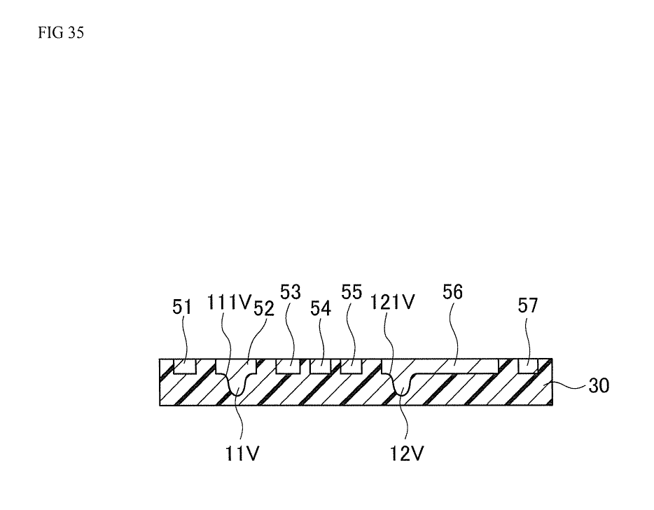

As shown in FIG. 35, first wiring patterns 51 to 57 and via patterns 11V and 12V are formed by plating or printing/sintering conductive paste to fill the concave portions 331 to 337 and the holes 31V and 32V with the conductive material. If surplus portions of nano-paste remain, they will be removed by polishing, etching or other appropriate means.

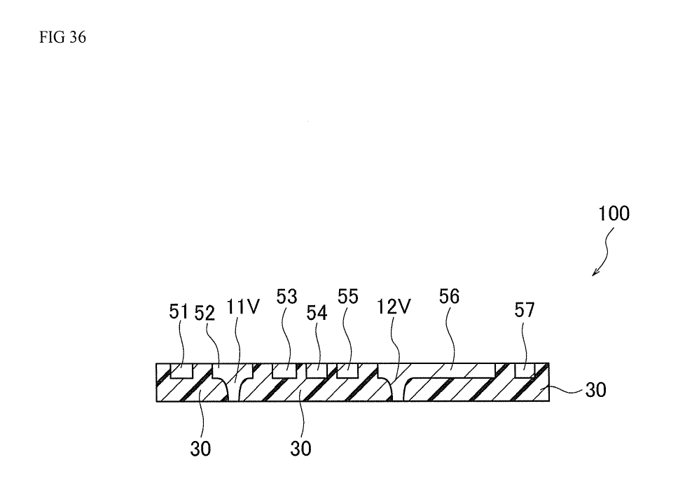

If the mold 1 has not penetrated the insulating base material 30 and resins remain on the ends of the via patterns 11V and 12V, as shown in FIG. 35, then they may be chemically or mechanically polished and removed to expose these ends of the via patterns 11V and 12V from the lower surface of the insulating base material 30, as shown in FIG. 36.

Subsequently, the other main surface (lower side surface in the figure) of the insulating base material 30 is subjected to a process for plating or printing/sintering conductive paste, and second wiring patterns 61 and 62 are thus formed to be conductive with the via patterns 11V and 12V.

FIG. 37 illustrates wiring board 100 according to the present embodiment. As shown in FIG. 37, the wiring board 100 in the present embodiment comprises: insulating base material 30; first wiring patterns 51 to 57 formed on one main surface of the insulating base material 30; second wiring patterns 61 and 62 formed on the other main surface of the insulating base material 30; and via patterns 11V and 12V penetrating from the one main surface side to the other main surface side of the insulating base material 30 and conducting with the first wiring patterns 51 to 57 and the second wiring patterns 61 and 62.

The first wiring patterns 51 to 57 of the wiring board 100 according to the present embodiment are formed on the one main surface of the insulating base material 30 in a status where they are embedded in convex-like shape from the main surface of the insulating base material 30 toward the inner side. As shown in FIG. 37, upper surface of the first wiring patterns 51 to 57 are of the same height as the main surface of the insulating base material 30, and there is no level difference between the main surface of the insulating base material 30 and the upper surface of the first wiring patterns 51 to 57. That is, even though the first wiring patterns 51 to 57 are formed, the main surface of the insulating base material 30 can be flat. Accordingly, other components may be mounted on the insulating base material 30, which is embedded therein with the first wiring patterns 51 to 57, without being restricted in regard to placing positions. Moreover, entirely flat laminate-type wiring board can be produced even when one or more additional wiring boards 100 are laminated on that wiring board 100.

The via patterns 11V and 12V in the present embodiment have, as shown in the figure, connection base portions 111V and 121V merging into the first wiring patterns 52 and 56 to have certain curvatures, and cone-like portions 113V and 123V decreasing in their outer diameters as approaching top head portions 112V and 122V of the via patterns 11V and 12V from the connection base portions 111V and 121V.

As shown in the figure, because the via patterns 11V and 12V in the present embodiment have curved surfaces 111Va and 121Va having certain curvatures with the first wiring patterns 52 and 56, and the via patterns 11V and 12V and the first wiring patterns 52 and 56 smoothly merge into one another via the curved surfaces 111Va and 121Va and are integrally formed, the present embodiment has functionalities and advantageous effects like the wiring board according to the first embodiment.

In addition to the advantageous effects obtained in the wiring board according to the first embodiment of the present invention, the present embodiment utilizes the two-stage shaped mold 1 to coincidentally form the first wiring patterns 51 to 57 and the via patterns 11V and 12V, thereby enabling to provide the wiring board 100 in high accuracy in which production errors are reduced, such as pitches among the first wiring patterns 51 to 57 and the via patterns 11V and 12V and the positional relationship thereof.

Moreover, the present embodiment utilizes the two-stage shaped mold 1 to coincidentally form the first wiring patterns 51 to 57 and the via patterns 11V and 12V, thereby enabling to collectively produce the via patterns 11V and 12V and the first wiring patterns 51 to 57 through one plating process. Therefore, compared to the case where steps of photolithography, plating and polishing are repeated to form via patterns and wiring patterns, the polishing step or the like therebetween is unnecessary and the steps or processes are simplified.

Here, as a first modified example for the third embodiment of the present invention, one example of a manufacturing method for a wiring board will be described.

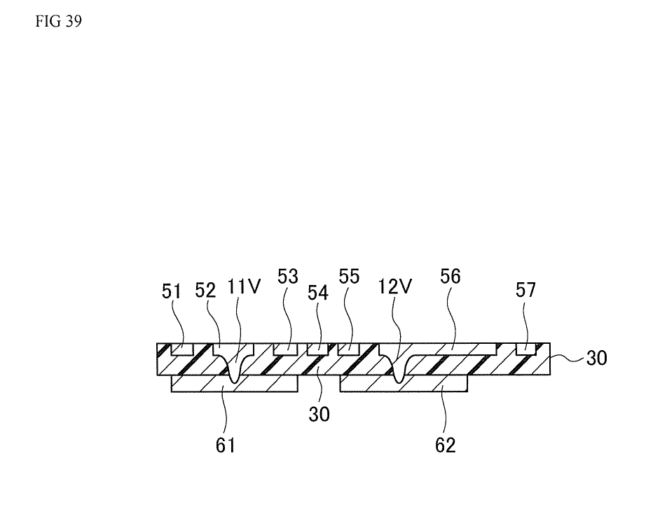

Steps or processes illustrated in FIG. 32 to FIG. 36 are substantially similar, so the description for them is omitted to avoid repetition. After having formed the first wiring patterns 51 to 57 and the via patterns 11V and 12V as shown in FIG. 36, a part of the insulating base material 30 is selectively removed to leave the via patterns 11V and 12V using appropriate chemical solution from the lower surface of the insulating base material 30. Ends of the via patterns 11V and 12V remain to project from the lower surface (lower side in the figure) of the insulating base material 30. Thereafter, as shown in FIG. 39, the second wiring patterns 61 and 62 are formed by plating or printing/sintering conductive paste. This allows the contact areas to be increased between the via patterns 11V and 12V and the second wiring patterns 61 and 62 thereby to improve the connection reliability.

Further, as a second modified example for the third embodiment of the present invention, one example of a manufacturing method for a wiring board will be described.

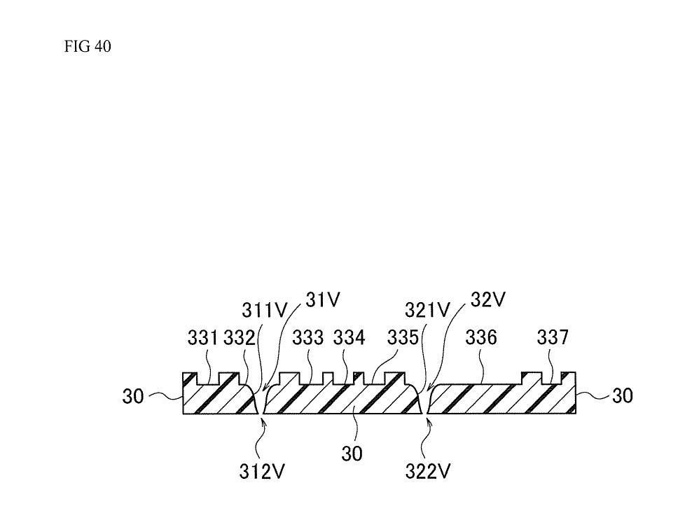

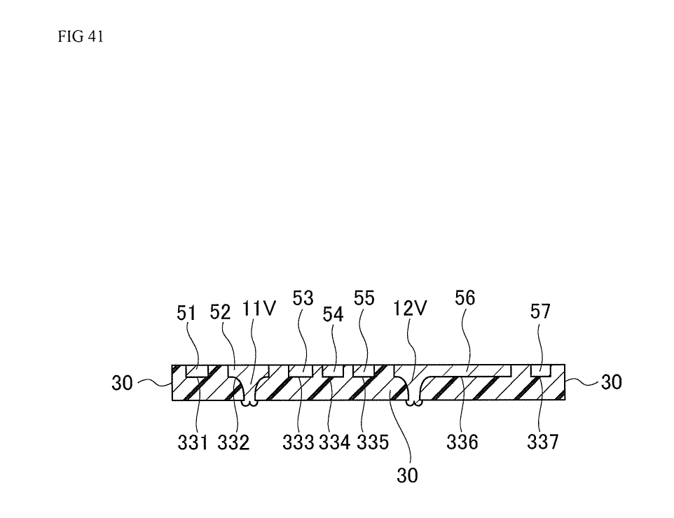

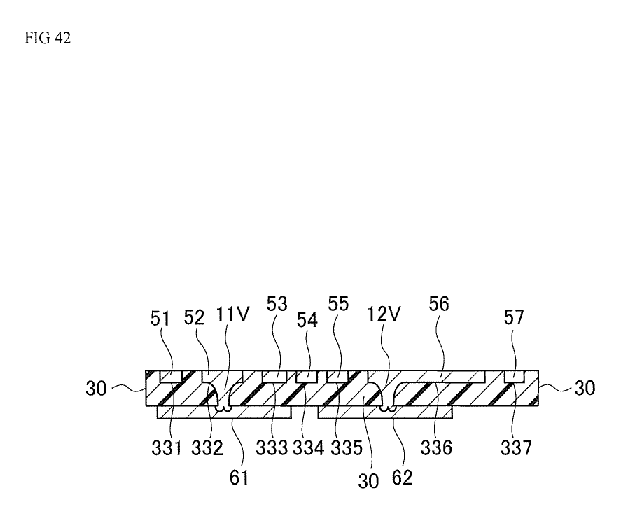

Steps or processes illustrated in FIG. 32 and FIG. 33 are substantially similar, so the description for them is omitted to avoid repetition. After having releasing the mold 1 from the insulating base material 30 as shown in FIG. 34, remaining portions of the bottom areas 312V and 322V are removed, as shown in FIG. 40, by performing chemical or mechanical polishing from the lower surface of the insulating base material 30 or by plasma, chemical solution, or sandblasting etc. from the upper surface or the lower surface of the insulating base material 30, thereby causing the holes 31V and 32V to pass through. Subsequently, the holes 31V and 32V are filled with conductive material by plating or printing/sintering conductive paste to form the first wiring patterns 51 to 57 and the via patterns 11V and 12V, as shown in FIG. 41. As a result, ends of the via patterns 11V and 12V are exposed to project from the other main surface (lower side surface in the figure) of the insulating base material 30. Thereafter, as shown in FIG. 42, the second wiring patterns 61 and 62 are formed by plating or printing/sintering conductive paste. This allows the contact areas to be increased between the via patterns 11V and 12V and the second wiring patterns 61 and 62 thereby to improve the connection reliability.

Still further, as a third modified example for the third embodiment of the present invention, one example of a manufacturing method for a wiring board will be described.

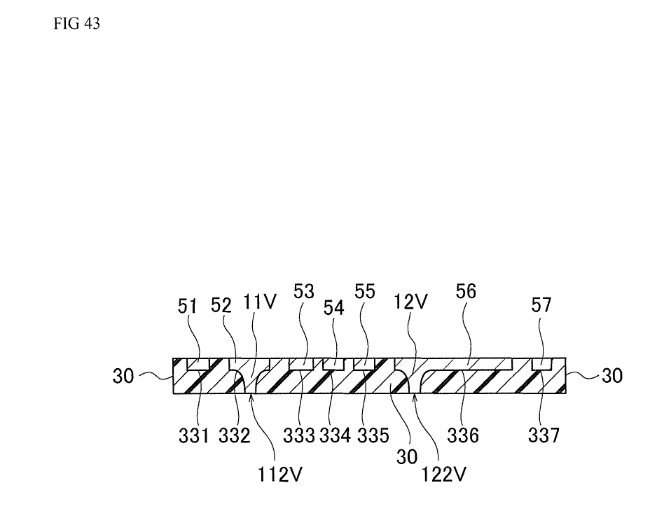

Steps or processes illustrated in FIG. 32 and FIG. 33 are substantially similar, so the description for them is omitted to avoid repetition. After having releasing the mold 1 from the insulating base material 30 as shown in FIG. 34, the holes 31V and 32V are caused to pass through, as shown in FIG. 40, by performing chemical or mechanical polishing from the lower surface of the insulating base material 30 or by plasma, chemical solution, or sandblasting etc. from the upper surface or the lower surface of the insulating base material 30. Subsequently, a supporting substrate (not shown) is located on the lower surface of the insulating base material 30 to temporarily seal the holes 31V and 32V, and the holes 31V and 32V are filled with conductive material by plating or printing/sintering conductive paste to form the first wiring patterns 51 to 57 and the via patterns 11V and 12V, as shown in FIG. 43. As a result, the lower surface of the insulating base material 30 and top head portions 112V and 122V of the via patterns 11V and 12V come to be of the same height (so-called “on the same plane”). Thereafter, as shown in FIG. 37, the second wiring patterns 61 and 62 are formed by plating or printing/sintering conductive paste.

The above-described modified examples 1 to 3 comprise common features to the third embodiment, and thus have common functionalities and advantageous effects thereto.

### Fourth Embodiment

Hereinafter, a fourth embodiment will be described. The fourth embodiment involves a method of manufacturing a laminate-type wiring board using the wiring board 100 according to the third embodiment, and the laminate-type wiring board obtained by this manufacturing method. Detailed descriptions for common elements will be represented by those for the above-described embodiments.

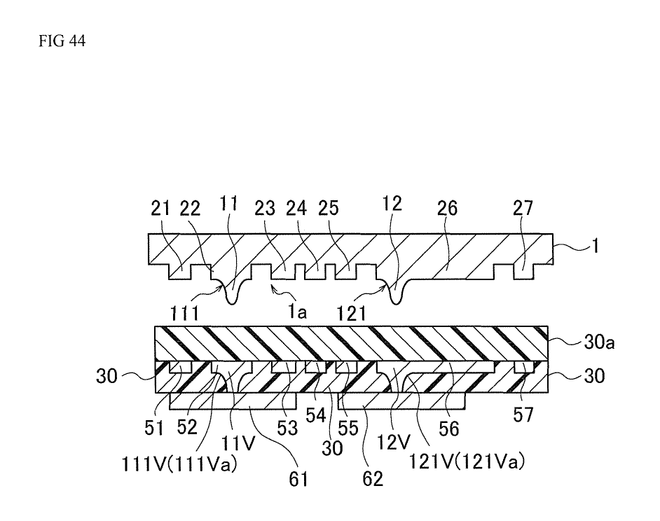

First with reference to FIG. 44 to FIG. 47, the manufacturing method for a laminate-type wiring board according to the fourth embodiment of the present invention will be described.

(1) As shown in FIG. 44, the previously-described wiring board 100 shown in FIG. 37 is prepared, and another insulating base material 30a other than the insulating base material 30 used in this wiring board 100 is laminated on the uppermost surface (exposed surface) of the wiring board 100 (first laminating process). As a material for the insulating base material 30a, the same material as the insulating base material 30 of the wiring board 100 may be used.

(2) Thereafter, mold 1 is prepared. The structure of the mold 1 is common to that of the mold 1 shown in FIG. 31 and described in the third embodiment, so the description thereof is omitted here. As shown in FIG. 44, the mold 1 is located parallel to the insulating base material 30a laminated on the uppermost layer surface side of the wiring board 100. Top portions 112 and 122 of the protruding portions 11 and 12 formed on the stamping surface 1a of the mold 1 oppose the insulating base material 30a.

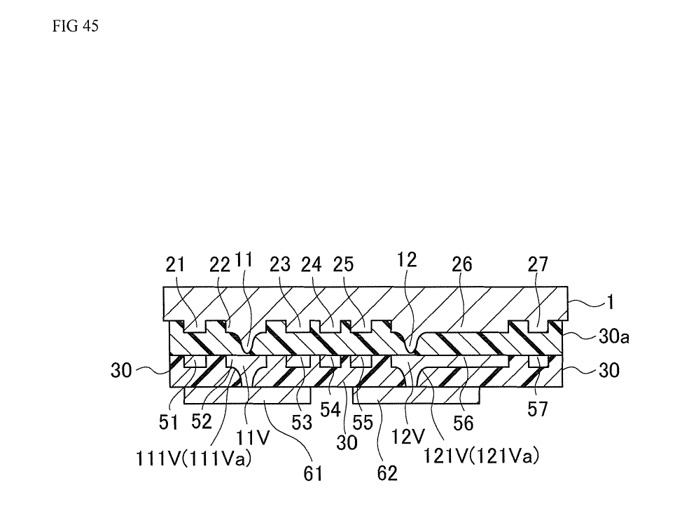

(3) The insulating base material 30a is heated to a temperature equal to or above the glass transition temperature, and the mold 1 is caused to move toward the insulating base material 30a such that the protruding portions 11 and 12 are pressed into the insulating base material 30a, as shown in FIG. 45.

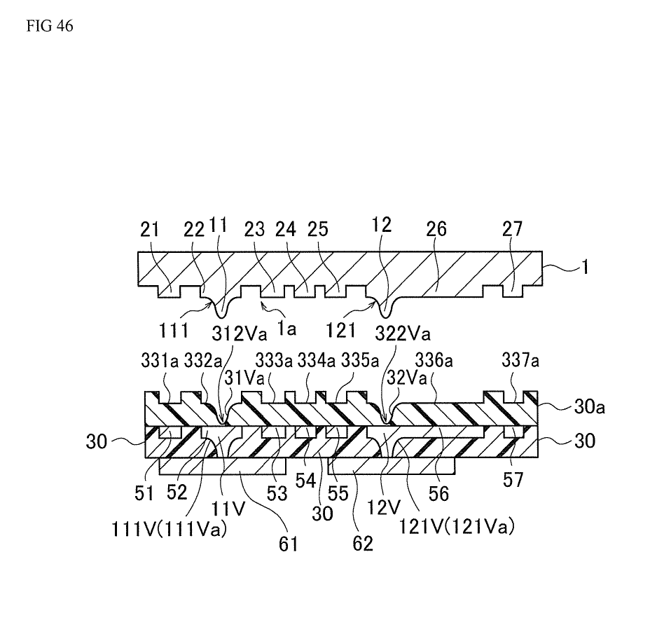

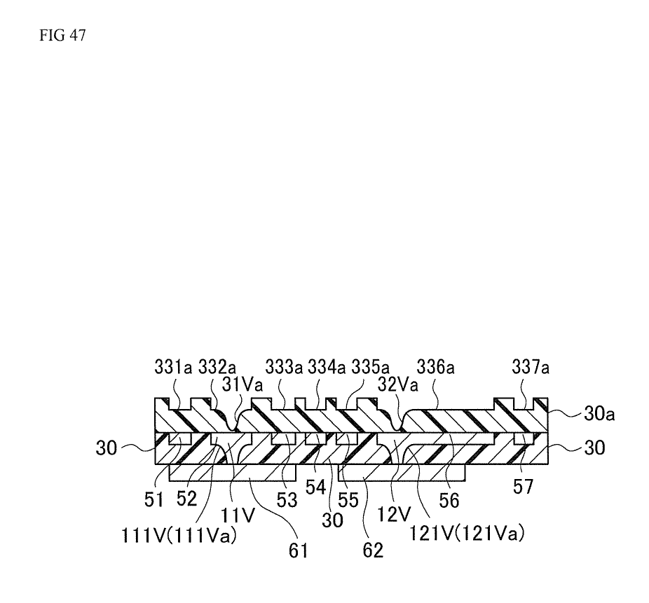

(4) Subsequently, as shown in FIG. 46, the mold 1 is released from the insulating base material 30a. At this time, because the base portions 111 and 121 of the protruding portions 11 and 12 have certain curvatures, the releasing is more easily performed than the case where the protruding portions 11 and 12 merge into the stamping surface 1a with angles. If the insulating base material 30a is of heat-curable resin, then it is cured by heating in an oven or the like. If, on the other hand, the insulating base material 30a is of thermoplastic resin, then it is cured by cooling. The step or process for curing the insulating base material 30a is not restricted to only after the releasing, but may be after pressing the mold 1 into the insulating base material 30a as shown in FIG. 45, or after causing holes 31Va and 32Va to pass through, as will be described later with reference to FIG. 47.

(5) If, as shown in FIG. 47, bottom areas 312Va and 322Va of the holes 31Va and 32Va of the insulating base material 30a are not passed through and the resins remain there, then irradiating plasma, spraying chemical solution, or sandblasting process may be performed from opening areas of the holes 31Va and 32Va to cause the bottom areas 312Va and 322Va of the holes 31Va and 32Va to pass through.

As shown in the figure, the insulating base material 30a after the releasing is formed therein the holes 31Va and 32Va depending on the shapes of the protruding portions 11 and 12 of the mold 1 and concave portions 331a to 337a depending on first wiring patterns (second laminating process).

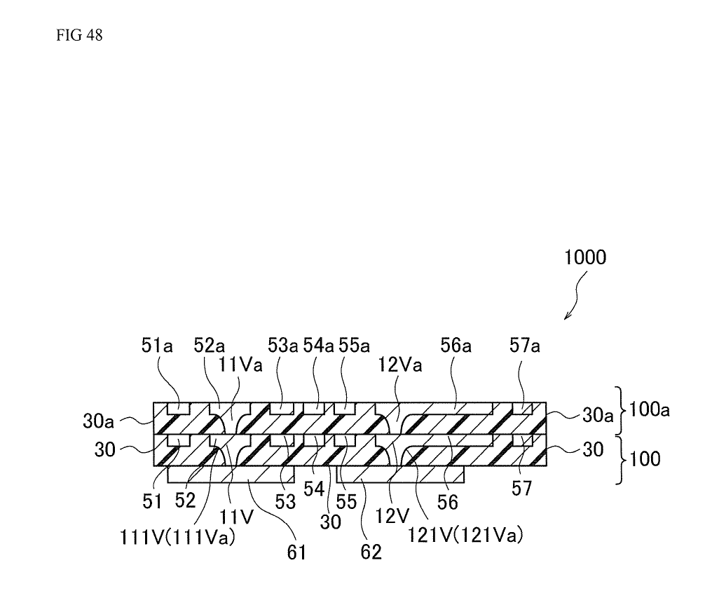

(6) The concave portions 331a to 337a and the holes 31Va and 32Va are filled with conductive material by plating or printing/sintering conductive paste to form first wiring patterns 51a to 57a and via patterns 11Va and 12Va, as shown in FIG. 48. If surplus portions of nano-paste remain, they will be removed by polishing, etching or other appropriate means (third laminating process).

(7) According to the above-described first laminating process to the third laminating process, a laminate-type wiring board 1000 can be obtained, as shown in FIG. 48, in which interlayer conduction is achieved. The above-described first laminating process to the third laminating process may be repeated a number of times depending on the target laminating number.

The laminate-type wiring board 1000 according to the present embodiment is such that, as similar to the above-described embodiments, the via patterns 11V and 12V (11Va and 12Va) merge into the first wiring patterns 51 to 57 (51a to 57a) to have certain curvatures, and have shapes decreasing in their outer diameters as approaching the top head portions of the vias from the connection portions with the first wiring patterns 51 to 57 (51a to 57a), thereby to provide functionalities and advantageous effects like the above-described embodiments.

Moreover, the laminate-type wiring board 1000 according to the present embodiment is such that, as similar to the above-described embodiments, the via patterns 11V and 12V (11Va and 12Va) are integrally formed with the first wiring patterns 51 to 57 (51a to 57a) in a status where no interface exists, thereby to provide functionalities and advantageous effects like the above-described embodiments.

Note that, while FIG. 48 illustrates the laminate-type wiring board 1000 having wiring boards 100 and 100a, one or more additional wiring boards 100 may be laminated on the upper surface of the wiring board 100a (opposite side to the wiring board 100). The first wiring patterns 51 to 57 of each wiring board to be laminated may be in a common fashion or different fashion.

### Fifth Embodiment

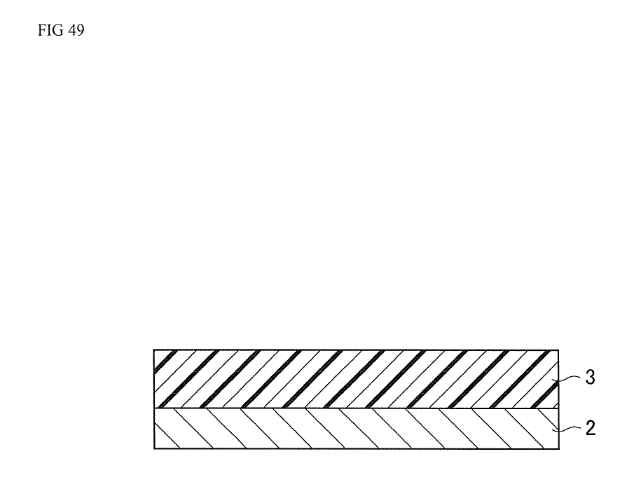

With reference to FIG. 49 to FIG. 61, a manufacturing method for a wiring board in the fifth embodiment and a wiring board 100 manufactured by this manufacturing method will be hereinafter described. Since the manufacturing method for a wiring board according to the present embodiment and the wiring board 100 manufactured by this manufacturing method essentially share common entities with the wiring board 100 in the first embodiment, descriptions for common entities will be represented by those for the first embodiment and different parts will primarily be described in order to avoid redundancy.

The manufacturing method for a wiring board in the present embodiment has the following two processes in broad terms: a process for preparing a mold to be used; and a process for producing a wiring board using the prepared mold. The manufacturing method for a mold and the manufactured mold will be described first, and the manufacturing method for a wiring board using this mold and the manufactured wiring board will then be described.

In the present embodiment, two molds, i.e., mold 1 for via and mold 1C for wiring pattern, are prepared.

The manufacturing method for the mold 1 for via is the same as that for the mold 1 in the first embodiment, and has a step for preparing a cured resin plate body, a step for irradiating laser or electron beam to a main surface of the resin plate body depending on via patterns thereby to form holes, and a step, using a mold material, for filling the holes formed in the resin plate body and covering the main surface of the resin plate body.

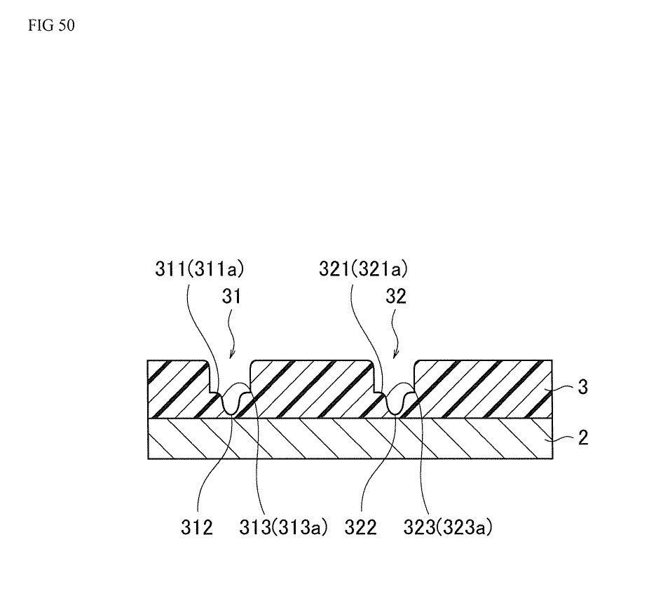

Each step will be specifically described. Like the first embodiment, a laminate of resin plate body 3 and supporting plate 2 as shown in FIG. 49 is prepared, and the resin plate body 3 is cured. Materials for the resin plate body 3 and the supporting plate 2 are the same as the first embodiment. Subsequently, as shown in FIG. 50, laser or electron beam (EB) is irradiated to the main surface of the resin plate body 3 to form holes 31 and 32 in a similar manner to the first embodiment. Inner walls 311a and 321a of opening areas 311 and 321 of the holes 31 and 32 of the resin plate body 3 according to the present embodiment are formed to merge into the main surface of the resin plate body 3, via cylindrical walls, with curved surfaces having certain curvatures. Further, the holes 31 and 32 have slope walls 313a and 323a inclined with respect to the depth direction and merge into the opening areas 311 and 321, and the slope walls 313a and 323a merge into bottom areas 312 and 322.

Although not particularly limited, the diameter of the opening areas 311 and 321 of the holes 31 and 32 in the present embodiment is 2 μm or more and 35 μm or less, preferably 2 μm or more and 15 μm or less, and further preferably 2 μm or more and less than 10 μm. In addition, the diameter of the bottom areas 312 and 322 of the holes 31 and 32 in the present embodiment is 1 μm or more and 30 μm or less, preferably 1 μm or more and 10 μm or less, and further preferably 1 μm or more and 5 μm or less. The depth is 1 μm or more and 50 μm or less, and preferably 10 μm or more and 40 μm or less. For one example, the diameter of the opening areas 311 and 321 of the holes 31 and 32 in the present embodiment is about 10 μm, and the depth is about 15 μm.

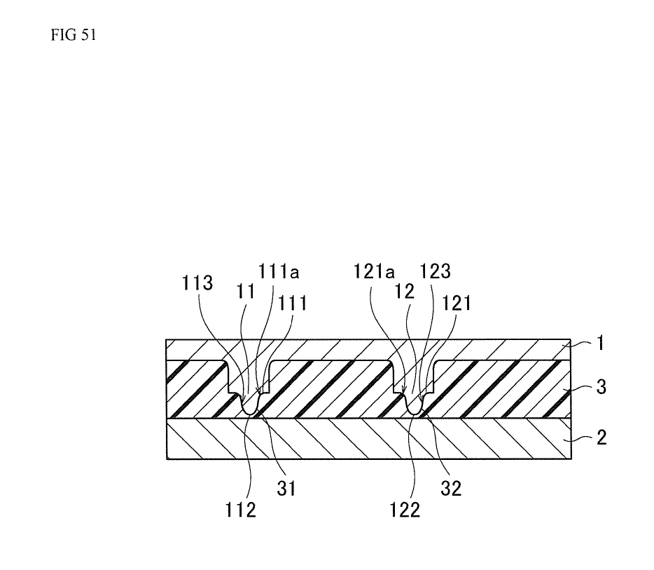

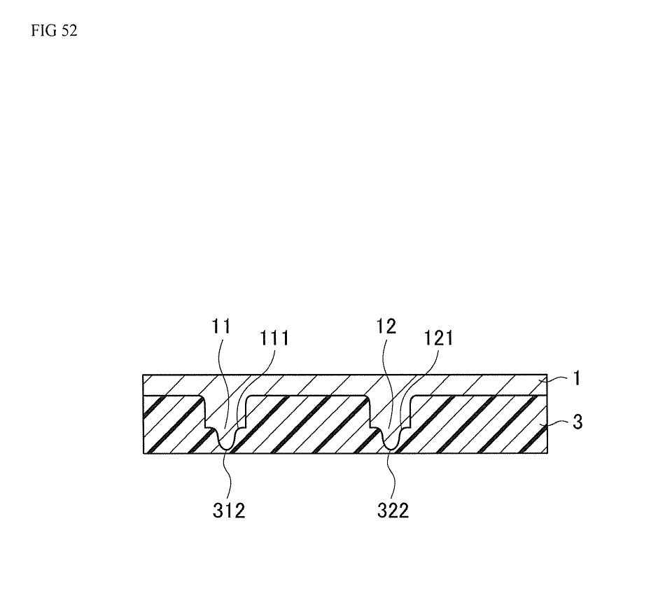

Subsequently, in a similar manner to the first embodiment, a conductive layer to be a seed layer for the subsequent plating process or the like is formed. Thereafter, as shown in FIG. 51, a mold material is used to fill the holes 31 and 32 formed in the resin plate body 3 and cover the main surface of the resin plate body 3. Specifically, plating is performed to fill the holes 31 and 32 formed in the resin plate body 3 with the mold material and cover the main surface of the resin plate body 3 with the mold material. Approaches for plating and other treatments are common to those in the first embodiment. Thereafter, as shown in FIG. 52, the supporting plate 2 is removed by using etching liquid such as ferric chloride solution. Finally, the resin plate body 3 is also removed through swelling by using aqueous solution of sodium hydroxide or other appropriate liquid, and the mold is obtained.

The present embodiment is configured such that the height of the protruding portions 11 and 12 in the mold clamping direction (vertical direction in the figure) is higher than the thickness of the insulating base material 30. This allows for avoiding the flat portion of the mold 1 from contacting with the insulating base material 30 when pressing the protruding portions 11 and 12 into the insulating base material 30, as will be described later, thereby to prevent losing the shape of concave portions 331 to 337 that would be previously formed in the insulating base material 30.

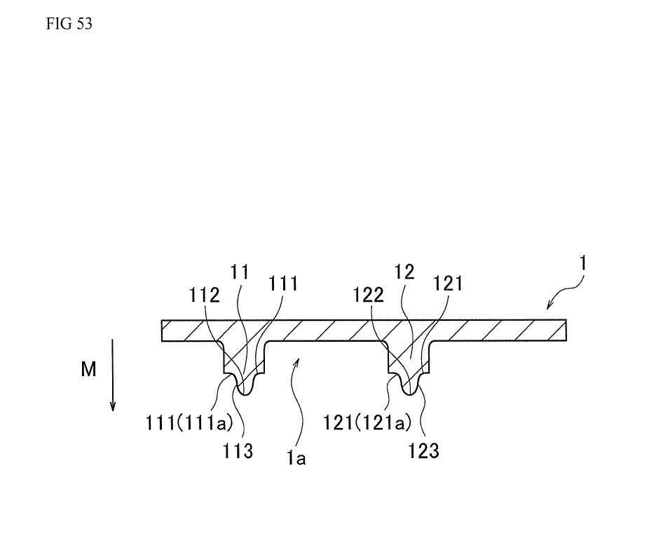

FIG. 53 is a cross-sectional view of the mold 1 in the present embodiment along the mold clamping direction (arrow M in the figure). As shown in FIG. 53, the stamping surface 1a of the mold 1 has at least protruding portions 11 and 12 each formed in convex shape on the main surface side of this stamping surface 1a. No interface exists between the flat portion of the stamping surface 1a and the protruding portions 11 and 12, and the protruding portions 11 and 12 thus constitute parts of the stamping surface 1a.

The protruding portions 11 and 12 in the present embodiment are formed into shapes having certain thicknesses (diameters), lengths and aspect ratios corresponding to those of holes of via patterns to be formed. Although not particularly limited, the diameter of base portions 111 and 121 of the protruding portions 11 and 12 is 2 μm or more and 35 μm or less, preferably 2 μm or more and 15 μm or less, and further preferably 2 μm or more and less than 10 μm. In addition, the diameter of top portions 112 and 122 of the protruding portions 11 and 12 in the present embodiment is 1 μm or more and 30 μm or less, preferably 1 μm or more and 10 μm or less, and further preferably 1 μm or more and 5 μm or less. Further, the length of the protruding portions 11 and 12 in the present embodiment is 1 μm or more and 50 μm or less, and preferably 10 μm or more and 40 μm or less. The aspect ratio is 0.5 to 40, preferably 1 to 30, and may be selected as being about 1 to 4 in this example.

The protruding portions 11 and 12 in the present embodiment, like the first embodiment, have base portions 111 and 121 which have curved surfaces 111a and 121a, and slope portions 113 and 123 which are tapered from these base portions 111 and 121 to top portions 112 and 122 of the protruding portions 11 and 12.

Concurrently, another mold 1C for wiring is prepared. The mold 1C for wiring comprises a stamping surface 1a including convex portions formed depending on wiring patterns to constitute a part of patterns. The stamping surface 1a of the mold 1C comprises convex portions depending on the wiring patterns. The mold 1C can be used to form wiring patterns with line width of about several nanometers to several micrometers on an insulating resin. While the mold 1C can be made by various methods, it may be made by using photolithography technique, for example. Specifically, a method may be used which comprises: applying photoresist to a glass substrate; patterning the resist using photolithography technique; forming a metal coat by sputtering, nonelectrolytic plating or other appropriate means on the surface of the patterned resist; forming a metal layer of nickel (Ni), copper (Cu) by electrolytic plating; releasing the glass substrate from this metal layer; and removing the resist remaining on the metal layer. Other than the above, it may be made by processing silicon or silica using electron beam lithography and dry-etching. In addition, as this mold 1C, commercially available nano-imprint mold or the like may also be used.

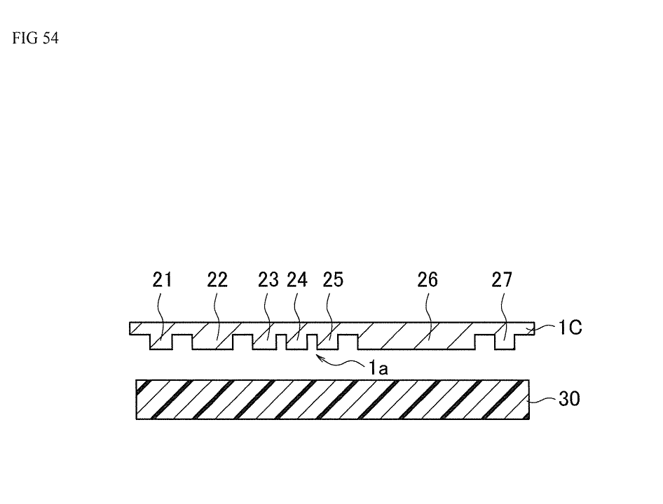

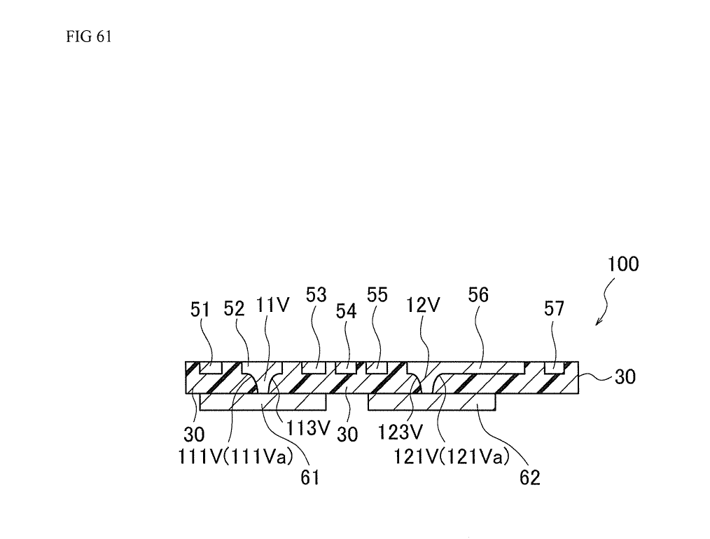

Hereinafter, a manufacturing method for a wiring board using the molds 1 and 1C will be described with reference to FIG. 54 to FIG. 60, and the manufactured wiring board will then be described with reference to FIG. 61.

In the present embodiment, a wiring board is obtained by so-called imprinting method using the above-described mold 1 for via shown in FIG. 53 and the mold 1C for wiring.

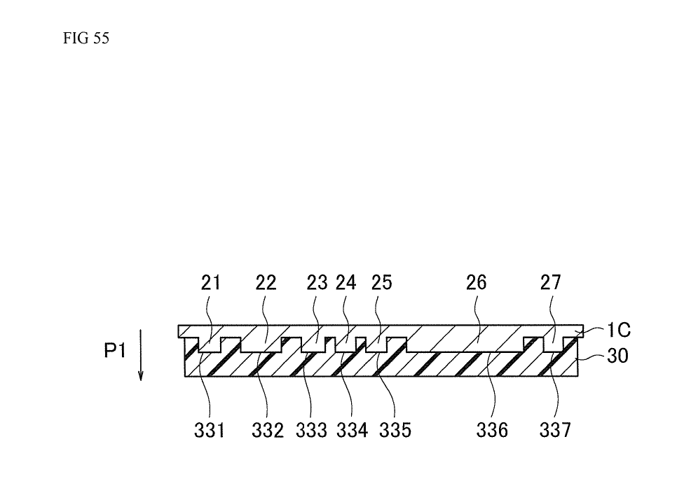

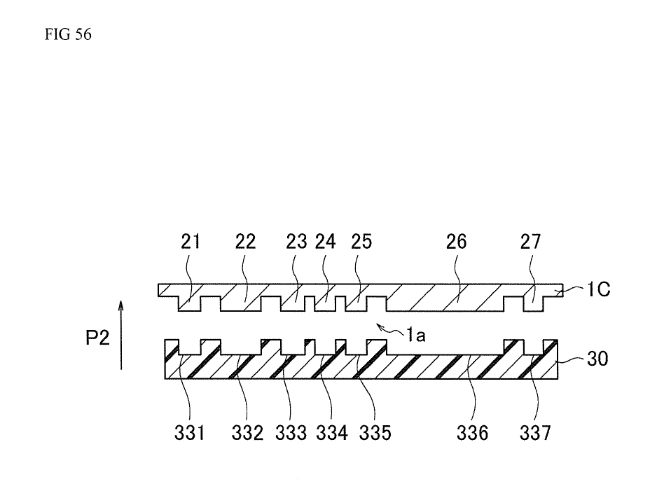

As shown in FIG. 54, the mold 1C for wiring is located first to oppose the main surface of the insulating base material 30. The stamping surface 1a of the mold 1C for wiring is formed thereon convex portions 21 to 27 depending on wiring patterns. The material for the insulating base material 30 is the same as that for the first embodiment. Thereafter, as shown in FIG. 55, the mold 1C is caused to approach the insulating base material 30 (caused to move along arrow P1) and mold clamping is performed under the same condition as the first embodiment. For example, the convex portions 21 to 27 are pressed into the insulating base material 30 by hot pressing under 130 to 170 degrees C. and 0.8 to 1.2 MPa. The mold 1C and the insulating base material 30 are cooled below the glass transition temperature (Tg), and the mold 1C is released in the direction where the mold 1C is separated from the insulating base material 30 (arrow P2), as shown in FIG. 56.

Although not particularly limited, Ajinomoto Build-Up Film (ABF) of heat-curable resin is used as the insulating base material 30, which is hot pressed under 130 to 170 degrees C. and 8 to 12 MPa.

As shown in FIG. 56, the main surface of the insulating base material 30 is formed thereon concave portions 331 to 337 depending on wiring patterns.

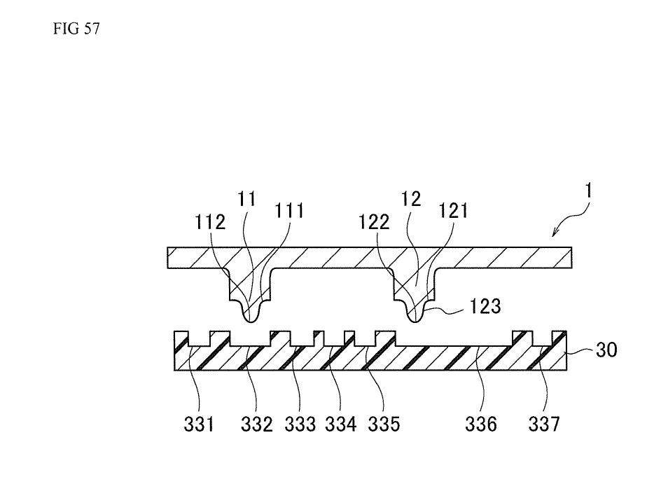

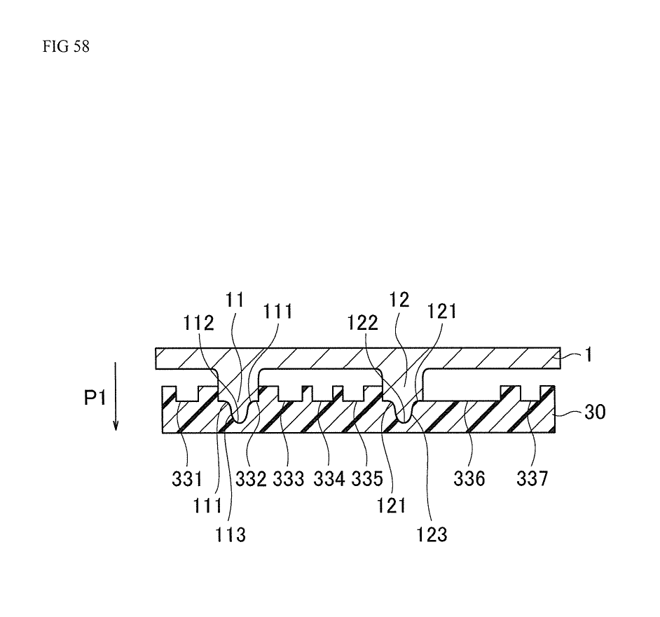

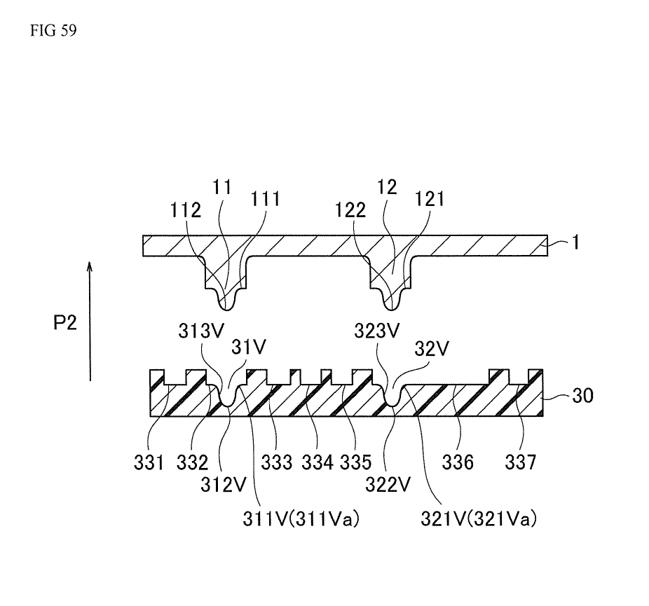

Subsequently, as shown in FIG. 57, the mold 1 for via is located to oppose the main surface of the insulating base material 30 such that the protruding portions 11 and 12 of this mold 1 get into touch with the concave portions 331 to 337 formed on one main surface of the insulating base material 30. Thereafter, as shown in FIG. 58, the mold 1 is caused to approach the insulating base material 30 (caused to move along arrow P1) and mold clamping is performed under the same condition as the first embodiment. For example, the protruding portions 11 and 12 are pressed into the insulating base material 30 by hot pressing under 130 to 170 degrees C. and 0.8 to 1.2 MPa. The mold 1 and the insulating base material 30 are cooled below the glass transition temperature (Tg), and the mold 1 is released in the direction where the mold 1 is separated from the insulating base material 30 (arrow P2), as shown in FIG. 59. If the insulating base material 30 is heat-curable resin, then the insulating base material 30 is fully cured by heating at 160 to 200 degrees C., for example, during 40 to 80 minutes in an oven or the like. If, on the other hand, the insulating base material 30 is thermoplastic resin, then it is cured by cooling.

Here, the height of the protruding portions 11 and 12 in the mold clamping direction (vertical direction in the figure) is higher than the thickness of the insulating base material 30, so that the flat portion of the mold 1 may be avoided from contacting with the insulating base material 30, thereby to prevent losing the shape of concave portions 331 to 337 of the insulating base material 30.

The above allows for transferring the shape depending on via patterns of the stamping surface 1a of the mold 1 and the shape depending on wiring patterns of the stamping surface 1a of the mold 1C to the main surface of the insulating base material 30. As shown in the figure, after releasing the mold 1, the insulating base material 30 is formed therein the concave portions 331 to 337 depending on the convex portions 21 to 27 of the mold 1C as well as the holes 31V and 32V depending on the shapes of the protruding portions 11 and 12 of the mold 1.

As shown in FIG. 59, these holes 31V and 32V have: inner walls 311Va and 321Va having certain curvatures around opening areas 311V and 321V; and slope walls 313Va and 323Va gradually decreasing in inner diameters thereof toward the bottom surfaces. Specifically, the holes 31V and 32V having been formed in the insulating base material 30 are such that, as shown in the figure, the inner walls 311Va and 321Va having certain curvatures are formed within the opening areas 311V and 321V, and merge into the concave portions 331 to 337 of the insulating base material 30. These holes 31V and 32V have body areas 313V and 323V comprising the slope walls 313Va and 323Va which decrease in their diameters as approaching the bottom areas 312V and 322V from the opening areas 311V and 321V. Although not particularly limited, the diameter of the opening areas 311V and 321V of the holes 31V and 32V in the present embodiment is 2 μm or more and 35 μm or less, preferably 2 μm or more and 15 μm or less, and further preferably 2 μm or more and less than 10 μm. In addition, the diameter of the bottom areas 312V and 322V of the holes 31V and 32V in the present embodiment is 1 μm or more and 30 μm or less, preferably 1 μm or more and 10 μm or less, and further preferably 1 μm or more and 5 μm or less. The depth is 1 μm or more and 50 μm or less, and preferably 10 μm or more and 40 μm or less. For one example, the holes 31V and 32V in the present embodiment are such that the diameter is about 10 μm and the depth is about 15 μm.

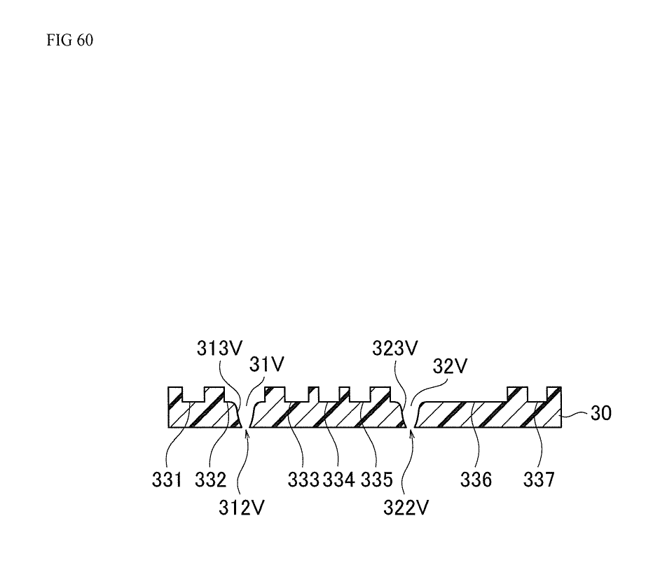

If the mold 1 has not penetrated the insulating base material 30 and resins remain at the bottoms of the holes 31V and 32V, as shown in FIG. 59, then they may be removed by chemical or mechanical polishing to cause the holes 31V and 32V to pass through, as shown in FIG. 60.

After applying resist to the lower surface of the insulating base material 30 shown in FIG. 60 and patterning the resist using photolithography technique, plating is performed to fill the holes 31V and 32V and the concave portions 331 to 337 with conductive material.

This plating process allows for concurrently forming via patterns 11V and 12V, first wiring patterns 51 to 57, and second wiring patterns 61 and 62. In an alternative embodiment, conductive paste may be printed/sintered on the upper surface and the lower surface of the insulating base material 30 to concurrently form the via patterns 11V and 12V, the first wiring patterns 51 to 57, and the second wiring patterns 61 and 62. If surplus portions of nano-paste remain, they will be removed by polishing, etching or other appropriate means.

FIG. 61 illustrates wiring board 100 according to the present embodiment. As shown in FIG. 61, the wiring board 100 in the present embodiment comprises: insulating base material 30; first wiring patterns 51 to 57 formed on one main surface of the insulating base material 30; second wiring patterns 61 and 62 formed on the other main surface of the insulating base material 30; and via patterns 11V and 12V penetrating from the one main surface side to the other main surface side of the insulating base material 30 and conducting with the first wiring patterns 51 to 57 and the second wiring patterns 61 and 62.

The first wiring patterns 51 to 57 of the wiring board 100 according to the present embodiment are formed in a status where they are embedded in convex-like shape from the one main surface (upper side in the figure) of the insulating base material 30 toward the inner side. Accordingly, upper surface of the first wiring patterns 51 to 57 are of the same height as the main surface of the insulating base material 30, and the main surface of the insulating base material 30 can thus be achieved as being flat in spite of being formed thereon with the first wiring patterns 51 to 57. This allows other components to be mounted or one or more additional wiring boards 100 to be laminated on the insulating base material 30, which is embedded therein with the first wiring patterns 51 to 57, without being restricted in regard to placing positions. Moreover, entirely flat laminate-type wiring board can be produced even when plural wiring boards 100 are laminated.

The via patterns 11V and 12V in the present embodiment have, as shown in the figure, connection base portions 111V and 121V merging into the first wiring patterns 52 and 56 with curved connection surfaces 111Va and 121Va having certain curvatures, and cone-like portions 113V and 123V decreasing in their outer diameters as approaching ends of the via patterns 11V and 12V from the connection base portions 111V and 121V.

As shown in the figure, because the via patterns 11V and 12V in the present embodiment have the curved surfaces 111Va and 121Va having certain curvatures with the first wiring patterns 52 and 56, and the via patterns 11V and 12V and the first wiring patterns 52 and 56 smoothly merge into one another via the curved surfaces 111Va and 121Va and are integrally formed, the present embodiment has functionalities and advantageous effects like the wiring board according to the above-described embodiments.

### Sixth Embodiment

Hereinafter, a sixth embodiment will be described. The sixth embodiment involves a method of manufacturing a laminate-type wiring board using the wiring board 100 according to the fifth embodiment, and the laminate-type wiring board obtained by this manufacturing method. Detailed descriptions for common elements will be represented by those for the above-described embodiments.

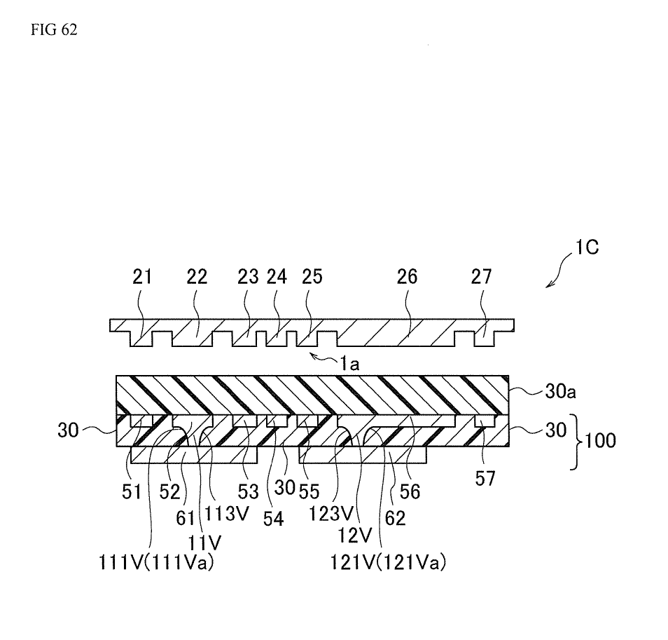

(1) As shown in FIG. 62, the previously-described wiring board 100 in the fifth embodiment is prepared, and another insulating base material 30a other than the insulating base material 30 used in this wiring board 100 is laminated on the uppermost surface (exposed surface) of the wiring board 100 (first laminating process). As a material for the insulating base material 30a, the same material as the insulating base material 30 of the wiring board 100 may be used.

(2) Thereafter, mold 1C is prepared. The structure of the mold 1C is common to that of the mold 1C described in the fifth embodiment. As shown in the figure, the mold 1C is located parallel to the insulating base material 30a laminated on the uppermost layer surface side of the wiring board 100. Convex portions 21 to 27 formed on the stamping surface 1a of the mold 1C oppose the insulating base material 30a.

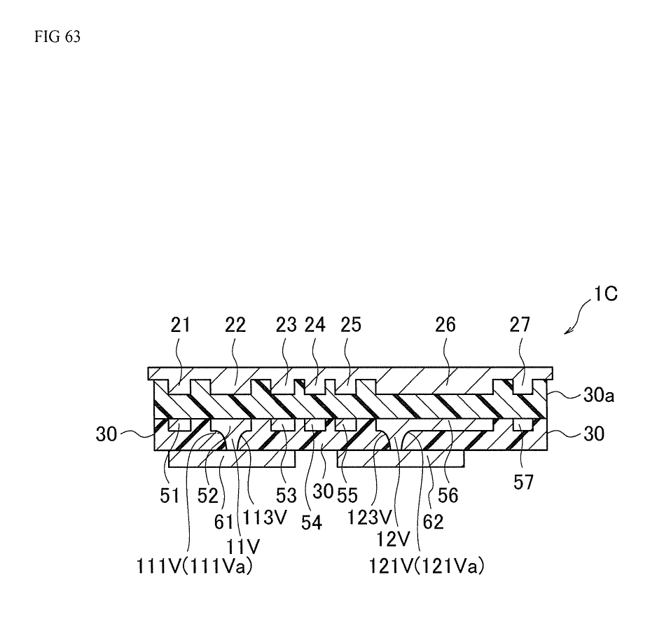

(3) The insulating base material 30a is heated to a temperature equal to or above the glass transition temperature, and the mold 1C is caused to move toward the insulating base material 30a such that the convex portions 21 to 27 are pressed into the insulating base material 30a, as shown in FIG. 63.

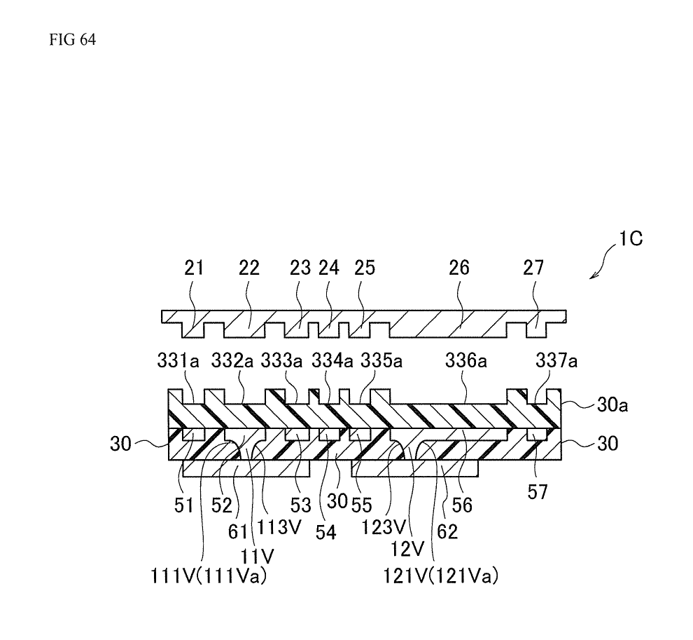

(4) Subsequently, as shown in FIG. 64, the mold 1C is released from the insulating base material 30a to form concave portions 331a to 337a with shapes depending on the convex portions 21 to 27 of the mold 1C on the insulating base material 30a (second laminating process).

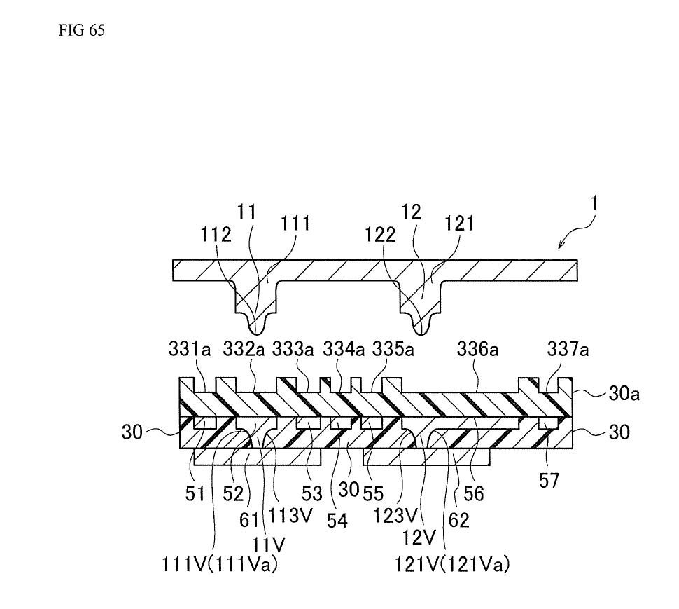

(5) Thereafter, mold 1 is prepared. The structure of the mold 1 is common to that of the mold 1 described in the fifth embodiment, so the description thereof is omitted here. As shown in FIG. 65, the mold 1 is located parallel to the insulating base material 30a laminated on the uppermost layer surface side of the wiring board 100. This insulating base material 30a has been formed therein concave portions 331a to 337a. Top portions 112 and 122 of the protruding portions 11 and 12 formed on the stamping surface 1a of the mold 1 oppose the concave portions 332a and 336a of the insulating base material 30a.

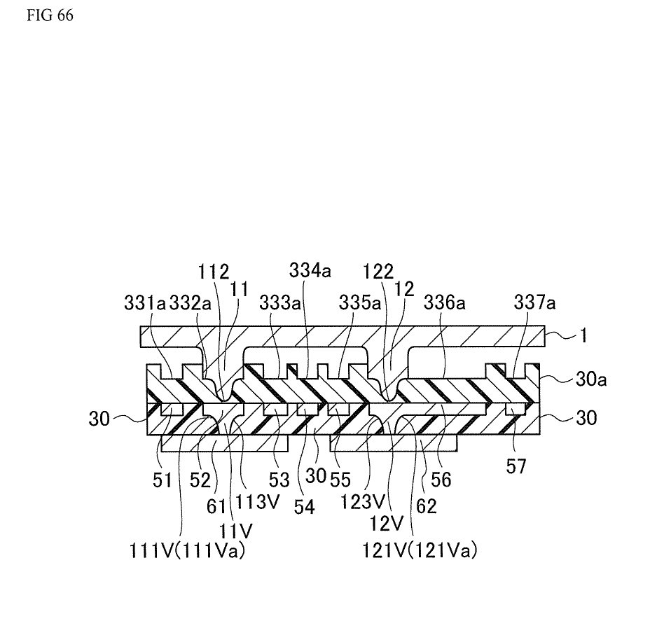

(6) The insulating base material 30a is heated to a temperature equal to or above the glass transition temperature, and the mold 1 is caused to move toward the insulating base material 30a such that the protruding portions 11 and 12 are pressed into the insulating base material 30a, as shown in FIG. 66.

(7) Subsequently, the mold 1 is released from the insulating base material 30a. At this time, because the base portions 111 and 121 of the protruding portions 11 and 12 have certain curvatures, the releasing is more easily performed than the case where the protruding portions 11 and 12 merge into the mold 1 with angles. If the insulating base material 30a is of heat-curable resin, then it is cured by heating in an oven or the like. If, on the other hand, the insulating base material 30a is of thermoplastic resin, then it is cured by cooling.

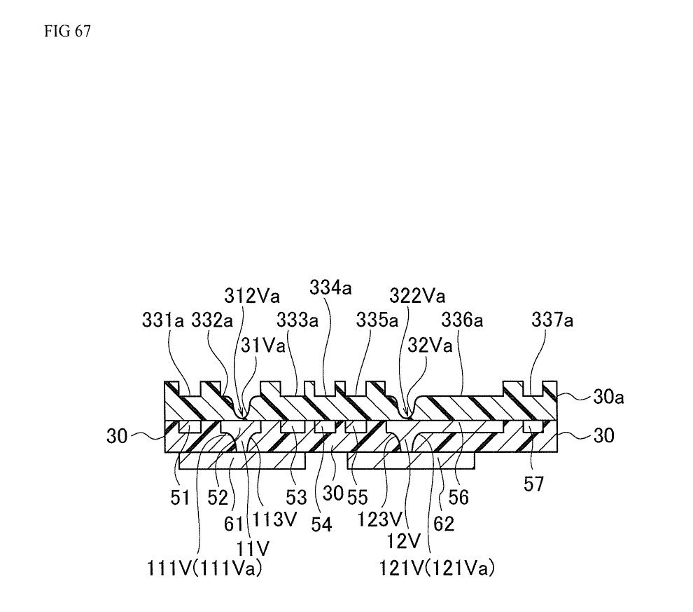

As shown in FIG. 67, the insulating base material 30a after the releasing of the mold 1 is formed therein the holes 31Va and 32Va depending on the shapes of the protruding portions 11 and 12 of the mold 1 and the concave portions 331a to 337a depending on first wiring patterns (third laminating process).

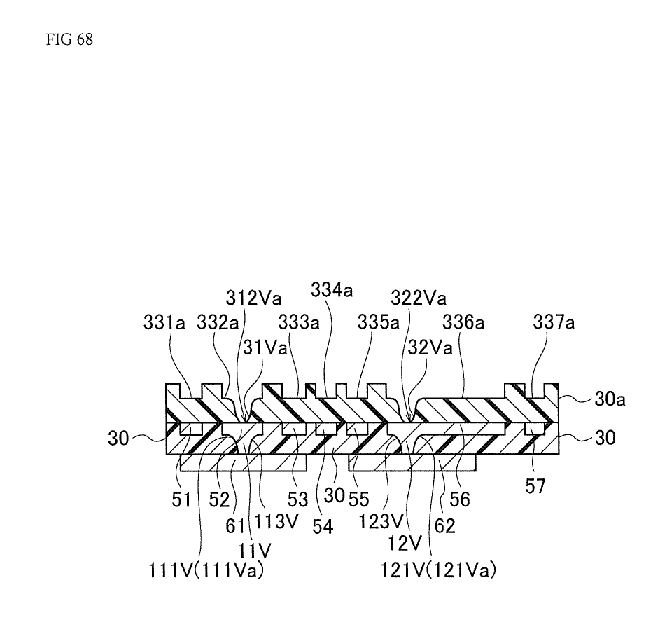

(8) If bottom areas 312Va and 322Va of the holes 31Va and 32Va of the insulating base material 30a are not passed through and resins remain there, then irradiating plasma, spraying chemical solution, or sandblasting process may be performed, as shown in FIG. 68, from opening areas of the holes 31Va and 32Va to cause the bottom areas 312Va and 322Va of the holes 31Va and 32Va to pass through.

(9) The concave portions 331a to 337a and the holes 31Va and 32Va are filled with conductive material by plating or printing/sintering conductive paste for the wiring board 100 shown in FIG. 68 to form first wiring patterns and via patterns (fourth laminating process). If surplus portions of nano-paste remain, they will be removed by polishing, etching or other appropriate means.

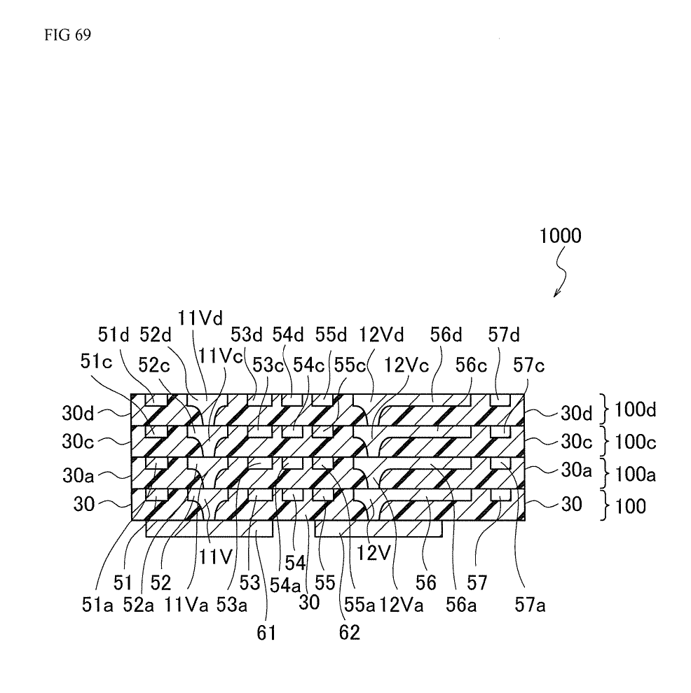

(10) According to the above-described first laminating process to the fourth laminating process, a laminate-type wiring board 1000 can be obtained in which interlayer conduction is achieved for the wiring board 100. FIG. 69 illustrates an example of laminate-type wiring board 1000 achieved by repeating three times the first laminating process to the fourth laminating process to laminate wiring boards 100a, 100c and 100d on the wiring board 100. The above-described first laminating process to the fourth laminating process may be repeated a number of times depending on the target laminating number of laminate-type wiring board 1000.

The laminate-type wiring board 1000 according to the present embodiment is such that, as similar to the above-described embodiments, the via patterns 11V and 12V (11Va, 11Vc, 11Vd, 12Va, 12Vc, 12Vd) merge into the first wiring patterns 51 to 57 (51a to 57a, 51c to 57c, 51d to 57d) to have certain curvatures, and have shapes decreasing in their outer diameters as approaching the top head portions of the vias from the connection portions with the first wiring patterns 51 to 57 (51a to 57a, 51c to 57c, 51d to 57d), thereby to provide functionalities and advantageous effects like the above-described embodiments.

Moreover, the laminate-type wiring board 1000 according to the present embodiment is such that, as similar to the above-described embodiments, the via patterns 11V and 12V (11Va, 11Vc, 11Vd, 12Va, 12Vc, 12Vd) are integrally formed with the first wiring patterns 51 to 57 (51a to 57a, 51c to 57c, 51d to 57d) in a status where no interface exists, thereby to provide functionalities and advantageous effects like the above-described embodiments.

Note that, while FIG. 69 illustrates the laminate-type wiring board 1000 having wiring boards 100, 100a, 100c and 100d, the number of laminating for the wiring board 100 is not limited. Note also that the first wiring patterns 51 to 57 (51a to 57a, 51c to 57c, 51d to 57d) of each wiring board to be laminated may be in a common fashion or different fashion.

### Seventh Embodiment

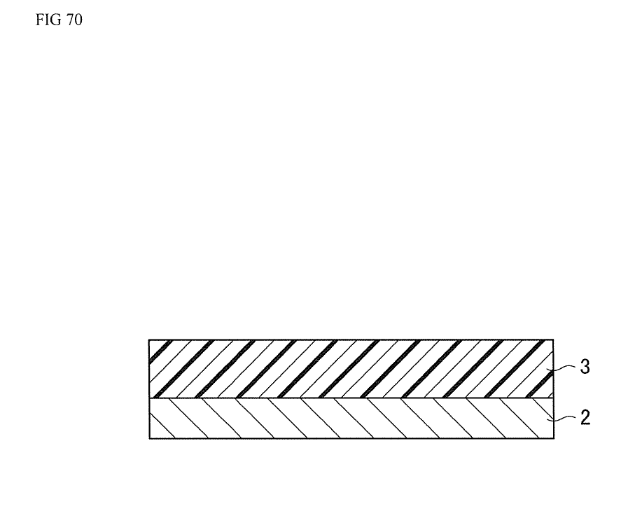

With reference to FIG. 70 to FIG. 82, a manufacturing method for a wiring board of the seventh embodiment and a wiring board 100 manufactured by this manufacturing method will be hereinafter described. Since the manufacturing method for a wiring board according to the present embodiment is essentially common to the fifth embodiment, descriptions will be represented by those for the fifth embodiment in order to avoid redundancy.

The manufacturing method for a wiring board in the present embodiment has the following two processes in broad terms: a process for preparing a mold to be used; and a process for producing a wiring board using the prepared mold. The manufacturing method for a mold and the manufactured mold will be described first, and the manufacturing method for a wiring board using this mold and the manufactured wiring board will then be described.

In the present embodiment, two molds, i.e., mold 1 for via and mold 1C for wiring pattern, are initially prepared.

The manufacturing method for the mold 1 for via is the same as that for the mold 1 in the first embodiment, and has a step for preparing a cured resin plate body, a step for irradiating laser or electron beam to a main surface of the resin plate body depending on via patterns thereby to form holes, and a step, using a mold material, for filling the holes formed in the resin plate body and covering the main surface of the resin plate body.

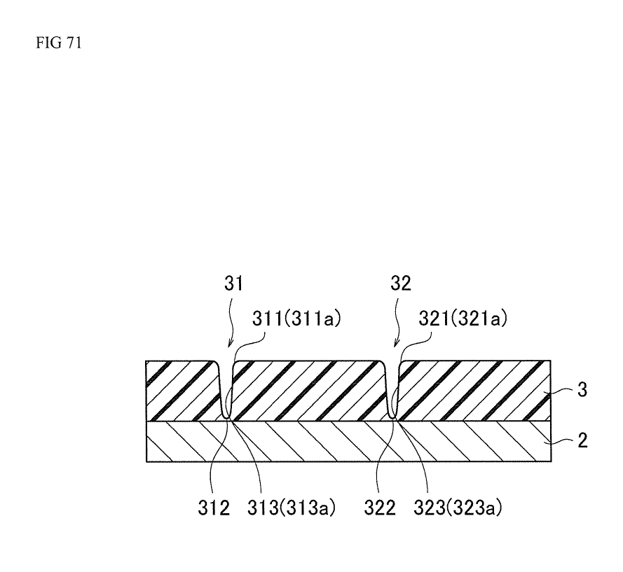

The manufacturing method for the mold 1 for via is common to the fifth embodiment. A laminate of resin plate body 3 and supporting plate 2 as shown in FIG. 70 is prepared first, and the resin plate body 3 is cured. Subsequently, as shown in FIG. 71, laser or electron beam (EB) is irradiated to the main surface of the resin plate body 3 to form holes 31 and 32 in a similar manner to the first embodiment. Inner walls 311a and 321a of opening areas 311 and 321 of holes 31 and 32 of the resin plate body 3 according to the present embodiment are formed to merge into the main surface of the resin plate body 3 with curved surfaces having certain curvatures. Further, the holes 31 and 32 have slope walls 313a and 323a inclined with respect to the depth direction and merge into the opening areas 311 and 321, and the slope walls 313a and 323a merge into bottom areas 312 and 322. The diameter, depth, and aspect ratio of the holes 31 and 32 are common to the fifth embodiment.

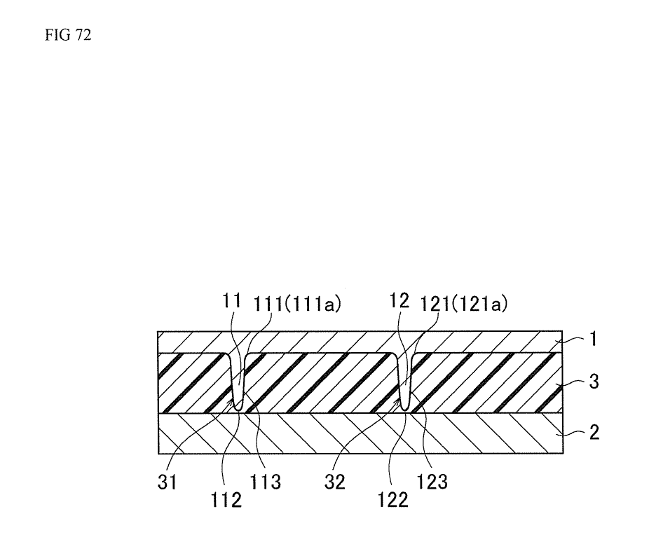

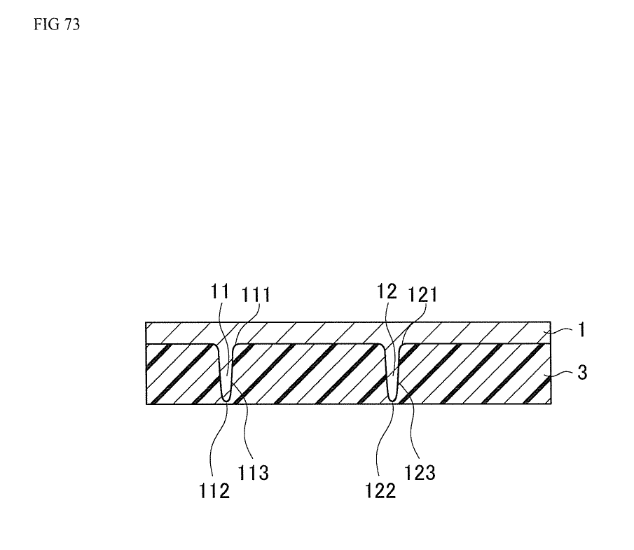

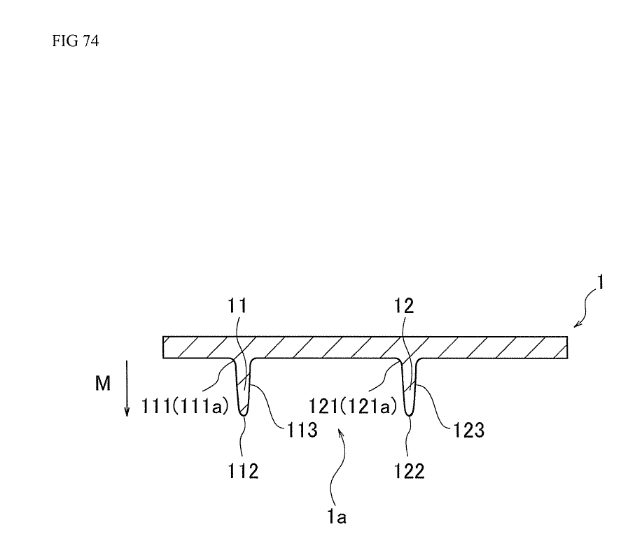

Subsequently, in a similar manner to the first embodiment, a conductive layer to be a seed layer for the subsequent plating process or the like is formed. Thereafter, as shown in FIG. 72, a mold material is used to fill the holes 31 and 32 formed in the resin plate body 3 and cover the main surface of the resin plate body 3. Specifically, plating is performed to fill the holes 31 and 32 formed in the resin plate body 3 with the mold material and cover the main surface of the resin plate body 3 with the mold material. Approaches for plating and other treatments are common to those in the first embodiment. Thereafter, as shown in FIG. 73, the supporting plate 2 is removed by using etching liquid such as ferric chloride solution. Finally, the resin plate body 3 is also removed through swelling by using aqueous solution of sodium hydroxide or other appropriate liquid, and the mold 1 is obtained as shown in FIG. 74.

The present embodiment is configured such that the height of the protruding portions 11 and 12 in the mold clamping direction (vertical direction in the figure) is higher than the thickness of the insulating base material 30. This allows for avoiding the flat portion of the mold 1 from contacting with the insulating base material 30 when pressing the protruding portions 11 and 12 into the insulating base material 30, as will be described later, thereby to prevent losing the shape of concave portions 331 to 337 that would be previously formed in the insulating base material 30.

FIG. 74 is a cross-sectional view of the mold 1 in the present embodiment along the mold clamping direction (arrow M in the figure). As shown in FIG. 74, the stamping surface 1a of the mold 1 has at least protruding portions 11 and 12 each formed in convex shape on the main surface side of this stamping surface 1a. No interface exists between the stamping surface 1a and the protruding portions 11 and 12, and the protruding portions 11 and 12 thus constitute parts of the stamping surface 1a. The thickness (diameter), length, and aspect ratio of the protruding portions 11 and 12 are common to the fifth embodiment. The protruding portions 11 and 12 in the present embodiment have base portions 111 and 121 which have curved surfaces 111a and 121a, and slope portions 113 and 123 which are tapered from these base portions 111 and 121 to top portions 112 and 122 of the protruding portions 11 and 12.

Concurrently, another mold 1C for wiring is prepared. The mold 1C for wiring is the same as that of the fifth embodiment.

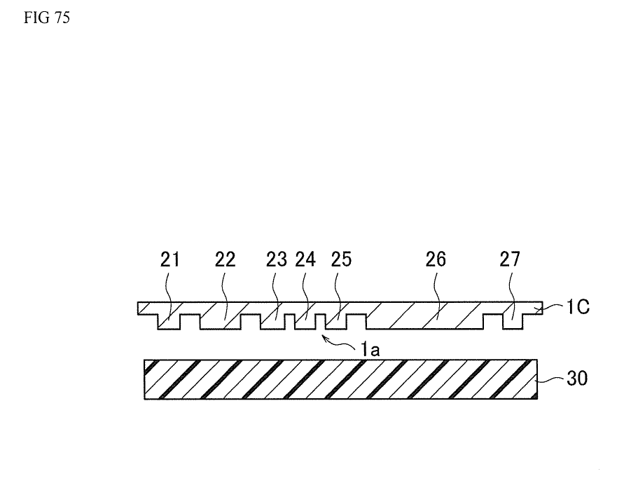

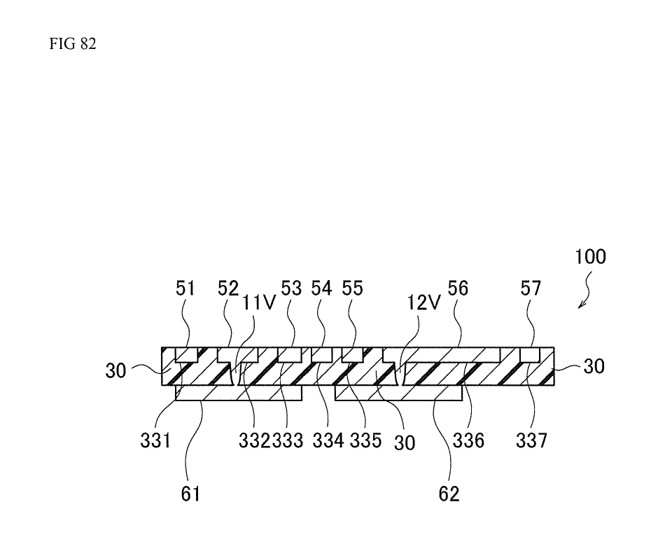

Hereinafter, a manufacturing method for a wiring board using the molds 1 and 1C will be described with reference to FIG. 75 to FIG. 81, and the manufactured wiring board will then be described with reference to FIG. 82.

In the present embodiment, a wiring board is obtained by so-called imprinting method using the above-described mold 1 for via shown in FIG. 74 and the mold 1C for wiring.

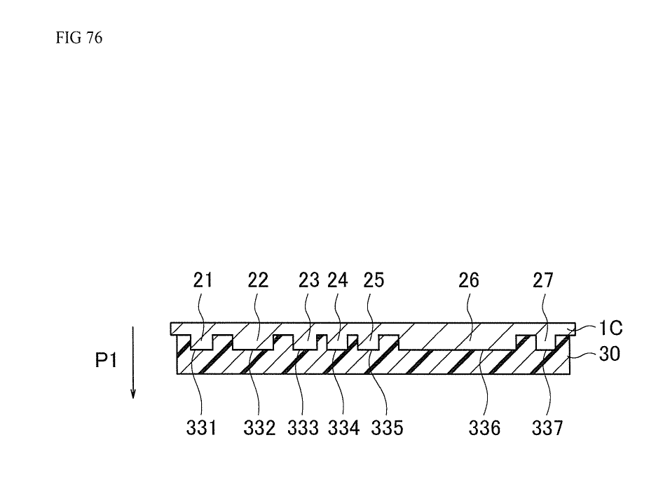

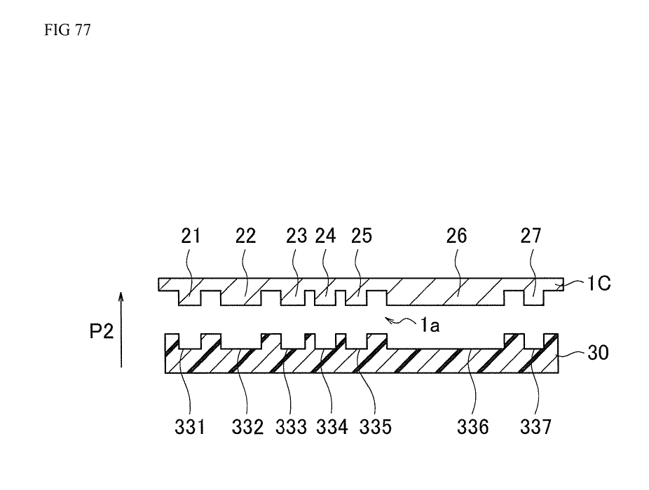

As shown in FIG. 75, the mold 1C for wiring is located first to oppose the main surface of the insulating base material 30. Thereafter, as shown in FIG. 76, the mold 1C is caused to approach the insulating base material 30 (caused to move along arrow P1) and hot pressing is performed under the same condition as the fifth embodiment. The mold 1C and the insulating base material 30 are cooled below the glass transition temperature (Tg), and the mold 1C is released in the direction where the mold 1C is separated from the insulating base material 30 (arrow P2), as shown in FIG. 77. Consequently, the main surface of the insulating base material 30 is formed thereon concave portions 331 to 337 depending on wiring patterns.

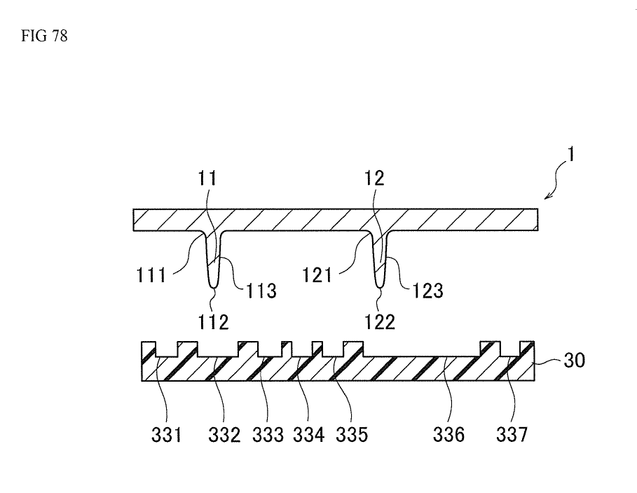

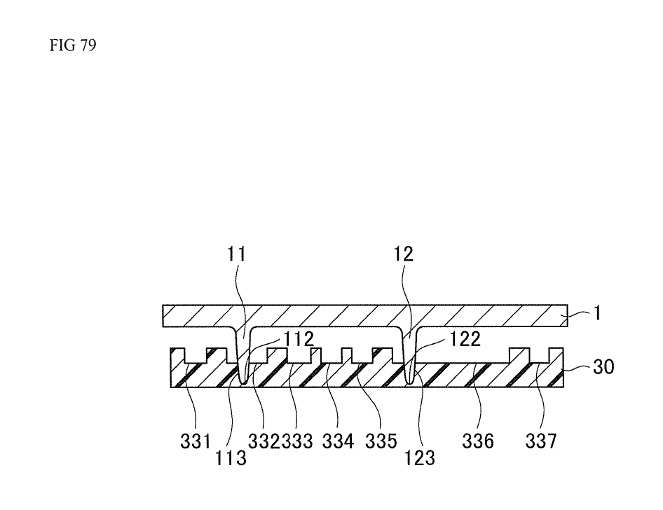

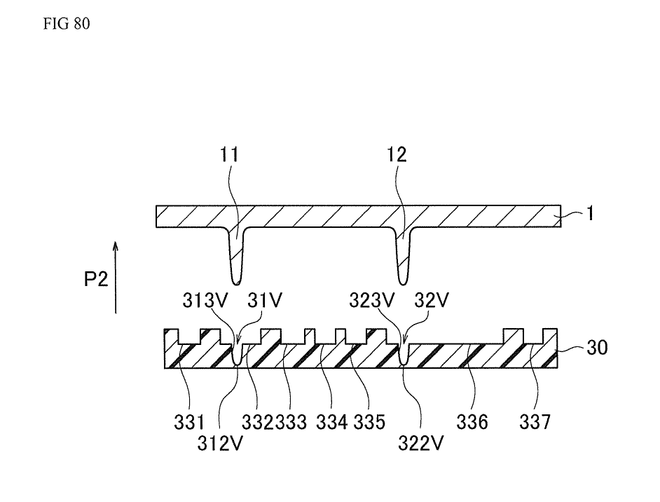

Subsequently, as shown in FIG. 78, the mold 1 for via is located to oppose the main surface of the insulating base material 30 formed thereon the concave portions 331 to 337. At this time, the mold 1 for via is located such that the protruding portions 11 and 12 of this mold 1 get into touch with concave portions 331 to 337 formed on one main surface of the insulating base material 30. Thereafter, as shown in FIG. 79, the mold 1 is caused to approach the insulating base material 30 (caused to move along arrow P1) and hot pressing is performed under the same condition as the fifth embodiment. The mold 1 and the insulating base material 30 are cooled below the glass transition temperature (Tg), and the mold 1 is released in the direction where the mold 1 is separated from the insulating base material 30 (arrow P2), as shown in FIG. 80.

Here, the height of the protruding portions 11 and 12 in the mold clamping direction (vertical direction in the figure) is higher than the thickness of the insulating base material 30, so that the flat portion of the mold 1 may be avoided from contacting with the insulating base material 30, thereby to prevent losing the shape of concave portions 331 to 337 of the insulating base material 30.

The above allows for transferring the shape depending on via patterns of the stamping surface 1a of the mold 1 and the shape depending on wiring patterns of the stamping surface 1a of the mold 1C to the main surface of the insulating base material 30. As shown in the figure, after releasing the mold 1, the insulating base material 30 is formed therein the concave portions 331 to 337 depending on the convex portions 21 to 27 of the mold 1C as well as the holes 31V and 32V depending on the shapes of the protruding portions 11 and 12 of the mold 1.

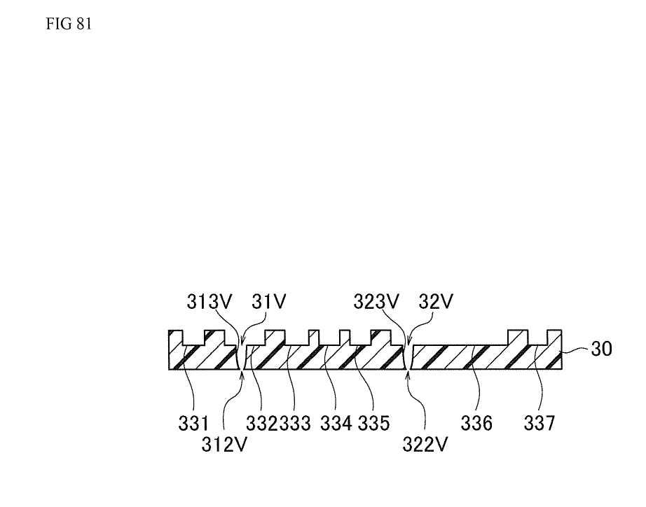

If the mold 1 has not penetrated the insulating base material 30 and resins remain at the bottoms of the holes 31V and 32V, as shown in FIG. 80, then they may be removed by chemical or mechanical polishing to cause the holes 31V and 32V to pass through, as shown in FIG. 81.

After applying resist to the lower surface of the insulating base material 30 shown in FIG. 81 and patterning the resist using photolithography technique, plating is performed to fill the holes 31V and 32V with conductive material.

This plating process allows for concurrently forming via patterns 11V and 12V, first wiring patterns 51 to 57, and second wiring patterns 61 and 62. In an alternative embodiment, conductive paste may be printed/sintered on the upper surface and the lower surface of the insulating base material 30 to concurrently form the via patterns 11V and 12V, the first wiring patterns 51 to 57, and the second wiring patterns 61 and 62. If surplus portions of nano-paste remain, they will be removed by polishing, etching or other appropriate means.

FIG. 82 illustrates wiring board 100 according to the present embodiment. As shown in FIG. 82, the wiring board 100 in the present embodiment comprises: insulating base material 30; first wiring patterns 51 to 57 formed on one main surface of the insulating base material 30; second wiring patterns 61 and 62 formed on the other main surface of the insulating base material 30; and via patterns 11V and 12V penetrating from the one main surface side to the other main surface side of the insulating base material 30 and conducting with the first wiring patterns 51 to 57 and the second wiring patterns 61 and 62. The first wiring patterns 51 to 57 of the wiring board 100 according to the present embodiment are formed in a status where they are embedded in convex-like shape from the one main surface (upper side in the figure) of the insulating base material 30 toward the inner side.

Accordingly, the wiring board 100 in the present embodiment provides functionalities and advantageous effects like the wiring board in the fifth embodiment.

### Eighth Embodiment

Hereinafter, an eighth embodiment will be described. The eighth embodiment involves a method of manufacturing a laminate-type wiring board using the wiring board 100 according to the seventh embodiment, and the laminate-type wiring board obtained by this manufacturing method. Detailed descriptions for common elements will be represented by those for the above-described embodiments.

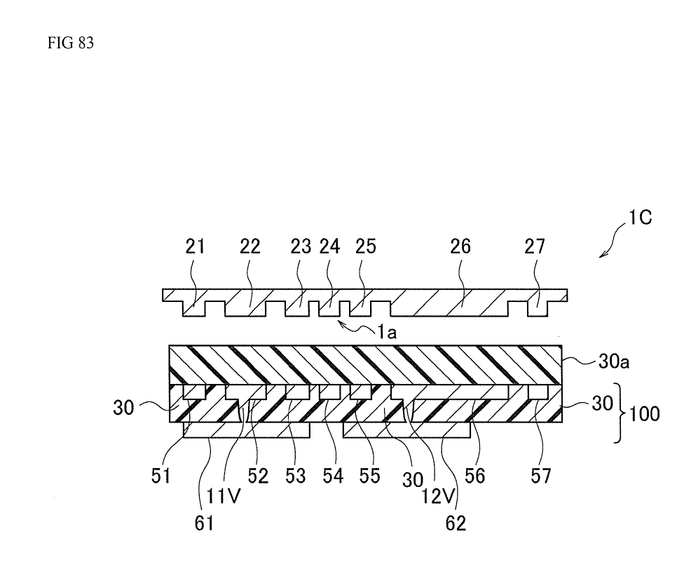

(1) As shown in FIG. 83, the wiring board 100 in the seventh embodiment is prepared, and another insulating base material 30a other than the insulating base material 30 used in this wiring board 100 is laminated on the uppermost surface (exposed surface) of the wiring board 100 (first laminating process). As a material for the insulating base material 30a, the same material as the insulating base material 30 of the wiring board 100 may be used.

(2) Thereafter, mold 1C is prepared. The mold 1C is common to the mold 1C described in the fifth embodiment. As shown in the figure, the mold 1C is located parallel to the insulating base material 30a laminated on the uppermost layer surface side of the wiring board 100. Convex portions 21 to 27 formed on the stamping surface 1a of the mold 1C oppose the insulating base material 30a.

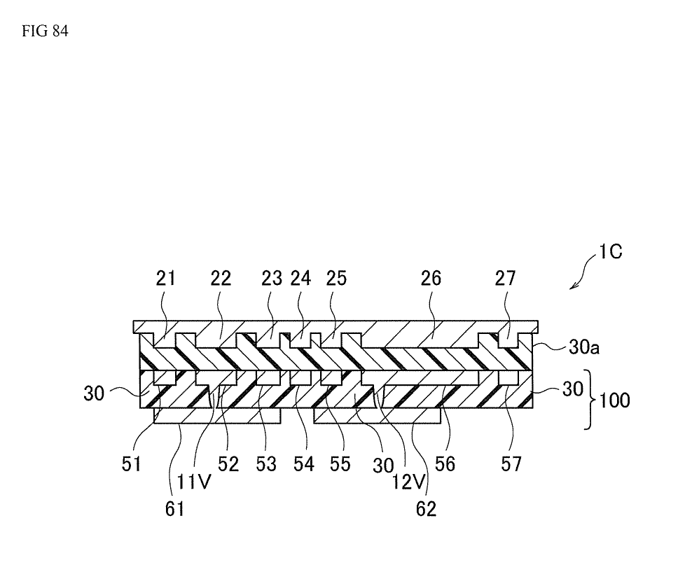

(3) The insulating base material 30a is heated to a temperature equal to or above the glass transition temperature, and the mold 1C is caused to move toward the insulating base material 30a such that the convex portions 21 to 27 are pressed into the insulating base material 30a, as shown in FIG. 84.

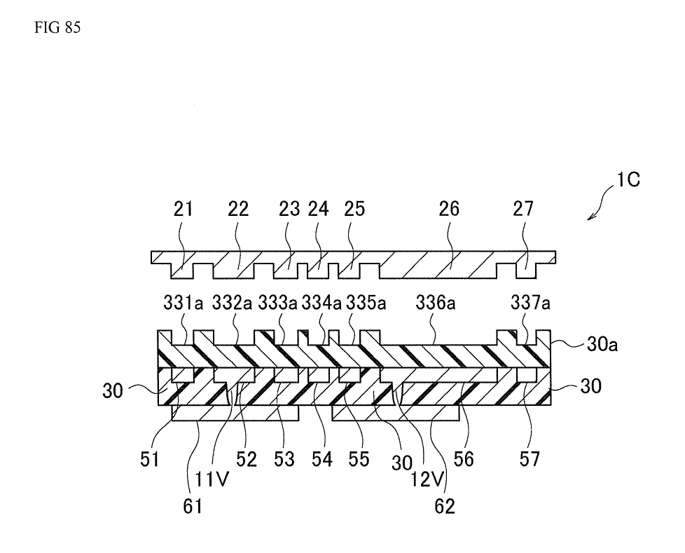

(4) Subsequently, as shown in FIG. 85, the mold 1C is released from the insulating base material 30a to form concave portions 331a to 337a with shapes depending on the convex portions 21 to 27 of the mold 1C on the insulating base material 30a (second laminating process).

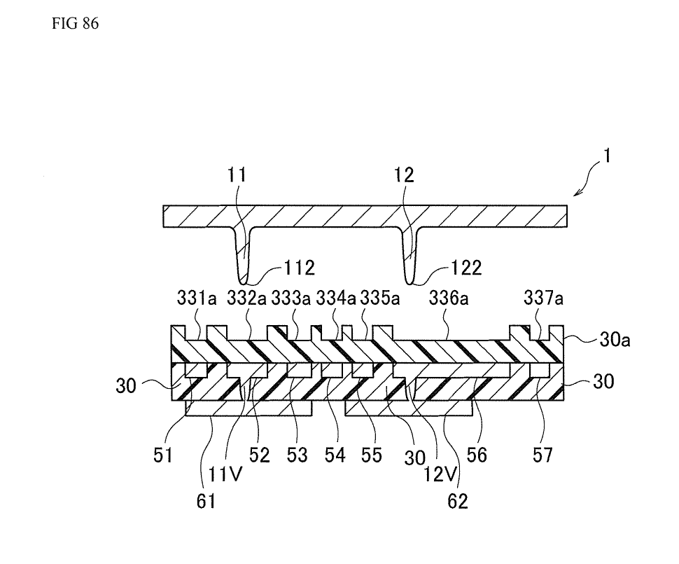

(5) Thereafter, mold 1 is prepared. The structure of the mold 1 is common to that of the mold 1 described in the seventh embodiment. As shown in FIG. 86, the mold 1 is located parallel to the insulating base material 30a laminated on the uppermost layer surface side of the wiring board 100. This insulating base material 30a has been formed therein concave portions 331a to 337a. Top portions 112 and 122 of the protruding portions 11 and 12 formed on the stamping surface 1a of the mold 1 oppose the concave portions 332a and 336a of the insulating base material 30a.

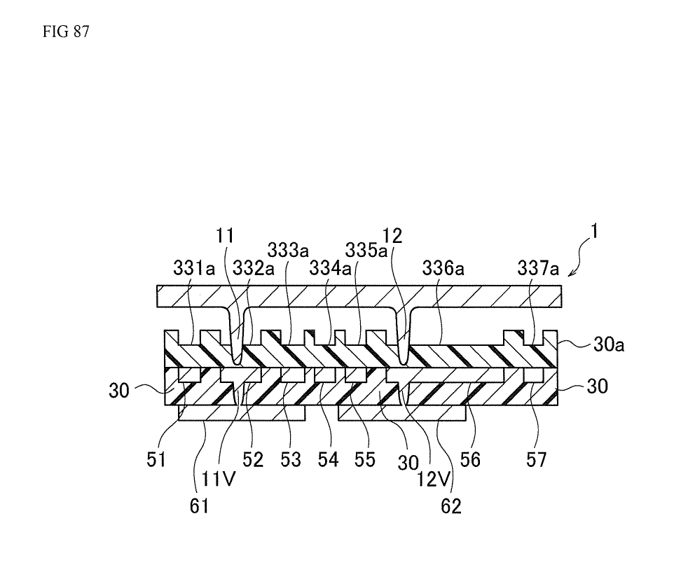

(6) The insulating base material 30a is heated to a temperature equal to or above the glass transition temperature, and the mold 1 is caused to move toward the insulating base material 30a such that the protruding portions 11 and 12 are pressed into the insulating base material 30a, as shown in FIG. 87.

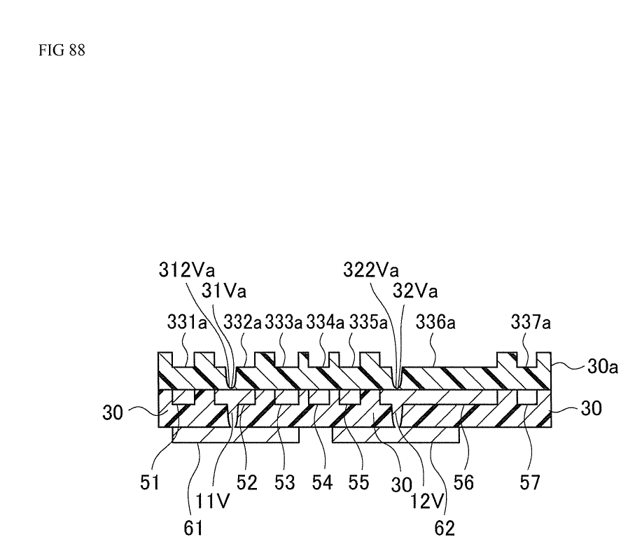

(7) Subsequently, the mold 1 is released from the insulating base material 30a. As shown in FIG. 88, the insulating base material 30a after the releasing of the mold 1 is formed therein the holes 31Va and 32Va depending on the shapes of the protruding portions 11 and 12 of the mold 1 and the concave portions 331a to 337a depending on first wiring patterns (third laminating process).

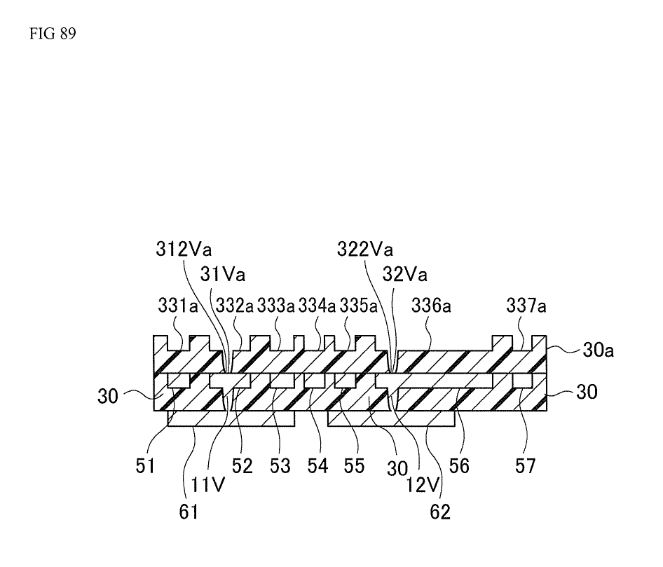

(8) If bottom areas 312Va and 322Va of the holes 31Va and 32Va of the insulating base material 30a are not passed through and resins remain there, then irradiating plasma, spraying chemical solution, or sandblasting process may be performed, as shown in FIG. 89, from opening areas of the holes 31Va and 32Va to cause the bottom areas 312Va and 322Va of the holes 31Va and 32Va to pass through.

(9) The concave portions 331a to 337a and the holes 31Va and 32Va are filled with conductive material by plating or printing/sintering conductive paste for the wiring board 100 shown in FIG. 89 to form first wiring patterns and via patterns (fourth laminating process).

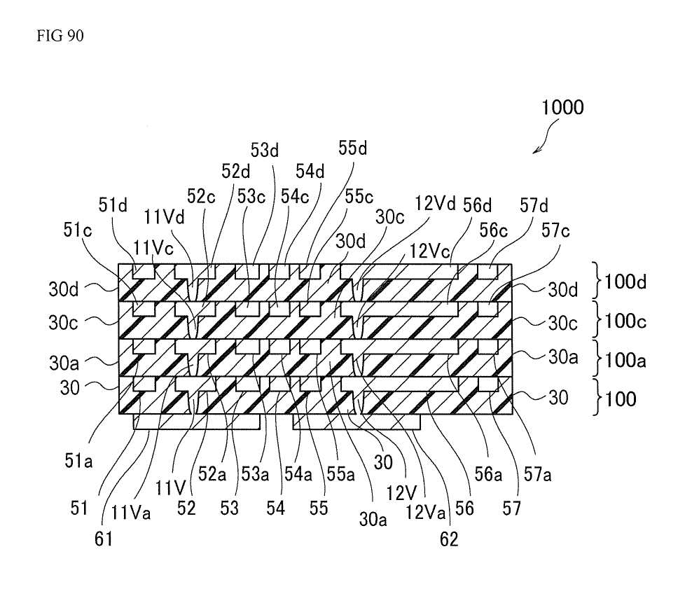

(10) According to the above-described first laminating process to the fourth laminating process, a laminate-type wiring board 1000 can be obtained in which interlayer conduction is achieved for the wiring board 100. FIG. 90 is a view illustrating an example of laminate-type wiring board 1000 achieved by repeating three times the first laminating process to the fourth laminating process to laminate wiring boards 100a, 100c and 100d on the wiring board 100. The above-described first laminating process to the fourth laminating process may be repeated a number of times depending on the target laminating number of laminate-type wiring board 1000.

The laminate-type wiring board 1000 according to the present embodiment is such that, as similar to the above-described embodiments, the via patterns 11V and 12V (11Va, 11Vc, 11Vd, 12Va, 12Vc, 12Vd) and the first wiring patterns 51 to 57 (51a to 57a, 51c to 57c, 51d to 57d) are integrally formed in a status where no interface exists, thereby to provide functionalities and advantageous effects like the above-described embodiments.

Note that, while FIG. 90 illustrates the laminate-type wiring board 1000 having wiring boards 100, 100a, 100c and 100d, the number of laminating for the wiring board 100 is not limited. Note also that first wiring patterns 51 to 57 (51a to 57a, 51c to 57c, 51d to 57d) of each wiring board to be laminated may be in a common fashion or different fashion.

It should be appreciated that the embodiments heretofore explained are described to facilitate understanding of the present invention and are not described to limit the present invention. Therefore, it is intended that the elements disclosed in the above embodiments include all design changes and equivalents to fall within the technical scope of the present invention.

### DESCRIPTION OF REFERENCE NUMERALS

100 . . . wiring board
1000 . . . laminate-type wiring board
1, 1A, 1B, 1C . . . mold
1a . . . stamping surface
11, 12 . . . protruding portion
111, 121 . . . base portion
111a, 121a . . . curved surface
112, 122 . . . top portion
113, 123 . . . slope portion
21-27 . . . convex portion
2 . . . supporting plate
3 . . . resin plate body
31, 32 . . . hole
311, 321 . . . opening area
312, 322 . . . bottom area
313, 323 . . . body area
313a, 323a . . . slope wall
4 . . . resist layer
41-47 . . . trench
11V, 12V, 11Va-11Vd, 12Va-12Vd . . . via pattern
111V, 121V . . . connection base portion
111Va, 121Va . . . curved connection surface
112V, 122V . . . top head portion
113V, 123V . . . cone-like portion
30, 30a, 30b . . . insulating base material
31V, 32V, 31Va, 32Va, 31Vb, 32Vb . . . hole
311V, 321V . . . opening area
311Va, 321Va . . . inner wall
312V, 322V, 312Va, 322Va, 312Vb, 322Vb . . . bottom area
313V, 323V . . . body area
331-337, 331a-337a . . . concave portion
51-57, 51a-57a, 51b-57b . . . first wiring pattern
61, 62 . . . wiring pattern

What is claimed is:

1. A manufacturing method for a wiring board, comprising:
preparing a first mold comprising a first stamping surface, the first stamping surface including a first protruding portion formed depending on a first via pattern constituting a part of patterns of a first wiring board, the first protruding portion having a first base portion and a first slope portion, the first base portion merging into a main surface of the first stamping surface to have a curvature, the first slope portion decreasing in outer diameter as approaching a first top portion of the first protruding portion from the first base portion;
pressing the first stamping surface to one main surface of a first insulating base material having been softened and thereafter releasing the first stamping surface from the one main surface to form a first hole depending on shape of the first protruding portion in the first insulating base material;
forming a first concave portion on the one main surface of the first insulating base material, the first concave portion depending on a first wiring pattern constituting a part of the patterns of the first wiring board; and
filling the first hole and the first concave portion formed in the first insulating base material with a conductive material to form the first via pattern and the first wiring pattern capable of being conductive with each other.

2. A manufacturing method for a laminate-type wiring board, comprising:
a first laminating process for preparing a first wiring board having been obtained by the manufacturing method for a wiring board of claim 1 and laminating one or more second insulating base materials on uppermost surface and/or lowermost surface of the first wiring board;
a second laminating process for preparing a second mold comprising a second stamping surface, the second stamping surface including a second protruding portion formed depending on a second via pattern constituting a part of patterns of a second wiring board to be laminated, the second protruding portion having a second base portion and a second slope portion, the second base portion merging into a main surface of the second stamping surface to have a curvature, the second slope portion decreasing in outer diameter as approaching a second top portion of the second protruding portion from the second base portion, the second laminating process further for pressing the second stamping surface to a surface of each laminated second insulating base material and thereafter releasing the second stamping surface from the surface of the laminated second insulating base material to form a second hole depending on shape of the second protruding portion in the laminated second insulating base material;
a third laminating process for forming a second concave portion on a main surface of the laminated second insulating base material, the second concave portion depending on a second wiring pattern constituting a part of the patterns of the second wiring board; and
a fourth laminating process for filling the second hole and the second concave portion formed in the laminated second insulating base material with a conductive material to form the second via pattern and the second wiring pattern capable of being conductive with each other,
wherein the first to fourth laminating processes are performed one time or repeated two or more times using the molds having stamping surfaces depending on respective patterns of the wiring boards to be laminated, and wherein whether the first to fourth laminating processes are performed one time or repeated two or more times is depending on a laminating number of a wiring board to be manufactured.

3. A manufacturing method for a wiring board, comprising:
preparing a first mold comprising a first stamping surface, the first stamping surface including a first protruding portion formed depending on a first via pattern constituting a part of patterns of a first wiring board, the first stamping surface further including a first convex portion formed depending on a first wiring pattern constituting a part of the patterns of the first wiring board, the first protruding portion having a first base portion and a first slope portion, the first base portion merging into an upper surface of the first convex portion to have a curvature, the first slope portion decreasing in outer diameter as approaching a first top portion of the first protruding portion from the first base portion;
pressing the first stamping surface to one main surface of a first insulating base material having been softened and thereafter releasing the first stamping surface from the one main surface to form in the first insulating base material a first hole depending on shape of the first protruding portion and a first concave portion depending on shape of the first convex portion; and
filling the first hole and the first concave portion formed in the first insulating base material with a conductive material to form the first via pattern and the first wiring pattern capable of being conductive with each other.

4. A manufacturing method for a laminate-type wiring board, comprising:
a first laminating process for preparing a first wiring board having been obtained by the manufacturing method for a wiring board of claim 3 and laminating one or more second insulating base materials on uppermost surface and/or lowermost surface of the first wiring board;
a second laminating process for preparing a second mold comprising a second stamping surface, the second stamping surface including a second protruding portion formed depending on a second via pattern constituting a part of patterns of a second wiring board to be laminated, the second stamping surface further including a second convex portion formed depending on a second wiring pattern constituting a part of the patterns of the second wiring board, the second protruding portion having a second base portion and a second slope portion, the second base portion merging into an upper surface of the second convex portion to have a curvature, the second slope portion decreasing in outer diameter as approaching a second top portion of the second protruding portion from the second base portion, the second laminating process further for pressing the second stamping surface to a surface of each laminated second insulating base material and thereafter releasing the second stamping surface from the surface of the laminated second insulating base material to form in the laminated second insulating base material a second hole depending on shape of the second protruding portion and a second concave portion depending on shape of the second convex portion; and
a third laminating process for filling the second hole and the second concave portion formed in the laminated second insulating base material with a conductive material to form the second via pattern and the second wiring pattern capable of being conductive with each other,
wherein the first to third laminating processes are performed one time or repeated two or more times using the molds having stamping surfaces depending on respective patterns of the wiring boards to be laminated, and wherein whether the first to third laminating processes are performed one time or repeated two or more times is depending on a laminating number of a wiring board to be manufactured.

5. A manufacturing method for a wiring board, comprising:
preparing a first mold for via, the first mold for via comprising a first stamping surface for via, the first stamping surface for via including a first protruding portion formed depending on a first via pattern constituting a part of patterns of a first wiring board, the first protruding portion having a first base portion and a first slope portion, the first base portion having a curved surface, the first slope portion decreasing in outer diameter as approaching a first top portion of the first protruding portion from the first base portion;
preparing a first mold for wiring, the first mold for wiring comprising a first stamping surface for wiring, the first stamping surface for wiring including a first convex portion formed depending on a first wiring pattern constituting a part of the patterns of the first wiring board;
pressing the first stamping surface for wiring to one main surface of a first insulating base material having been softened and thereafter releasing the first stamping surface for wiring from the one main surface to form a first concave portion in the first insulating base material, the first concave portion being of shape depending on the first convex portion;
pressing the first stamping surface for via to the one main surface of the first insulating base material such that the first protruding portion gets into touch with the first concave portion formed on the one main surface of the first insulating base material and thereafter releasing the first stamping surface for via from the one main surface to form a first hole depending on shape of the first protruding portion in the first insulating base material; and
filling the first hole and the first concave portion formed in the first insulating base material with a conductive material to form the first via pattern and the first wiring pattern capable of being conductive with each other.

6. A manufacturing method for a laminate-type wiring board, comprising:
a first laminating process for preparing a first wiring board having been obtained by the manufacturing method for a wiring board of claim 5 and laminating one or more second insulating base materials on uppermost surface and/or lowermost surface of the first wiring board;
a second laminating process for preparing a second mold for wiring, the second mold for wiring comprising a second stamping surface for wiring, the second stamping surface for wiring including a second convex portion formed depending on a second wiring pattern constituting a part of patterns of a second wiring board to be laminated, the second laminating process further for pressing the second stamping surface for wiring to a surface of each laminated second insulating base material and thereafter releasing the second stamping surface for wiring from the surface of the laminated second insulating base material to form a second concave portion in the laminated second insulating base material, the second concave portion being of shape depending on the second convex portion;
a third laminating process for preparing a second mold for via, the second mold for via comprising a second stamping surface for via, the second stamping surface for via including a second protruding portion formed depending on a second via pattern constituting a part of the patterns of the second wiring board, the second protruding portion having a second base portion and a second slope portion, the second base portion having a curved surface, the second slope portion decreasing in outer diameter as approaching a second top portion of the second protruding portion from the second base portion, the third laminating process further for pressing the second stamping surface for via to the surface of the laminated second insulating base material such that the second protruding portion gets into touch with the second concave portion formed on the surface of the laminated second insulating base material and thereafter releasing the second stamping surface for via from the surface of the laminated second insulating base material to form a second hole depending on shape of the second protruding portion in the laminated second insulating base material; and
a fourth laminating process for filling the second hole and the second concave portion formed in the laminated second insulating base material with a conductive material to form the second via pattern and the second wiring pattern capable of being conductive with each other,
wherein the first to fourth laminating processes are performed one time or repeated two or more times using the molds for via and the molds for wiring depending on respective patterns of the wiring boards to be laminated, and wherein whether the first to fourth laminating processes are performed one time or repeated two or more times is depending on a laminating number of a wiring board to be manufactured.

7. The manufacturing method for a wiring board as set forth in claim 1, further comprising:
forming a lower layer concave portion on the other main surface of the first insulating base material, the lower layer concave portion depending on a third wiring pattern conductive with the first via pattern,
wherein the filling the first hole with a conductive material includes filling the lower layer concave portion formed on the other main surface of the first insulating base material with the conductive material.

8. The manufacturing method for a wiring board as set forth in claim 3, further comprising:
forming a lower layer concave portion on the other main surface of the first insulating base material, the lower layer concave portion depending on a third wiring pattern conductive with the first via pattern,
wherein the filling the first hole with a conductive material includes filling the lower layer concave portion formed on the other main surface of the first insulating base material with the conductive material.

9. The manufacturing method for a wiring board as set forth in claim 5, further comprising:
forming a lower layer concave portion on the other main surface of the first insulating base material, the lower layer concave portion depending on a third wiring pattern conductive with the first via pattern,
wherein the filling the first hole with a conductive material includes filling the lower layer concave portion formed on the other main surface of the first insulating base material with the conductive material.

10. The manufacturing method for a wiring board as set forth in claim 1,
wherein the first top portion of the first protruding portion has a curved surface.

11. The manufacturing method for a wiring board as set forth in claim 3,
wherein the first top portion of the first protruding portion has a curved surface.

12. The manufacturing method for a wiring board as set forth in claim 5,
wherein the first top portion of the first protruding portion has a curved surface.

13. The manufacturing method for a laminate-type wiring board as set forth in claim 2,
wherein the first top portion of the first protruding portion and the second top portion of the second protruding portion have curved surfaces.

14. The manufacturing method for a laminate-type wiring board as set forth in claim 4,
wherein the first top portion of the first protruding portion and the second top portion of the second protruding portion have curved surfaces.

15. The manufacturing method for a laminate-type wiring board as set forth in claim 6,
wherein the first top portion of the first protruding portion and the second top portion of the second protruding portion have curved surfaces.

16. The manufacturing method for a wiring board as set forth in claim 1, further comprising:
after forming the first hole in the first insulating base material, removing the first insulating base material from a bottom portion of the first hole to cause the first hole to pass through.

17. The manufacturing method for a wiring board as set forth in claim 3, further comprising:
after forming the first hole in the first insulating base material, removing the first insulating base material from a bottom portion of the first hole to cause the first hole to pass through.

18. The manufacturing method for a wiring board as set forth in claim 5, further comprising:
after forming the first hole in the first insulating base material, removing the first insulating base material from a bottom portion of the first hole to cause the first hole to pass through.
